(19) United States
(12) Patent Application Publication
(10) Pub. No.: US 2010/0112474 A1
(43) Pub. Date: May 6, 2010

(54) PHOTOSENSITIVE COMPOSITION, PHOTOSENSITIVE FILM, METHOD FOR FORMING A PERMANENT PATTERN, AND PRINTED BOARD

(75) Inventors: Masayuki Iwasaki, Shizuoka (JP); Hiroshi Kamikawa, Shizuoka (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/530,547

(22) PCT Filed: Sep. 12, 2007
(86) PCT No.: PCT/JP2007/067753

§ 371 Date: Sep. 9, 2009

(30) Foreign Application Priority Data
Mar. 12, 2007 (JP) 2007-062117

(51) Int. Cl. G03F 7/20; G03F 7/004

(52) U.S. Cl. 430/270.1; 430/325; 430/319

(57) ABSTRACT

This invention provides a photosensitive composition, which can form a smooth photosensitive layer, has good storage stability, and exhibits high sensitivity when a blue-violet laser exposure system is used, a photosensitive film, a method for forming a permanent pattern using the photosensitive composition, and a printed board with a permanent pattern formed thereon by the method for forming a permanent pattern.

### TECHNICAL FIELD

The present invention relates to a photosensitive composition suitable for use in a blue-violet laser exposure system for the formation of solder resists as insulating films or protective films for covering printed wiring boards and the like, a photosensitive film, a method for forming a permanent pattern using the photosensitive composition, and a printed board with a permanent pattern formed by the method for forming a permanent pattern.

### BACKGROUND ART

In the field of printed wiring boards, semiconductors and capacitors, resistors or other components are soldered onto a printed wiring board. In this case, for example, in the step of soldering such as IR reflow, a method is adopted in which a permanent pattern corresponding to a part unnecessary to be soldered is formed as a protective film or an insulating film to prevent the deposition of solder onto the part unnecessary to be soldered. Further, a solder resist is suitable as a permanent pattern of the protective film.

The permanent pattern has hitherto been generally formed by a method for forming a permanent pattern using a liquid resist in which a photosensitive composition solution is coated onto the printed wiring board to stack a photosensitive layer onto the printed wiring board. In recent years, changing the liquid resist to a dry film has been desired because of better handleability and excellent film thickness uniformity.

On the other hand, the photosensitive layer has been generally exposed by using a photomask. In recent years, however, attention has been drawn to a maskless laser exposure system that can enhance the productivity of a printed board and can reduce the defective fraction.

Here it is known that halogen atom-containing compounds generate harmful substances such as dioxin upon burning, and there is an increasing demand for a halogen atom-free printed board.

Up to now, it is known that, among halogen atom-containing materials, phthalocyanine greens (C.I. Pigment Green 7 and C.I. Pigment Green 36), which are green pigments, occupies a large part of the content of halogen atoms in solder resists used in permanent patterns.

Accordingly, for example, techniques are disclosed in which, instead of the phthalocyanine green, a mixture of a halogen atom-free blue pigment with a halogen atom-free yellow or orange pigment is used as a photosensitive composition having a lowered halogen content (see Patent Literatures 1 to 5).

Patent Literature 1 discloses a technique regarding a photosensitive resin composition using a combination of a cyanine green-type green with a yellow pigment.

Further, Patent Literature 2 describes that the halogen content of a solder resist cured film containing 1.9% by mass of C.I. Pigment Green 7 is 8,767 ppm.

Patent Literature 3 describes that an epoxy resin synthesized through an epichlorohydrin intermediate usually incorporated in a solder resist contains several hundreds of ppm of halogens as impurities. Further, Patent Literature 3 discloses that, when changing the epoxy resin production process to a peracid oxidation process and chlorine reduction treatment can reduce the halogen content to 10 ppm to 50 ppm or less.

Patent Literature 4 discloses a technique regarding a resist ink composition comprising halogen-free blue and yellow pigments in combination.

Patent Literature 5 discloses a technique regarding a solder resist ink using halogen-free blue and orange pigments in combination.

In the photosensitive compositions disclosed in Patent Literatures 1 to 5, instead of the phthalocyanine greens, a mixture of a blue pigment free from a halogen atom per molecule with yellow and/or orange pigments free from a halogen atom per molecule is contained as a colorant.

Besides Patent Literatures 1 to 5, a technique regarding a solder resist ink in which, instead of the phthalocyanine greens, a copper phthalocyanine pigment containing one halogen atom per molecule and having a halogen content of 25% or less based on the molecular weight is contained (see Patent Literature 6).

The photosensitive compositions disclosed in Patent Literatures 1 to 5, however, are disadvantageous in that (1) a problem that the dispersibility of the pigment constituting the colorant is so low that ensuring a stable pigment dispersion is difficult and the formation of a smooth photosensitive layer is difficult has not been solved. Patent Literature 6 has a problem that (2) although the stable pigment dispersion can be ensured, the photosensitive composition suffers from a problem of the storage stability (a change in developability with the elapse of time).

Further, Patent Literatures 1 to 6 suffer from a problem that (3) exhibiting a desired high sensitivity is difficult for a blue-violet laser beam (wavelength=405±5 nm).

Thus, despite the development of various resist materials, which have taken an influence on an environment upon disposal into consideration, a photosensitive composition, which can form a smooth photosensitive layer, has good storage stability, and exhibits high sensitivity when a blue-violet laser exposure system is used, a photosensitive film, a method for forming a permanent pattern using the photosensitive composition, and a printed board with a permanent pattern formed by the method for forming a permanent pattern have not hitherto been provided.

### [Patent Literature 1] Japanese Patent Application Laid-Open (JP-A) No. 09-136942

### [Patent Literature 2] Japanese Patent Application Laid-Open (JP-A) No. 2000-7974

### [Patent Literature 3] Japanese Patent Application Laid-Open (JP-A) No. 2000-232264

### [Patent Literature 4] Japanese Patent Application Laid-Open (JP-A) No. 2000-290564

[Patent Literature 5] International Publication No. WO 01/67178
[Patent Literature 6] International Publication No. WO 02/48794

### DISCLOSURE OF INVENTION

The present invention has been made so as to solving the above-described various problems of the prior art and achieving the following object. An object of the present invention is to provide a photosensitive composition, which can form a smooth photosensitive layer, has good storage stability, and exhibits high sensitivity when a blue-violet laser exposure system is used, a photosensitive film, a method for forming a permanent pattern using the photosensitive composition, and a printed board with a permanent pattern formed by the method for forming a permanent pattern.

In view of the above problems of the present invention, the present inventors have made extensive and intensive studies and, as a result, have found that the above object, that is, providing a photosensitive composition, which can form a smooth photosensitive layer and exhibits high sensitivity for a blue-violet laser beam, can be attained by a photosensitive composition including a colorant (a pigment), an alkali soluble photosensitive resin, a polymerizable compound, a photopolymerization initiator or photoinitiator compound, and a thermal crosslinking resin, wherein the colorant (pigment) contains a pigment which contains 5% by mass to 50% by mass of a halogen atom per molecule and shows a yellow color, and a pigment which does not contain a halogen atom per molecule and shows a blue color in a mixing ratio (mass ratio) of 1:1 to 1:4, the colorant shows a green color due to the mixing of these pigments, and the halogen content in the total solid content is 900 ppm or less.

The present invention has been made based on the above finding of the present inventors and can be summarized as follows.

<1> A photosensitive composition containing: an alkali soluble photosensitive resin; a polymerizable compound; a photopolymerization initiator or a photoinitiator compound; a thermal crosslinking resin; and a colorant, wherein the colorant contains a pigment which contains 5% by mass to 50% by mass of a halogen atom per molecule and shows a yellow color, and a pigment which does not contain a halogen atom per molecule and shows a blue color in a mixing ratio (mass ratio) of 1:1 to 1:4, the colorant shows a green color due to the mixing of the pigments, and the halogen content in the total solid content of the photosensitive composition is 900 ppm or less.

<2> The photosensitive composition according to <1>, wherein the pigment which shows a blue color is a phthalocyanine pigment, and

the pigment which shows a yellow color is a pigment that contains a halogen atom in a molecule thereof and is selected from: monoazo compounds; diarylide non-lake compounds and lake compounds among disazo compounds; bisacetoacetarylide compounds; benzimidazolone compounds; metal complex compounds; quinophthalone compounds; isoindoline compounds; and aminoanthraquinone compounds and heterocylic anthraquinone pigments among condensed polycyclic compound.

<3> The photosensitive composition according to <2>, wherein the phthalocyanine pigment is C.I. Pigment Blue 15:3.

<4> The photosensitive composition according to <2>, wherein the pigment which shows a yellow color is selected from C.I. Pigment Yellow 2, C.I. Pigment Yellow 3, C.I. Pigment Yellow 6, C.I. Pigment Yellow 49, C.I. Pigment Yellow 73, C.I. Pigment Yellow 75, C.I. Pigment Yellow 97, C.I. Pigment Yellow 98, C.I. Pigment Yellow 111, C.I. Pigment Yellow 116, C.I. Pigment Yellow 10, C.I. Pigment Yellow 60, C.I. Pigment Yellow 168, C.I. Pigment Yellow 12, C.I. Pigment Yellow 13, C.I. Pigment Yellow 14, C.I. Pigment Yellow 17, C.I. Pigment Yellow 55, C.I. Pigment Yellow 63, C.I. Pigment Yellow 81, C.I. Pigment Yellow 83, C.I. Pigment Yellow 87, C.I. Pigment Yellow 106, C.I. Pigment Yellow 113, C.I. Pigment Yellow 114, C.I. Pigment Yellow 121, C.I. Pigment Yellow 124, C.I. Pigment Yellow 126, C.I. Pigment Yellow 127, C.I. Pigment Yellow 136, C.I. Pigment Yellow 152, C.I. Pigment Yellow 170, C.I. Pigment Yellow 171, C.I. Pigment Yellow 172, C.I. Pigment Yellow 174, C.I. Pigment Yellow 176, C.I. Pigment Yellow 188, C.I. Pigment Yellow 109, C.I. Pigment Yellow 110, C.I. Pigment Yellow 173, C.I. Pigment Yellow 154, C.I. Pigment Yellow 93, C.I. Pigment Yellow 94, C.I. Pigment Yellow 95, C.I. Pigment Yellow 128, C.I. Pigment Yellow 166, and C.I. Pigment Yellow 138.

<5> The photosensitive composition according to any one of <1> to <4>, wherein an amount of the halogen component in the photosensitive composition is 500 ppm or less.

<6> The photosensitive composition according to any one of <1> to <4>, wherein an amount of the halogen component in the photosensitive composition is 250 ppm to 800 ppm.

<7> The photosensitive composition according to any one of <1> to <6>, wherein the pigment which shows a yellow color has an average particle diameter of 100 nm to 500 nm.

<8> A photosensitive film containing a photosensitive layer formed by applying the photosensitive composition according to any one of <1> to <7> onto a support and drying the applied photosensitive composition.

<9> A photosensitive film containing a support and a photosensitive layer provided on the support, wherein the photosensitive layer is formed form the photosensitive composition according to any one of <1> to <7>.

<10> The photosensitive film according to any one of <8> and <9>, wherein a thermoplastic resin layer and the photosensitive layer are provided in that order on the support.

<11> The photosensitive film according to any one of <8> to <10>, wherein the photosensitive film is continuous and wound in a roll form.

<12> The photosensitive film according to any one of <8> to <11>, wherein the photosensitive layer has a thickness of 1 μm to 100 μm.

<13> The photosensitive film according to any one of <8> to <12>, wherein the support contains a synthetic resin and is transparent.

<14> The photosensitive film according to any one of <8> to <13>, further containing a protective film provided on the photosensitive layer.

<15> An apparatus for formation a pattern, containing: a light irradiation unit capable of applying light; and a light modulation unit configured to modulate light emitted from the light irradiation unit and to perform exposure of a photosensitive layer formed by applying the photosensitive composition according to any one of <1> to <7> onto a surface of a substrate and drying the applied photosensitive composition. In the apparatus for forming a pattern described in <15>, the light irradiation unit applies light toward the light modulation unit. The light modulation unit modulates the light received from the light irradiation unit. The photosensitive layer is exposed to the light modulated by the light modulation unit. For example, when the photosensitive layer is then developed, a high-definition pattern is formed. A method for forming a permanent pattern contains performing exposure and development.

<16> An apparatus for forming a pattern, containing: the photosensitive film according to any one of <8> to <14>; a light irradiation unit capable of applying light; and a light modulation unit configured to modulate the light emitted from the light irradiation unit and perform exposure of a photosensitive layer in the photosensitive film.

In the apparatus for forming a pattern according to <16>, the light irradiation unit applies light toward the light modulation unit. The light modulation unit modulates light received from the light irradiation unit. The photosensitive layer is exposed to the light modulated by the light modulation unit. For example, when the photosensitive layer is then developed, a high-definition pattern is formed.

<17> The apparatus for pattern formation according to any one of <15> and <16>, wherein the light modulation unit further contains a pattern signal generation unit which generates a control signal based on information about a pattern to be formed and modulates light applied from the light irradiation unit according to the control signal generated by the pattern signal generation unit. In the apparatus for forming a pattern described in <17>, since the light modulation is provided with the pattern signal generation unit, the light applied from the light irradiation unit is modulated according to the control signal generated by the pattern signal generation unit.

<18> The apparatus for forming a pattern according to any one of <15> to <17>, wherein the light modulation unit includes n pieces of pixel parts and is capable of control arbitral less than n pieces of the pixel parts which are arranged in a row among the n pieces of the pixel parts according to information about a pattern to be formed. In the apparatus for forming a pattern in <18>, the light applied from the light irradiation unit can be modulated at a high speed by controlling the arbitrary less than n pieces of the pixel parts, which have been arranged in a row, among the n pieces of the pixel parts in the light modulation unit according to information about a pattern to be formed.

<19> The apparatus for forming a pattern according to any one of <15> to <18>, wherein the light modulation unit is a spatial light modulation element.

<20> The apparatus for forming a pattern according to <19>, wherein the spatial light modulation element is a digital micromirror device (DMD).

<21> The apparatus for forming a pattern according to any one of <18> to <20>, wherein the pixel part is a micromirror.

<22> The apparatus for forming a pattern according to any one of <15> to <21>, wherein the light irradiation unit is capable of combining two or more lights and applying the combined lights. In the apparatus for forming a pattern described in <22>, since the light irradiation unit can combine two or more lights and can apply the combined lights, the exposure can be performed with exposure light having a high focal depth. Consequently, the exposure of the photosensitive layer can be performed in a very high-definition manner. For example, when the photosensitive layer is then developed, a very high-definition pattern can be formed.

<23> The apparatus for forming a pattern according to any one of <15> to <22>, wherein the light irradiation unit contains a plurality of lasers, a multi-mode optical fiber, and an integrated optical system configured to collect laser beams applied from each of the plurality of lasers and converge the collected laser beams on the multi-mode optical fiber. In the apparatus for forming a pattern described in <23>, in the light irradiation unit, since the integrated optical system can collect laser beams applied from each of the plurality of lasers and can converge them on the multi-mode optical fiber, the exposure can be performed by exposure light having a high focal depth. Consequently, the exposure of the photosensitive layer can be performed in a very high-definition manner. For example, when the photosensitive layer is then developed, a very high-definition pattern can be formed.

<24> A method for forming a permanent pattern, containing exposing the photosensitive layer formed on a surface of a substrate using the photosensitive composition according to any one of <1> to <7>, and developing the exposed photosensitive layer.

<25> The method for forming a permanent pattern according to <24>, further containing stacking the photosensitive layer in the photosensitive film according to any one of <8> to <14> on the surface of the substrate under any one of heating and pressure, and then exposing the photosensitive layer.

<26> The method for forming a permanent pattern according to <24> and <25>, wherein the substrate is a printed wiring board with wiring formed thereon.

<27> The method for forming a permanent pattern according to any one of <24> to <26>, wherein the exposure is performed using a laser beam having a wavelength of 350 nm to 415 nm.

<28> The method for forming a permanent pattern according to any one of <24> to <27>, wherein the exposure is performed image-wise based on information about a pattern to be formed.

<29> The method for forming a permanent pattern according to any one of <24> to <28>, wherein the exposure is performed using an exposure head comprising a light irradiation unit, a light modulation unit which contains two-dimensionally arranged n pieces (wherein n is a natural number of 2 or more) of pixel parts, which receives the light applied from the light irradiation unit and allows the received light to exit, and is capable of controlling the pixel parts according to the information about a pattern to be formed, wherein the pixel parts are disposed so as to have a predetermined set inclination angle θ with the scanning direction of the exposure head in a column direction of the pixel parts, and wherein the exposing includes specifying, among the usable pixel parts, the pixel parts to be used in N-fold exposure (wherein N is a natural number of 2 or more) by a service pixel part specifying unit; controlling the pixel parts by the pixel part control unit so that only the pixel parts specified by the service pixel part specifying unit participate in the exposure; and moving the exposure head relatively to the photosensitive layer in the scanning direction. In the method for forming a permanent pattern described in <29>, for the exposure head, the pixel parts to be used in the N-fold exposure (wherein N is a natural number of 2 or more) among the usable pixel parts are specified by the service pixel part specifying unit, and the pixel parts are controlled by the pixel part control units so that only the pixel parts specified by the service pixel part specifying unit participate in the exposure. Since the exposure is performed while moving the exposure head relatively to the photosensitive layer in the scanning direction, a variation in resolution and density unevenness of the pattern formed on the exposure surface of the photosensitive layer caused by a deviation of the mounting position and mounting angle of the exposure head from the desired mounting position and mounting angle can be leveled. Consequently, the exposure of the photosensitive layer can be performed in a very high-definition manner. For example, when the photosensitive layer is then developed, a very high-definition pattern can be formed.

<30> The method for forming a permanent pattern according to <29>, wherein the exposure is performed with a plurality of the exposure heads, and the service pixel part specifying unit specifies, among the pixel parts involved in the exposure of a connection region between heads which is an overlapped exposure region on the exposure surface formed by the plurality of the exposure heads, pixel parts to be used in the realization of N-fold exposure in the connection region between the heads. In the apparatus for forming a permanent pattern described in <30>, since the exposure is performed with a plurality of exposure heads and service pixel part specifying unit specifies, among pixel parts involved in the exposure of a connection region between heads which is an overlapped exposure region on the exposure surface formed by the plurality of the exposure heads, pixel parts to be used in the realization of N-fold exposure in the connection region between the heads, a variation in resolution and density unevenness of the pattern formed in the connection region between the heads on the exposure surface of the photosensitive layer caused by a deviation of the mounting position and mounting angle of the exposure head from the desired mounting position and mounting angle can be leveled. Consequently, the exposure of the photosensitive layer can be performed in a very high-definition manner. For example, when the photosensitive layer is then developed, a very high-definition pattern can be formed.

<31> The method for pattern formation according to <29>, wherein the exposure is performed with a plurality of exposure heads, and the service pixel part specifying unit specifies, among pixel parts involved in the exposure of a region other than a connection region between heads which is an overlapped exposure region on the exposure surface formed by the plurality of the exposure heads, pixel parts to be used in the realization of N-fold exposure in the region other than the connection region between the heads. In the apparatus for forming a permanent pattern described in <31>, since the exposure is performed with a plurality of exposure heads and service pixel part specifying unit specifies, among pixel parts involved in the exposure of a region other than a connection region between heads which is an overlapped exposure region on the exposure surface formed by the plurality of the exposure heads, pixel parts to be used in the realization of N-fold exposure in the region other than the connection region between the heads, a variation in resolution and density unevenness of the pattern formed a region other than in the connection region between the heads on the exposure surface of the photosensitive layer caused by a deviation of the mounting position and mounting angle of the exposure head from the desired mounting position and mounting angle can be leveled. Consequently, the exposure of the photosensitive layer can be performed in a very high-definition manner. For example, when the photosensitive layer is then developed, a very high-definition pattern can be formed.

<32> The method for forming a permanent pattern according to any one of <29> to <31>, wherein the set inclination angle θ is set so as to satisfy a relationship of θ≧θ_{ideal} wherein θ_{ideal} satisfies the following formula: sp sin θ_{ideal}≧Nδ wherein N represents the number of times of exposure in N-fold exposure; s represents the number of pixel parts in the column direction; p represents the interval of pixel parts in the column direction; and δ represents the pitch of pixel parts in the column direction along a direction orthogonal to the scanning direction of the exposure head in such a state that the exposure head has been inclined.

<33> The method for forming a permanent pattern according to any one of <29> to <32>, wherein N in the N-fold exposure is a natural number of 3 or more. In the method for forming a permanent pattern described in <33>, since N in the N-fold exposure is a natural number of 3 or more, multiple imaging can be performed. By virtue of the compensation effect, a variation in resolution and density unevenness of the pattern formed on the exposure surface of the photosensitive layer caused by a deviation of the mounting position and mounting angle of the exposure head from the desired mounting position and mounting angle can be leveled more precisely.

<34> The method for forming a permanent pattern according to any one of <29> to <33>, wherein the service pixel part specifying unit contains: a light spot position detection unit that detects the position of light spots, which are generated by the pixel parts and serves as pixel units constituting an exposure region, on the exposure surface; and a pixel part selection unit that selects pixel parts to be used for the realization of the N-fold exposure based on the results of detection with the light spot position detection unit.

<35> The method for forming a permanent pattern according to any one of <29> to <34>, wherein the service pixel part specifying unit specifies on a row basis pixel parts to be used for the realization of the N-fold exposure.

<36> The method for forming a permanent pattern according to any one of <34> and <35>, wherein the light spot position detection unit specifies, an actual inclination angle θ′ between the direction of light spot columns on the exposure surface, in such a state that the exposure head has been inclined, and the scanning direction of the exposure head, based on at least two detected light spot positions, and the pixel part selection unit that selects pixel parts to be used so that an error between the actual inclination angle θ′ and the set inclination angle θ is absorbed.

<37> The method for forming a permanent pattern according to <36>, wherein the actual inclination angle θ′ is any one of the average value, the central value, the maximum value, and the minimum value of a plurality of actual inclination angles between the direction of light spot columns on the exposure surface, in such a state that the exposure head has been inclined, and the scanning direction of the exposure head.

<38> The method for forming a permanent pattern according to any one of <34> to <37>, wherein the pixel part selection unit derives a natural number T close to t satisfying t tan θ′=N (wherein N represents the number of times of exposure in the N-fold exposure) from actual inclination angle θ′, and selects pixel parts located in the first row to the tth row, in the pixel parts arranged in m rows (wherein m is a natural number of 2 or more), as pixel parts to be used.

<39> The method for forming a permanent pattern according to any one of <34> to <38>, wherein the pixel part selection unit derives a natural number T close to t satisfying t tan θ′=N (wherein N represents the number of times of exposure in the N-fold exposure) from actual inclination angle θ′, and selects, among pixel parts arranged in m rows (wherein m is a natural number of 2 or more), pixel parts located in the (T+1)th row to the mth row as pixel parts not be used and pixel parts, excluding the pixel parts not to be used, as pixel parts to be used.

<40> The method for forming a permanent pattern according to any one of <34> to <39>, wherein the pixel part selection unit is any one unit selected from

(1) a unit that, in a region including at least an overlapped exposure region on the exposure surface formed by a plurality of pixel part columns, selects pixel parts to be used so that, as compared with ideal N-fold exposure, the total area of a region of overexposure state and a region of underexposure state is minimized,
(2) a unit that, in a region including at least an overlapped exposure region on the exposure surface formed by a plurality of pixel part columns, selects pixel parts to be used so that, as compared with ideal N-fold exposure, the number of pixel units in a region of overexposure state is equal to the number pixel units in a region of underexposure state,
(3) a unit that, in a region including at least an overlapped exposure region on the exposure surface formed by a plurality of pixel part columns, selects pixel parts to be used so that, as compared with ideal N-fold exposure, the area of a region of overexposure state is minimized and no region of underexposure state exists, and
(4) a unit that, in a region including at least an overlapped exposure region on the exposure surface formed by a plurality of pixel part columns, selects pixel parts to be used so that, as compared with ideal N-fold exposure, the area of a region of underexposure state is minimized and no region of overexposure state exists.

<41> The method for forming a permanent pattern according to any one of <34> to <40>, wherein the pixel part selection unit is any one unit selected from

(1) a unit that, in a connection region between heads which is an overlapped exposure region on the exposure surface formed by a plurality of exposure heads, specifies pixel parts not to be used among pixel parts involved in the exposure of the connection region between the heads so that, as compared with ideal N-fold exposure, the total area of a region of overexposure state and a region of underexposure state is minimized, and the pixel parts excluding the pixel parts not to be used are selected as pixel parts to be used,
(2) a unit that, in a connection region between heads which is an overlapped exposure region on the exposure surface formed by a plurality of, exposure heads, specifies pixel parts not to be used among pixel parts involved in the exposure of the connection region between the heads so that, as compared with ideal N-fold exposure, the number of pixel units in a region of overexposure state is equal to the number pixel units in a region of underexposure state, and the pixel parts excluding the pixel parts not to be used are selected as pixel parts to be used,
(3) a unit that, in a connection region between heads which is an overlapped exposure region on the exposure surface formed by a plurality of pixel part columns, specifies pixel parts not to be used among pixel parts involved in the exposure of the connection region between the heads so that, as compared with ideal N-fold exposure, the area of a region of overexposure state is minimized while no region of underexposure state exists, and the pixel parts excluding the pixel parts not to be used are selected as pixel parts to be used, and
(4) a unit that, in a connection region between heads which is an overlapped exposure region on the exposure surface formed by a plurality of pixel part columns, specifies pixel parts not to be used among pixel parts involved in the exposure of the connection region between the heads so that, as compared with ideal N-fold exposure, the area of a region of underexposure state is minimized while no region of overexposure state exists, and the pixel parts excluding the pixel parts not to be used are selected as pixel parts to be used,

<42> The method for forming a permanent pattern according to <41>, wherein the pixel parts not to be used are specified on a row basis.

<43> The method for forming a permanent pattern according to any one of <29> to <42>, wherein, in order to specify pixel parts, to be used, in the service pixel part specifying unit, reference exposure is performed using only pixel parts constituting a pixel part column for each (N−1) column, wherein N is the number of times of exposure in the N-fold exposure, among usable pixel parts. In the method for forming a permanent pattern described in <43>, in order to specify pixel parts, to be used, in the service pixel part specifying unit, reference exposure is performed using only pixel parts constituting a pixel part column for each (N−1) column, wherein N is the number of times of exposure in the N-fold exposure, among usable pixel parts, whereby a simple pattern of substantially single imaging can be formed. Consequently, the pixel parts in the connection region between the heads can easily be specified.

<44> The method for forming a permanent pattern according to any one of <29> to <43>, wherein, in order to specify pixel parts, to be used, in the service pixel part specifying unit, reference exposure is performed using only pixel parts constituting a pixel part row for each 1/N row, wherein N is the number of times of exposure in the N-fold exposure, among usable pixel parts. In the method for forming a permanent pattern described in <44>, in order to specify pixel parts, to be used, in the service pixel part specifying unit, reference exposure is performed using only pixel parts constituting a pixel part column for each 1/N column, wherein N is the number of times of exposure in the N-fold exposure, among usable pixel parts, whereby a simple permanent pattern of substantially single imaging can be formed. Consequently, the pixel parts in the connection region between the heads can easily be specified.

<45> The method for forming a permanent pattern according to any one of <29> to <44>, wherein the service pixel part specifying unit comprises a slit and a photodetector as the light spot position detection unit and an arithmetic device, connected to the photodetector, as the pixel part selection unit.

<46> The method for forming a permanent pattern according to any one of <29> to <45>, wherein N in the N-fold exposure is a natural number of 3 to 7.

<47> The method for forming a permanent pattern according to any one of <29> to <46>, wherein the light modulation unit further comprises a pattern signal generation unit, which generates a control signal according to information about a pattern, and modulates the light applied from the light irradiation unit according to the control signal generated by the pattern signal generation unit. In the method for forming a permanent pattern described in <47>, since the light modulation unit comprises the pattern signal generation unit, the light applied from the light irradiation unit can be modulated according to the control signal generated by the pattern signal generation unit.

<48> The method for forming a permanent pattern according to any one of <29> to <47>, wherein the light modulation unit is a spatial light modulation element.

<49> The method for forming a permanent pattern according to any one of <48>, wherein the spatial light modulation element is a digital micromirror device (DMD).

<50> The method for forming a permanent pattern according to any one of <29> to <49>, wherein the pixel part is a micromirror.

<51> The method for forming a permanent pattern according to any one of <29> to <50>, which contains a transformation unit that transforms the pattern information so that the dimension of a predetermined part in a pattern represented by the pattern information is equal to the dimension of the corresponding part which can be realized by the specified pixel parts used.

<52> The method for forming a permanent pattern according to any one of <29> to <51>, wherein the light irradiation unit can combine two or more lights and can apply the combined lights. In the method for forming a permanent pattern described in <52>, since the light irradiation unit can combine two or more lights and can apply the combined lights, the exposure can be performed with exposure light having a high focal depth. Consequently, the exposure of the photosensitive film can be performed in a very high-definition manner. For example, when the photosensitive layer is then developed, a very high-definition permanent pattern can be formed.

<53> The method for forming a permanent pattern according to any one of <29> to <52>, wherein the light irradiation unit contains a plurality of lasers, a multi-mode optical fiber, and an integrated optical system that collects laser beams applied from each of the plurality of lasers and converges them on the multi-mode optical fiber. In the method for pattern formation described in <53>, in the light irradiation unit, since the integrated optical system can collect laser beams applied from each of the plurality of lasers and can converge them on the multi-mode optical fiber, the exposure can be performed by exposure light having a high focal depth. Consequently, the exposure of the photosensitive film can be performed in a very high-definition manner. For example, when the photosensitive layer is then developed, a very high-definition pattern can be formed.

<54> The method for forming a permanent pattern according to any one of <24> to <53>, wherein, after the exposure, the photosensitive layer is developed. In the method for forming a permanent pattern described in <54>, since the photosensitive layer is developed after the exposure, a high-definition pattern can be formed.

<55> The method for forming a permanent pattern according to <54>, wherein, after the development, a permanent pattern is formed.

<56> The method for forming a permanent pattern according to <55>, wherein, after the development, the photosensitive layer is subjected to curing treatment.

<57> The method for forming a permanent pattern according to <56>, wherein the curing treatment is at least one of whole image exposure treatment and complete heating treatment at 120° C. to 200° C.

<58> The method for forming a permanent pattern according to any one of <56> to <57>, wherein at least one of a protective film, an interlayer insulating film, and a solder resist pattern.

<59> A permanent pattern, which is formed by the method for pattern formation according to any one of <24> to <58>. Since the permanent pattern described in <59> is formed by the method for forming a permanent pattern, the technique is advantageous in the a smooth photosensitive layer can be formed, the storage stability is good, a high definition can be realized, and high-density mounting, for example, on multilayered wiring boards for semiconductors and components and build-up wiring boards can be realized.

<60> The pattern according to <59>, which is at least one of a protective film, an interlayer insulating film, and a solder resist pattern. Since the permanent pattern described in <60> is at least one of a protective film, an interlayer insulating film, and a solder resist pattern, by virtue of the insulating properties, heat resistance and the like of the film, the wiring can be protected against external impact, bending and the like.

<61> A printed board containing a permanent pattern formed by the method for forming a permanent pattern according to any one of <24> to <58>.

The present invention can provide a photosensitive composition, which can solve the conventional problems, can form a smooth photosensitive layer, has good storage stability, and exhibits high sensitivity when a blue-violet laser exposure system is used, a photosensitive film, a method for forming a permanent pattern using the photosensitive composition, and a printed board with a permanent pattern formed by the method for forming a permanent pattern

### BRIEF DESCRIPTION OF DRAWINGS

FIG. 1A is a top view of one example of a detailed construction of an exposure head;

FIG. 1B is a side view of one example of a detailed construction of an exposure head;

FIG. 2 is a partially enlarged view of one example of DMD of a pattern forming apparatus;

FIG. 3 is an explanatory view of an example of unevenness of a pattern on an exposure surface when there are misregistration in relative position between adjacent exposure heads and exposure head mounting angle errors; and

FIG. 4 is an explanatory view for explaining exposure using only imaging parts for use selected in the example in FIG. 3.

### BEST MODE FOR CARRYING OUT THE INVENTION

### Photosensitive Film

The photosensitive film of the present invention includes a support and a photosensitive layer provided on the support. Preferably, a protective film is provided on the photosensitive layer. If necessary, other constructions may be adopted.

The photosensitive film is not particularly limited and can be suitably selected according to the purpose as long as the photosensitive film includes the support and the photosensitive layer provided in that order. Examples of the form of the photosensitive film include one including an oxygen-barrier layer, a photosensitive layer, and a protective film provided in that order on a support and one including a cushion layer, an oxygen-barrier layer, a photosensitive layer, and a protective film provided in that order on a support. The photosensitive layer may have a single-layer structure or a multilayer structure.

### [Support]

The support is not particularly limited and may be suitably selected in accordance with the intended use. Preferably, the photosensitive layer can be separated from the support, and the support is highly transparent and has higher surface smoothness.

Preferably, the support is formed from a transparent synthetic resin; examples of the synthetic resin include various plastic films such as polyethylene terephthalate, polyethylene naphthalate, polypropylene, polyethylene, triacetyl cellulose, diacetyl cellulose, polyalkyl(meth)acrylate, poly(meth)acrylate copolymer, polyvinyl chloride, polyvinyl alcohol, polycarbonate, polystyrene, cellophane, polyvinylidene chloride copolymer, polyamide, polyimide, vinylchloride-vinylacetate copolymer, polytetrafluoroethylene, polytrifluoroethylene, cellulose film, and nylon film. Among these, polyethylene terephthalate is particularly preferable. Each of these synthetic resins may be used alone or in combination.

For the support, the supports described in Japanese Patent Application Laid-Open (JP-A) Nos. 04-208940, 05-80503, 05-173320, and 05-72724 may also be used.

The thickness of the support is not particularly limited and may be suitably selected in accordance with the intended use; the thickness is preferably 4 μm to 300 μm, and more preferably 5 μm to 175 μm.

The shape of the support is not particularly limited and may be suitably selected in accordance with the intended use, however, it is preferable that the support is formed in a long shape. The length of the support is not particularly limited and may be 10 m to 20,000 m, for example.

### [Photosensitive Layer]

The photosensitive layer is formed from a photosensitive composition. The photosensitive composition contains a binder, a polymerizable compound, a photopolymerization initiator, a thermal crosslinking resin (a thermal crosslinking agent), a colorant (a pigment), an inorganic filler, a heat curing accelerator, and optionally suitably selected other components.

Preferably, the photosensitive layer has a thickness of 5 μm to 100 μm and has an absorbance of 1 or less at a wavelength of 410±5 nm.

### [Binder]

Binders includes polymer compounds having an optionally hetero ring-containing aromatic group on a side chain thereof and an ethylenically unsaturated bond on a side chain thereof. Preferably, the polymer compounds have a carboxyl group on a side chain thereof.

Preferably, the binder is a compound that is insoluble in water and is swellable with or dissolved in an aqueous alkaline solution.

### —Optionally Hetero Ring-Containing Aromatic Group—

Examples of the optionally hetero ring-containing aromatic group (hereinafter sometimes referred to simply as “aromatic group”) include a benzene ring, two or three benzene rings that together form a condensed ring, and a benzene ring that, together with a five-membered unsaturated ring, forms a condensed ring.

Specific examples of such aromatic groups include a phenyl group, a naphthyl group, an anthryl group, a phenanthryl group, an indenyl group, an acenaphthenyl group, a fluorenyl group, a benzopyrrole ring group, a benzofuran ring group, a benzothiophene ring group, a pyrazole ring group, an isoxazole ring group, an isothiazole ring group, an indazole ring group, a benzisoxazole ring group, a benzoisothiazole ring group, an imidazole ring group, an oxazole ring group, a thiazole ring group, a benzimidazole ring group, a benzoxazole ring group, a benzothiazole ring group, a pyridine ring group, a quinoline ring group, an isoquinoline ring group, a pyridazine ring group, a pyrimidine ring group, a pyrazine ring group, a phthalazine ring group, a quinazoline ring group, a quinoxaline ring group, an aciridine ring group, a phenanthridine ring group, a carbazole ring group, a purine ring group, a pyran ring group, a piperidine ring group, a piperazine ring group, an indole ring group, an indolizine ring group, a chromene ring group, a cinnoline ring group, an acridine ring group, a phenothiazine ring group, a tetrazole ring group, a triazine ring group. Among them, a hydrocarbon aromatic group is preferred. A phenyl group and a naphthyl group are more preferred.

The aromatic group is optionally substituted, and examples of substituents include halogen atom, optionally substituted amino group, alkoxycarbonyl group, hydroxyl group, ether group, thiol group, thioether group, silyl group, nitro group, cyano group, optionally substituted alkyl group, optionally substituted alkenyl group, optionally substituted alkynyl group, optionally substituted aryl group, and optionally substituted heterocyclic group.

Preferable examples of the alkyl group include a straight-chain, branched and cyclic alkyl group having 1 to 20 carbon atoms.

Specific examples thereof include methyl group, ethyl group, propyl group, butyl group, pentyl group, hexyl group, heptyl group, octyl group, nonyl group, decyl group, undecyl group, dodecyl group, tridecyl group, hexadecyl group, octadecyl group, eicosyl group, isopropyl group, isobutyl group, sec-butyl group, tert-butyl group, isopentyl group, neopentyl group, 1-methylbutyl group, isohexyl group, 2-ethylhexyl group, 2-methylhexyl group, cyclohexyl group, cyclopentyl group and 2-norbornyl group. Of these, a straight-chain alkyl group having 1 to 12 carbon atoms, a branched alkyl group having 3 to 12 carbon atoms and a cyclic alkyl group having 5 to 10 carbon atoms are preferable.

The substituent group for the alkyl groups is a group containing a monovalent nonmetal atom group excluding a hydrogen atom; and preferable examples thereof include halogen atoms (—F, —Br, —Cl, and —I); hydroxyl, alkoxy, aryloxy, mercapto, alkylthio, arylthio, alkyldithio, aryldithio, amino, N-alkylamino, N,N-dialkylamino, N-arylamino, N,N-diarylamino, N-alkyl-N-arylamino, acyloxy, carbamoyloxy, N-alkylcarbamoyloxy, N-arylcarbamoyloxy, N,N-dialkylcarbamoyloxy, N,N-diarylcarbamoyloxy, N-alkyl-N-arylcarbamoyloxy, alkylsulfoxy, arylsulfoxy, acylthio, acylamino, N-alkylacylamino, N-arylacylamino, ureido, N′-alkylureido, N′,N′-dialkylureido, N′-arylureido, N′,N′-diarylureido, N′-alkyl-N′-arylureido, N′-alkylureido, N-arylureido, N′-alkyl-N-alkylureido, N′-alkyl-N-arylureido, N′,N′-dialkyl-N-alkylureido, N′,N′-dialkyl-N-arylureido, N′-aryl-N-alkylureido, N′-aryl-N-arylureido, N′,N′-diaryl-N-alkylureido, N′,N′-diaryl-N-arylureido, N′-alkyl-N′-aryl-N-alkylureido, N′-alkyl-N′-aryl-N-arylureido, alkoxycarbonylamino, aryloxycarbonylamino, N-alkyl-N-alkoxycarbonylamino, N-alkyl-N-aryloxycarbonylamino, N-aryl-N-alkoxycarbonylamino, N-aryl-N-aryloxycarbonylamino, formyl, acyl, carboxyl, alkoxycarbonyl, aryloxycarbonyl, carbamoyl, N-alkylcarbamoyl, N,N-dialkylcarbamoyl, N-arylcarbamoyl, N,N-diarylcarbamoyl, N-alkyl-N-arylcarbamoyl, alkylsulfinyl, arylsulfinyl, alkylsulfonyl, arylsulfonyl, sulfo (—SO₃H) and its conjugate base (referred to as sulfonato), alkoxysulfonyl, aryloxysulfonyl, sulfinamoyl, N-alkylsulfinamoyl, N,N-dialkylsulfinamoyl, N-arylsulfinamoyl, N,N-diarylsulfinamoyl, N-alkyl-N-arylsulfinamoyl, sulfamoyl, N-alkylsulfamoyl, N,N-dialkylsulfamoyl, N-arylsulfamoyl, N,N-diarylsulfamoyl, N-alkyl-N-arylsulfamoyl, phosphono (—PO₃H₂) and its conjugate base (referred to as phosphonato), dialkylphosphono (—PO₃(alkyl)₂) (hereinafter, alkyl means an alkyl group), diarylphosphono (—PO₃(aryl)₂) (hereinafter, aryl means an aryl group), alkylarylphosphono (—PO₃(alkyl)(aryl)), monoalkylphosphono (—PO₃H(alkyl)) and its conjugate base (referred to as alkylphosphonato), monoarylphosphono (—PO₃H(aryl)) and its conjugate base (referred to as arylphosphonato), phosphonooxy (—OPO₃H₂) and its conjugate base (referred to as phosphonatooxy), dialkylphosphonooxy (—OPO₃H(alkyl)₂), diarylphosphonooxy (—OPO₃(aryl)₂), alkylarylphosphonooxy (—OPO₃(alkyl)(aryl)), monoalkylphosphonooxy (—OPO₃H(alkyl)) and its conjugate base (referred to as alkylphosphonatooxy), monoarylphosphonooxy (—OPO₃H(aryl)) and its conjugate base (referred to as arylphosphonatooxy), cyano, nitro, aryl, alkenyl, alkynyl, heterocyclic, and silyl groups.

Specific examples of the alkyl groups in these substituent groups include the alkyl groups described above.

Specific examples of the aryl groups in these substituent groups include phenyl, biphenyl, naphthyl, toluoyl, xylyl, mesityl, cumenyl, chlorophenyl, bromophenyl, chloromethylphenyl, hydroxyphenyl, methoxyphenyl, ethoxyphenyl, phenoxyphenyl, acetoxyphenyl, benzyoloxyphenyl, methylthiophenyl, phenylthiophenyl, methylaminophenyl, dimethylaminophenyl, acetylaminophenyl, carboxyphenyl, methoxycarbonylphenyl, ethoxyphenylcarbonyl, phenoxycarbonylphenyl, N-phenylcarbamoylphenyl, cyanophenyl, sulfophenyl, sulfonatophenyl, phosphonophenyl, and phosphonatophenyl groups.

Examples of the alkenyl groups in these substituent groups include vinyl, 1-propenyl, 1-butenyl, cinnamyl, and 2-chloro-1-ethenyl groups.

Examples of the alkynyl groups in these substituent groups include ethynyl, 1-propynyl, 1-butynyl, and trimethylsilylethynyl groups

Examples of R⁰¹ in the acyl group (R⁰¹CO—) in these substituent groups include a hydrogen atom, and the alkyl and aryl groups described above.

Among these substituent groups, still more preferable are halogen atoms (—F, —Br, —Cl, and —I); and alkoxy, aryloxy, alkylthio, arylthio, N-alkylamino, N,N-dialkylamino, acyloxy, N-alkylcarbamoyloxy, N-arylcarbamoyloxy, acylamino, formyl, acyl, carboxyl, alkoxycarbonyl, aryloxycarbonyl, carbamoyl, N-alkylcarbamoyl, N,N-dialkylcarbamoyl, N-arylcarbamoyl, N-alkyl-N-arylcarbamoyl, sulfo, sulfonato, sulfamoyl, N-alkylsulfamoyl, N,N-dialkylsulfamoyl, N-arylsulfamoyl, N-alkyl-N-arylsulfamoyl, phosphono, phosphonato, dialkylphosphono, diarylphosphono, monoalkylphosphono, alkylphosphonato, monoarylphosphono, arylphosphonato, phosphonooxy, phosphonatooxy, aryl, and alkenyl groups.

Examples of the heterocyclic groups in these substituent groups include a pyridyl group and a piperidinyl group. Examples of the silyl groups in these substituent groups include a trimethylsilyl group.

On the other hand, the alkylene group in the alkyl group is, for example, a bivalent organic residue group derived from alkyl group having 1 to 20 carbon atoms described above by removing one hydrogen atom on the alkyl group; and preferable examples thereof include straight-chain alkylene groups having 1 to 12 carbon atoms, branched alkylene groups having 3 to 12 carbon atoms, and cyclic alkylene groups having 5 to 10 carbon atoms.

Specific examples of the preferred substituted alkyl groups obtained by binding the alkylene group to a substituent group include chloromethyl, bromomethyl, 2-chloroethyl, trifluoromethyl, methoxymethyl, isopropoxymethyl, butoxymethyl, s-butoxybutyl, methoxyethoxyethyl, allyloxymethyl, phenoxymethyl, methylthiomethyl, tolylthiomethyl, pyridylmethyl, tetramethylpiperidinylmethyl, N-acetyl-tetramethylpiperidinylmethyl, trimethylsilylmethyl, methoxyethyl, ethylaminoethyl, diethylaminopropyl, morpholinopropyl, acetyloxymethyl, benzoyloxymethyl, N-cyclohexylcarbamoyloxyethyl, N-phenylcarbamoyloxyethyl, acetylaminoethyl, N-methyl-benzoylaminopropyl, 2-oxoethyl, 2-oxopropyl, carboxypropyl, methoxycarbonylethyl, allyloxycarbonylbutyl, chlorophenoxycarbonylmethyl, carbamoylmethyl, N-methylcarbamoylethyl, N,N-dipropylcarbannoylmethyl, N-(methoxyphenyl)carbamoylethyl, N-methyl-N-(sulfophenyl)carbamoylmethyl, sulfobutyl, sulfonatobutyl, sulfamoylbutyl, N-ethylsulfamoylmethyl, N,N-dipropylsulfamoylpropyl, N-tolylsulfamoylpropyl, N-methyl-N-(phosphonophenyl)sulfamoyloctyl, phosphonobutyl, phosphonatohexyl, diethylphosphonobutyl, diphenylphosphonopropyl, methylphosphonobutyl, methylphosphonatobutyl, tolylphosphonohexyl, tolylphosphonatohexyl, phosphonooxypropyl, phosphonatooxybutyl, benzyl, phenethyl, α-methylbenzyl, 1-methyl-1-phenylethyl, p-methylbenzyl, cinnamyl, allyl, 1-propenylmethyl, 2-butenyl, 2-methylallyl, 2-methylpropenylmethyl, 2-propynyl, 2-butynyl, and 3-butynyl groups.

Preferable examples of the aryl groups include groups having a benzene ring, a condensed ring of 2 to 3 benzene rings and a condensed ring of a benzene ring and a five-membered unsaturated ring.

Specific examples of the aryl groups include phenyl, naphthyl, anthryl, phenanthryl, indenyl, acenaphthenyl, and fluorenyl groups; and among these, phenyl and naphthyl groups are more preferable.

The aryl group may have a substituent group (hereinafter, also referred to as a substituted aryl group), and examples thereof include an aryl group described above having a monovalent nonmetal atomic group excluding a hydrogen atom as the substituent group on the ring carbon atom of the aryl group.

Preferable examples of the substituent groups for the alkyl groups include the alkyl and substituted alkyl groups described above and the substituent groups described above for the alkyl groups.

Specific examples of the substituted aryl groups include biphenyl, toluoyl, xylyl, mesityl, cumenyl, chlorophenyl, bromophenyl, fluorophenyl, chloromethylphenyl, trifluoromethylphenyl, hydroxyphenyl, methoxyphenyl, methoxyethoxyphenyl, allyloxyphenyl, phenoxyphenyl, methylthiophenyl, tolylthiophenyl, ethylaminophenyl, diethylaminophenyl, morpholinophenyl, acetyloxyphenyl, benzoyloxyphenyl, N-cyclohexylcarbamoyloxyphenyl, N-phenylcarbamoyloxyphenyl, acetylaminophenyl, N-methylbenzoylaminophenyl, carboxyphenyl, methoxycarbonylphenyl, allyloxycarbonylphenyl, chlorophenoxycarbonylphenyl, carbamoylphenyl, N-methylcarbamoylphenyl, N,N-dipropylcarbamoylphenyl, N-(methoxyphenyl)carbamoylphenyl, N-methyl-N-(sulfophenyl)carbamoylphenyl, sulfophenyl, sulfonatophenyl, sulfamoylphenyl, N-ethylsulfamoylphenyl, N,N-dipropylsulfamoylphenyl, N-tolylsulfamoylphenyl, N-methyl-N-(phosphonophenyl)sulfamoylphenyl, phosphonophenyl, phosphonatophenyl, diethylphosphonophenyl, diphenylphosphonophenyl, methylphosphonophenyl, methylphosphonatophenyl, tolylphosphonophenyl, tolylphosphonatophenyl, allylphenyl, 1-propenylmethylphenyl, 2-butenylphenyl, 2-methylallylphenyl, 2-methylpropenylphenyl, 2-propynylphenyl, 2-butynylphenyl, and 3-butynylphenyl groups.

The alkenyl group (—C(R⁰²)═C(R⁰³)(R⁰⁴)), and the alkynyl group (—C≡C(R⁰⁵)) may be those where R⁰², R⁰³, R⁰⁴ or R⁰⁵ is a group containing a monovalent nonmetallic atom group.

Preferred examples of R⁰², R⁰³, R⁰⁴ and R⁰⁵ include a hydrogen atom, a halogen atom, an alkyl group, a substituted alkyl group, an aryl group and a substituted aryl group. Specific examples thereof include those described above and more preferred examples of R⁰², R⁰³, R⁰⁴ and R⁰⁵ include a hydrogen atom, a halogen atom and a linear, branched or cyclic alkyl group having from 1 to 10 carbon atoms.

Specific examples of the preferred alkenyl group and the alkynyl group include a vinyl group, a 1-propenyl group, a 1-butenyl group, a 1-pentenyl group, a 1-hexenyl group, a 1-octenyl group, a 1-methyl-1-propenyl group, a 2-methyl-1-propenyl group, a 2-methyl-1-butenyl group, a 2-phenyl-1-ethenyl group, a 2-chloro-1-ethenyl group, an ethynyl group, a 1-propynyl group, a 1-butynyl group and a phenylethynyl group.

Specific examples of the heterocyclic groups include a pyridyl group exemplified as the substituent group in the substituted alkyl group.

The oxy group (R⁰⁶O—) includes those where R⁰⁶ is a group containing a monovalent nonmetallic atom group exclusive of a hydrogen atom.

Examples of the oxy group include an alkoxy group, an aryloxy group, an acyloxy group, a carbamoyloxy group, an N-alkylcarbamoyloxy group, an N-arylcarbamoyloxy group, an N,N-dialkylcarbamoyloxy group, an N,N-diarylcarbamoyloxy group, an N-alkyl-N-arylcarbamoyloxy group, an alkylsulfoxy group, an arylsulfoxy group, a phosphonooxy group and a phosphonatooxy group.

The alkyl group and the aryl group in these groups include those described above for the alkyl group and the substituted alkyl group and those for the aryl group and the substituted aryl group, respectively. The acyl group (R⁰⁷CO—) in the acyloxy group include those where R⁰⁷ is the alkyl group, substituted alkyl group, aryl group or substituted aryl group described above. Among these substituents, more preferred are an alkoxy group, an aryloxy group, an acyloxy group and an arylsulfoxy group.

Specific examples of the preferred oxy groups include a methoxy group, an ethoxy group, a propyloxy group, an isopropyloxy group, a butyloxy group, a pentyloxy group, a hexyloxy group, a dodecyloxy group, a benzyloxy group, an allyloxy group, a phenethyloxy group, a carboxyethyloxy group, a methoxycarbonylethyloxy group, an ethoxycarbonylethyloxy group, a methoxyethoxy group, a phenoxyethoxy group, a methoxyethoxyethoxy group, an ethoxyethoxyethoxy group, a morpholinoethoxy group, a morpholinopropyloxy group, an allyloxyethoxyethoxy group, a phenoxy group, a tolyloxy group, a xylyloxy group, a mesityloxy group, a mesityloxy group, a cumenyloxy group, a methoxyphenyloxy group, an ethoxyphenyloxy group, a chlorophenyloxy group, a bromophenyloxy group, an acetyloxy group, a benzoyloxy group, a naphthyloxy group, a phenylsulfonyloxy group, a phosphonooxy group and a phosphonatooxy group.

The amino group which may contain an amide group (R⁰⁸NH—, (R⁰⁹)(R⁰¹⁰)N—) includes those where R⁰⁸, R⁰⁹ and R⁰¹⁰ each is a group containing a monovalent nonmetallic atom group exclusive of a hydrogen atom. R⁰⁹ and R⁰¹⁰ may be combined to form a ring.

Preferred examples of the amino group include an N-alkylamino group, an N,N-dialkylamino group, an N-arylamino group, an N,N-diarylamino group, an N-alkyl-N-arylamino group, an acylamino group, an N-alkylacylamino group, an N-arylacylamino group, a ureido group, an N′-alkylureido group, an N′,N′-dialkylureido group, an N′-arylureido group, an N′,N′-diarylureido group, an N′-alkyl-N′-arylureido group, an N-alkylureido group, an N-arylureido group, an N′-alkyl-N-alkylureido group, an N′-alkyl-N-arylureido group, an N′,N′-dialkyl-N-alkylureido group, an N′-alkyl-N′-arylureido group, an N′,N′-dialkyl-N-alkylureido group, an N′,N′-dialkyl-N′-arylureido group, an N′-aryl-N-alkylureido group, an N′-aryl-N-arylureido group, an N′,N′-diaryl-N-alkylureido group, an N′,N′-diaryl-N-arylureido group, an N′-alkyl-N′-aryl-N-alkylureido group, an N′-alkyl-N′-aryl-N-arylureido group, an alkoxycarbonylamino group, an aryloxycarbonylamino group, an N-alkyl-N-alkoxycarbonylamino group, an N-alkyl-N-aryloxycarbonylamino group, an N-aryl-N-alkoxycarbonylamino group and an N-aryl-N-aryloxycarbonylamino group. The alkyl group and the aryl group in these groups include those described above for the alkyl group and the substituted alkyl group and those for the aryl group and the substituted aryl group, respectively, and R⁰⁷ of the acyl group (R⁰⁷CO—) in the acylamino group, the N-alkylacylamino group and the N-arylacylamino group are the same as described above. Among these, more preferred are an N-alkylamino group, an N,N-dialkylamino group, an N-arylamino group and an acylamino group.

Specific examples of the preferred amino groups include a methylamino group, an ethylamino group, a diethylamino group, a morpholino group, a piperidino group, a pyrrolidino group, a phenylamino group, a benzoylamino group and an acetylamino group.

The sulfonyl group (R⁰¹¹—SO₂—) include those where R⁰¹¹ is a group containing a monovalent nonmetallic atom group.

More preferred examples thereof include an alkylsulfonyl group and an arylsulfonyl group. The alkyl group and the aryl group in these groups include those described above for the alkyl group and the substituted alkyl group and those for the aryl group and the substituted aryl group, respectively.

Specific examples of the sulfonyl group include a butylsulfonyl group, a phenylsulfonyl group and a chlorophenylsulfonyl group.

The sulfonato group (—SO₃—) is a conjugated base anion group of a sulfo group (—SO₃H) as described above, and generally, the sulfonato group is preferably used together with a counter cation.

As the counter cation, those generally known may be suitably selected in accordance with the intended use. Examples of the counter cation include various oniums (e.g., ammoniums, sulfoniums, phosphoniums, iodoniums, aziniums) and metal ions (e.g., Na⁺, K⁺, Ca²⁺, Zn²⁺).

The carbonyl group (R⁰¹³—CO—) includes those where R⁰¹³ is a group containing a monovalent nonmetallic atom group.

Preferred examples of the carbonyl group include a formyl group, an acyl group, a carboxyl group, an alkoxycarbonyl group, an aryloxycarbonyl group, a carbamoyl group, an N-alkylcarbamoyl group, an N,N-dialkylcarbamoyl group, an N-arylcarbamoyl group, an N,N-diarylcarbamoyl group and an N-alkyl-N′-arylcarbamoyl group. The alkyl group and the aryl group in these groups include those described above for the alkyl group and the substituted alkyl group and those for the aryl group and the substituted aryl group, respectively.

Among these, more preferred are a formyl group, an acyl group, a carboxyl group, an alkoxycarbonyl group, an aryloxycarbonyl group, a carbamoyl group, an N-alkylcarbamoyl group, an N,N-dialkylcarbamoyl group and an N-arylcarbamoyl group, still more preferred are a formyl group, an acyl group, an alkoxycarbonyl group and an aryloxycarbonyl group.

Specific examples of preferred carbonyl groups include a formyl group, an acetyl group, a benzoyl group, a carboxyl group, a methoxycarbonyl group, an ethoxycarbonyl group, an allyloxycarbonyl group, a dimethylaminophenyl ether carbonyl group, a methoxycarbonylmethoxycarbonyl group, an N-methylcarbamoyl group, an N-phenylcarbamoyl group, an N,N-diethylcarbamoyl group and a morpholinocarbonyl group.

The sulfinyl group (R⁰¹⁴—SO—) includes those where R⁰¹⁴ is a group containing a monovalent nonmetallic atom group.

Preferred examples thereof include an alkylsulfinyl group, an arylsulfinyl group, a sulfinamoyl group, an N-alkylsulfinamoyl group, an N,N-dialkylsulfinamoyl group, an N-arylsulfinamoyl group, an N,N-diarylsulfinamoyl group and an N-alkyl-N-arylsulfinamoyl group. The alkyl group and the aryl group in these groups include those described above for the alkyl group and the substituted alkyl group and those for the aryl group and the substituted aryl group, respectively. Among these, more preferred are an alkylsulfinyl group and an arylsulfinyl group.

Specific examples of the substituted sulfinyl group include a hexylsulfinyl group, a benzylsulfinyl group and a tolylsulfinyl group.

The phosphono group is a phosphono group on which one or two hydroxyl groups are substituted by an organic oxo group. Preferred examples thereof include a dialkylphosphono group, a diarylphosphono group, an alkylarylphosphono group, a monoalkylphosphono group and a monoarylphosphono group, which are described above. Of these, more preferred are a dialkylphosphono group and a diarylphosphono group.

Specific examples thereof include diethylphosphono group, a dibutylphosphono group and a diphenylphosphono group.

The phosphonato group (—PO₃H₂—, —PO₃H—) is a conjugated base anion group derived from the acid first dissociation or acid second dissociation of a phosphono group (—PO₃H₂) as described above, and generally, the phosphonato group is preferably used together with a counter cation. As the counter cation, those generally known may be suitably selected in accordance with the intended use. Examples of the counter cation include various oniums (e.g., ammoniums, sulfoniums, phosphoniums, iodoniums, aziniums) and metal ions (e.g., Na⁺, K⁺, Ca²⁺, Zn²⁺).

The phosphonato group is a conjugated base anion group of the above-described phosphono group in which one of the hydroxyl groups is substituted by an organic oxo group. Specific examples thereof include conjugated bases of a monoalkylphosphono group (—PO₃H(alkyl)) or a monoarylphosphono group (—PO₃H(aryl)) described above.

A polymer compound containing the aromatic group can be produced by polymerizing one or more aromatic group-containing radical polymerizable compounds and optionally one or more other radical polymerizable compounds as a comonomer component by a conventional radical polymerization method.

Conventional radical polymerization methods include, for example, suspension polymerization and solution polymerization.

Preferred aromatic group-containing radical polymerizable compounds include, for example, compounds represented by structural formula (A) and compounds represented by structural formula (B).

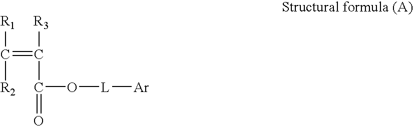

In structural formula (A), R₁, R₂, and R₃ represent a hydrogen atom or a monovalent organic group; L represents an organic group and may be absent; and Ar represents an aromatic group optionally containing a hetero ring.

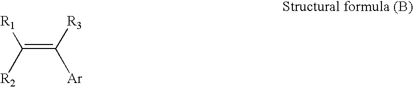

In structural formula (B), R₁, R₂, R₃, and Ar are as defined in structural formula (A).

The organic group indicated by L is, for example, a polyvalent organic group of a nonmetallic atom, and examples thereof include organic groups including 1 to 60 carbon atoms, 0 to 10 nitrogen atoms, 0 to 50 oxygen atoms, 1 to 100 hydrogen atoms, and 0 to 20 sulfur atoms.

More specifically, for example, a combination of the following structural units, polyvalent naphthalene, and polyvalent anthracene may be mentioned as the organic group indicated by L.

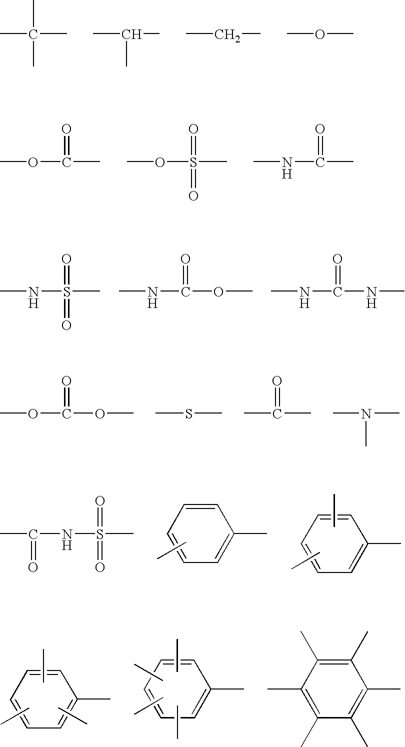

The linking group for L may have a substituent. Such substituents include those described above, i.e., a halogen atom, a hydroxyl group, a carboxyl group, a sulfonato group, a nitro group, a cyano group, an amide group, an amino group, an alkyl group, an alkenyl group, an alkynyl group, an aryl group, a substituted oxy group, a substituted sulfonyl group, a substituted carbonyl group, a substituted sulfinyl group, a sulfo group, a phosphono group, a phosphonato group, a silyl group, and a heterocyclic group.

Compounds represented by structural formula (A) is more preferred than compounds represented by structural formula (B) from the viewpoint of sensitivity. Among compounds represented by structural formula (A), those having a linking group are preferred from the viewpoint of stability. The organic group indicated by L is preferably an alkylene group having 1 to 4 carbon atoms from the viewpoint of the removal (developability) of non-image areas.

Compounds represented by structural formula (A) are converted to compounds including structural units represented by structural formula (I). Compounds represented by structural formula (B) are converted to compounds including structural units represented by structural formula (II). Structural units represented by structural formula (I) are more preferred than structural units represented by structural formula (II) from the viewpoint of storage stability.

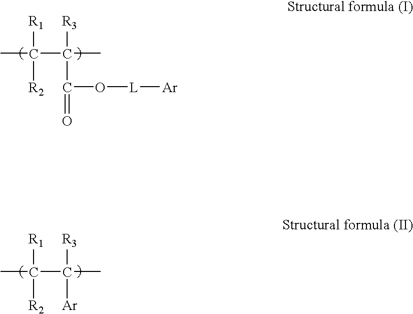

In structural formulae (I) and (II), R₁, R₂, R₃, and Ar are as defined in structural formulae (A) and (B).

In structural formulae (I) and (II), from the viewpoints of the removal (developability) of non-image areas, preferably, R₁ and R₂ represent a hydrogen atom while R₃ represents a methyl group.

Preferably, L in structural formula (I) represents an alkylene group having 1 to 4 carbon atoms from the viewpoint of the removal (developability) of non-image areas.

Compounds represented by structural formula (A) and compounds represented by structural formula (B) include, but are not limited to, for example, the following compounds (1) to (30).

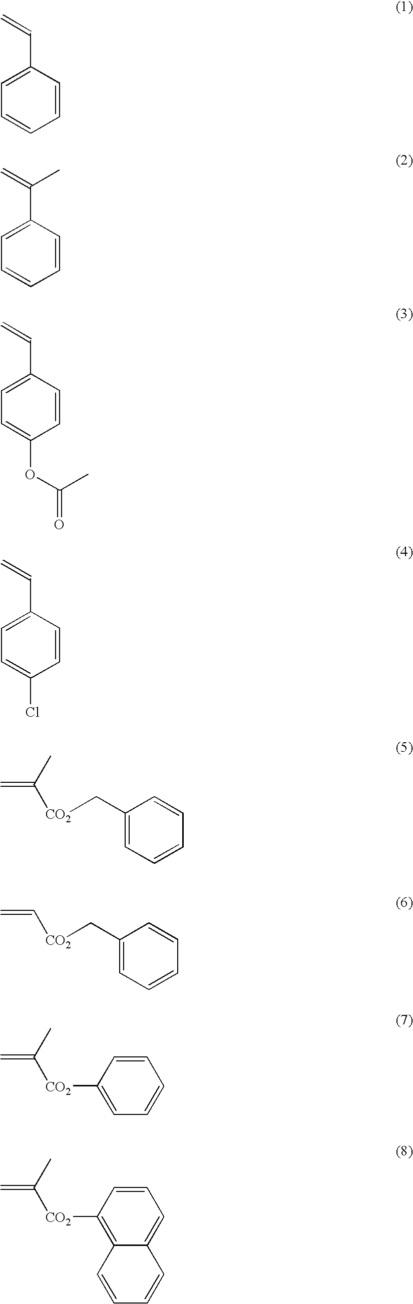

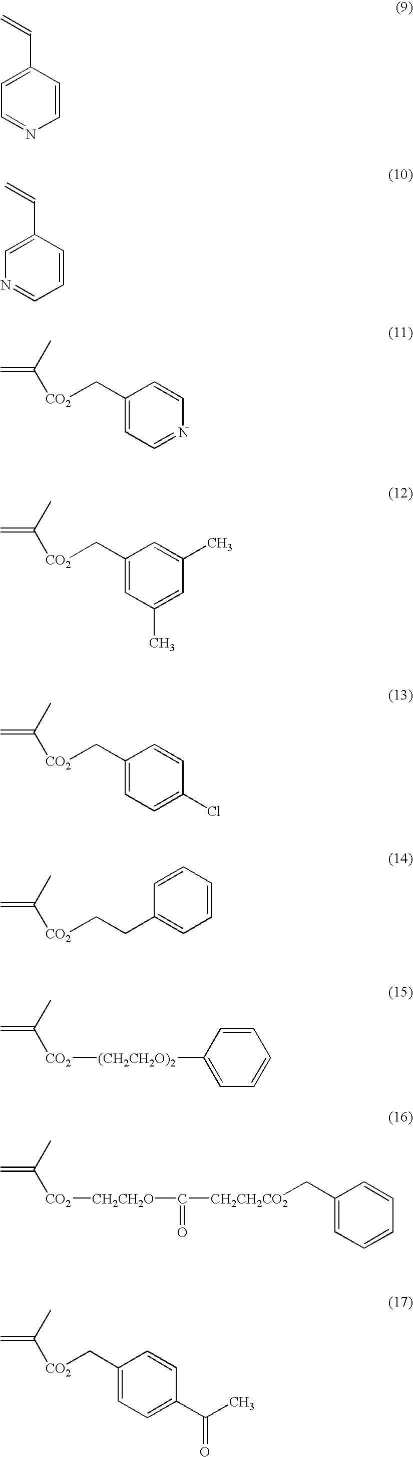

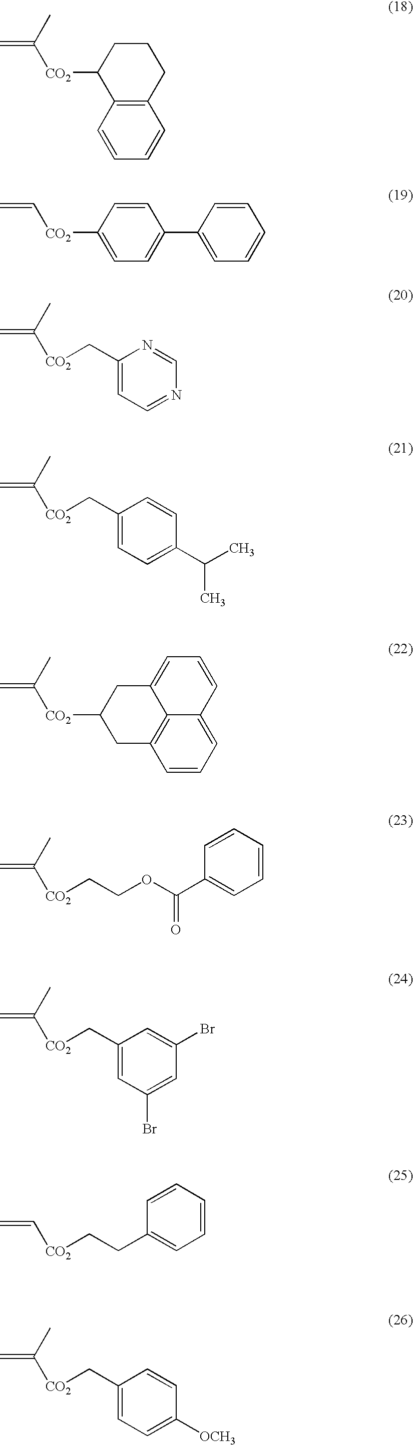

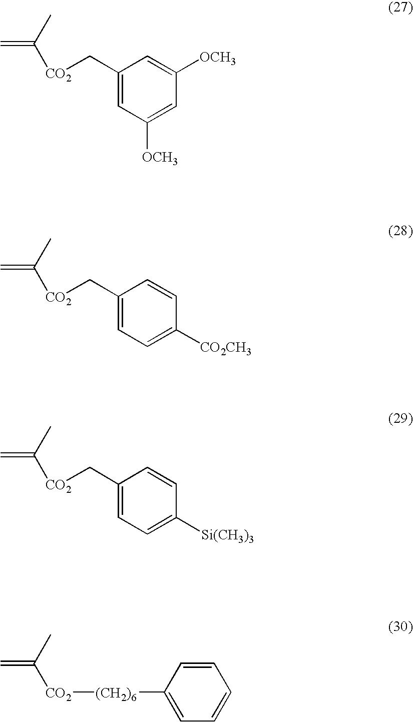

Among the exemplified compounds (1) to (30), compounds (5), (6), (11), (14), and (28) are preferred, and compounds (5) and (6) are more preferred from the viewpoints of storage stability and developability.

The content of the optionally hetero ring-containing aromatic group in the binder is not particularly limited. Preferably, however, when the whole structural unit of the polymer compound is presumed to be 100% by mole, the content of the structural unit represented by structural formula (I) is 20% by mole or more, more preferably 30% by mole to 45% by mole. When the content is less than 20% by mole, the storage stability is sometimes lowered. On the other hand, when the content is more than 45% by mole, the developability is sometimes lowered.

### —Ethylenically Unsaturated Bond—

The ethylenically unsaturated bond is not particularly limited and may be suitably selected according to the purpose. For example, ethylenically unsaturated bonds represented by structural formulae (III) to (V) are preferred.

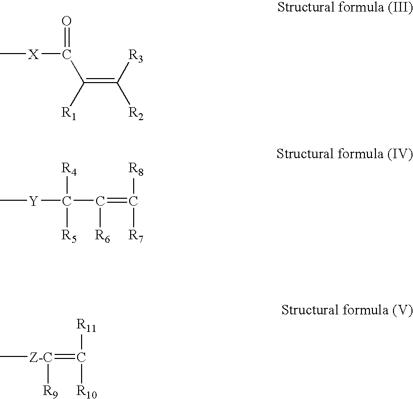

In the structural formulae (III) to (V), R₁ to R₃ and R₅ to R₁₁ each independently represent a monovalent organic group; X and Y each independently represent an oxygen atom, a sulfur atom, or —N—R₄; Z represents an oxygen atom, a sulfur atom, —N—R₄, or a phenylene group; and R₄ represents a hydrogen atom or a monovalent organic group.

In structural formula (III), preferably R₁ₛ each independently represent, for example, a hydrogen atom, an optionally substituted alkyl group, more preferably a hydrogen atom or a methyl group from the viewpoint of high radical reactivity.

R₂ and R₃ each independently represent, for example, a hydrogen atom, a halogen atom, an amino group, a carboxyl group, an alkoxycarbonyl group, a sulfo group, a nitro group, a cyano group, an optionally substituted alkyl group, an optionally substituted aryl group, an optionally substituted alkoxy group, an optionally substituted aryloxy group, an optionally substituted alkylamino group, an optionally substituted arylamino group, an optionally substituted alkylsulfonyl group, or an optionally substituted arylsulfonyl group. Among them, a hydrogen atom, a carboxyl group, an alkoxycarbonyl group, an optionally substituted alkyl group, or an optionally substituted aryl group is more preferred from the viewpoint of high radical reactivity.

Preferably, R₄ represents, for example, an optionally substituted alkyl group, more preferably a hydrogen atom, a methyl group, an ethyl group, or an isopropyl group from the viewpoint of high radical reactivity.

Substituents which can be introduced include, for example, alkyl groups, alkenyl groups, alkynyl groups, aryl groups, alkoxy groups, aryloxy groups, halogen atoms, amino group, alkylamino groups, arylamino groups, carboxyl groups, alkoxycarbonyl groups, sulfo group, nitro group, cyano group, amide group, alkylsulfonyl groups, and arylsulfonyl groups.

In structural formula (4), preferably, R₄ to R₈ represent, for example, a hydrogen atom, a halogen atom, an amino group, a dialkylamino group, a carboxyl group, an alkoxycarbonyl group, a sulfo group, a nitro group, a cyano group, an optionally substituted alkyl group, an optionally substituted aryl group, an optionally substituted alkoxy group, an optionally substituted aryloxy group, an optionally substituted alkylamino group, an optionally substituted arylamino group, an optionally substituted alkylsulfonyl group, or an optionally substituted arylsulfonyl group, more preferably a hydrogen atom, a carboxyl group, an alkoxycarbonyl group, an optionally substituted alkyl group, or an optionally substituted aryl group.

Examples of substituents which can be introduced include those exemplified in structural formula (III).

In structural formula (5), preferably, R₉ represents, for example, a hydrogen atom or an optionally substituted alkyl group, more preferably a hydrogen atom or a methyl group from the viewpoint of high radical reactivity.

Preferably, R₁₀ and R₁₁ each independently represent, for example, a hydrogen atom, a halogen atom, an amino group, a dialkylamino group, a carboxyl group, an alkoxycarbonyl group, a sulfo group, a nitro group, a cyano group, an optionally substituted alkyl group, an optionally substituted aryl group, an optionally substituted alkoxy group, an optionally substituted aryloxy group, an optionally substituted alkylamino group, an optionally substituted arylamino group, an optionally substituted alkylsulfonyl group, or an optionally substituted arylsulfonyl group. A hydrogen atom, a carboxyl group, an alkoxycarbonyl group, an optionally substituted alkyl group, or an optionally substituted aryl group is more preferred from the viewpoint of high radical reactivity.

Examples of substituents which can be introduced include those exemplified in structural formula (III).

Z represents an oxygen atom, a sulfur atom, —NR₁₃—, or an optionally substituted phenylene group. R₁₃ represents, for example, an optically substituted alkyl group. A hydrogen atom, a methyl group, an ethyl group, or an isopropyl group is preferred from the viewpoint of high radical reactivity.

Among side chain ethylenically unsaturated bonds represented by structural formulae (III) to (V), those represented by structural formula (III) are more preferred because the polymerization reactivity is high and the sensitivity is high.

The content of the ethylenically unsaturated bond in the polymer compound is not particularly limited but is preferably 0.5 meq/g to 3.0 meq/g, more preferably 1.0 meq/g to 3.0 meq/g, particularly preferably 1.5 meq/g to 2.8 meq/g. When the content is less than 0.5 meq/g, the sensitivity is sometimes low due to a small curing reaction weight. On the other hand, when the content is more than 3.0 meq/g, the storage stability is sometimes deteriorated.

The content (meq/g) can be measured, for example, by iodine number titration.

The method for introducing the ethylenically unsaturated bond represented by structural formula (III) into the side chain is not particularly limited. For example, the ethylenically unsaturated bond represented by structural formula (III) can be introduced into the side chain by subjecting the side chain to an additional reaction with a polymer compound having a carboxyl group on its side chain and a compound containing an ethylenically unsaturated bond and an epoxy group.

The polymer compound having a carboxyl group on its side chain can be produced, for example, by radically polymerizing one or more carboxyl group-containing radical polymerizable compounds and optionally one or more other radical polymerizable compounds as a comonomer component by conventional radical polymerization. Radical polymerization methods include, for example, suspension polymerization and solution polymerization.

Any compound containing the ethylenically unsaturated bond and the epoxy group may be used without particular limitation. For example, compounds represented by structural formula (VI) and compounds represented by formula (VII) are preferred. Particularly, the use of the compounds represented by structural formula (VI) is preferred from the viewpoint of high sensitivity.

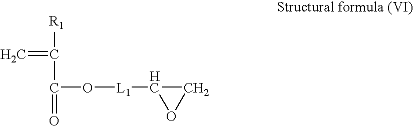

In structural formula (VI), R₁ represents a hydrogen atom or a methyl group; and L₁ represents an organic group.

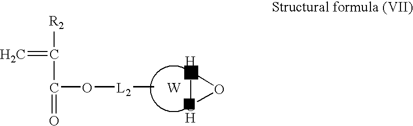

In structural formula (VII), R₂ represents a hydrogen atom or a methyl group; L₂ represents an organic group; and W represents a four- to seven-membered aliphatic hydrocarbon group.

Among compounds represented by structural formula (VI) and compounds represented by structural formula (VII), compounds represented by structural formula (VI) are preferred. Among compounds represented by structural formula (VI), compounds wherein L₁ represents an alkylene group having 1 to 4 carbon atoms are preferred.

The compounds represented by structural formula (VI) or the compounds represented by structural formula (VII) are not particularly limited. However, examples of such compounds include the following exemplified compounds (31) to (40).

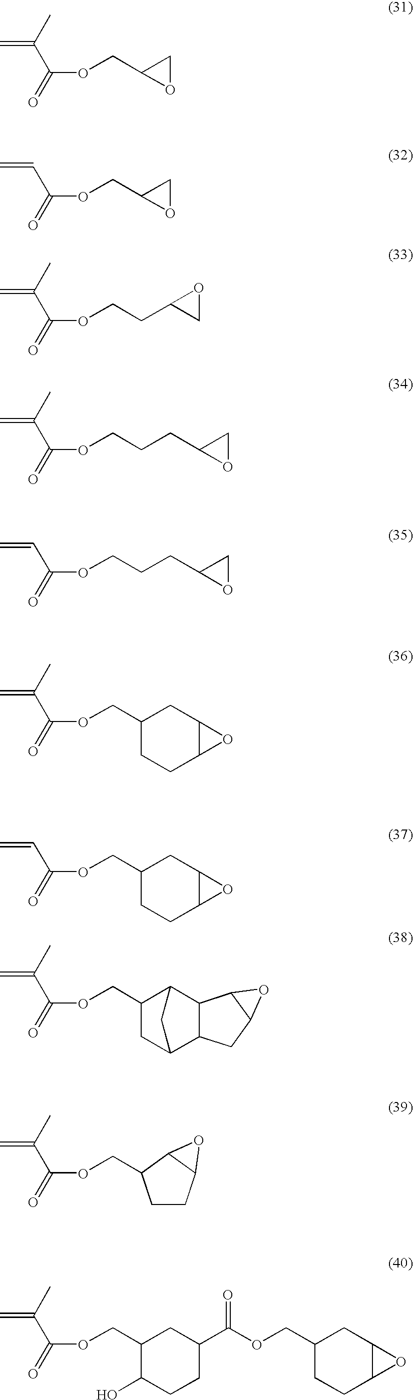

Examples of radical polymerizable compounds containing the carboxyl group include acrylic acid, methacrylic acid, itaconic acid, crotonic acid, isocrotonic acid, maleic acid, and p-carboxylstyrene. Particularly preferred are acrylic acid and methacrylic acid.

The ethylenically unsaturated bond can be introduced into the side chain, for example, by a reaction in the presence of a catalyst such as a tertiary amine such as triethylamine or benzylmethylamine, quaternary ammonium salt such as dodecyltrimethylammonium chloride, tetramethylammonium chloride, or tetraethylammonium chloride, pyridine, or triphenylphosphine at a reaction temperature of 50° C. to 150° C. in an organic solvent for several hr to several tens of hr.

The structural units having an ethylenically unsaturated bond on its side chain are not particularly limited. For example, structures represented by structural formula (i), structures represented by structural formula (ii), and a mixture of these structures are preferred.

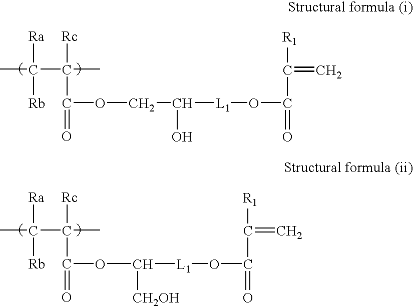

In structural formulae (i) and (ii), Ra to Rc represent a hydrogen atom or a monovalent organic group; R₁ represents a hydrogen atom or a methyl group; and L₁ represents an organic group optionally having a linking group.

The content of the structure represented by structural formula (i) or the content of the structure represented by structural formula (ii) in the polymer compound is preferably 20% by mole or more, more preferably 20% by mole to 50% by mole, particularly preferably 25% by mole to 45% by mole. When the content is less than 20% by mole, the curing reaction weight is so small that the sensitivity is sometimes low. On the other hand, when the content is more than 50% by mole, the storage stability is sometimes deteriorated.

### —Carboxyl Group—

In the polymer compound in the present invention, a carboxyl group may be contained from the viewpoint of improving various properties such as removal of non-image areas.

The carboxyl group can be imparted to the polymer compound by copolymerization with an acid group-containing radical polymerizable compound.

Acid groups possessed by the radical polymerizable compound include, for example, carboxylic acid, sulfonic acid, and phosphoric acid groups. The carboxylic acid group is particularly preferred.

The carboxyl group-containing radical polymerizable compound is not particularly limited and may be suitably selected according to the purpose. Examples of such carboxyl group-containing radical polymerizable compounds include acrylic acid, methacrylic acid, itaconic acid, crotonic acid, isocrotonic acid, maleic acid, and p-carboxylstyrene. Among them, acrylic acid, methacrylic acid, and p-carboxylstyrene are preferred. They may be used either solely or in a combination of two or more.

The content of the carboxyl group in the binder is 1.0 meq/g to 4.0 meq/g and is preferably 1.5 meq/g to 3.0 meq/g. When the carboxyl group content is less than 1.0 meq/g, the developability is sometimes unsatisfactory. On the other hand, when the carboxyl group content is more than 4.0 meq/g, image strength damage by development with an aqueous alkaline solution is likely to occur.

The carboxyl group content (meq/g) may be measured, for example, by titration with sodium hydroxide.

In the polymer compound according to the present invention, preferably, in addition to the radical polymerizable compound, other radical polymerizable compounds can be copolymerized from the viewpoint of improving various properties such as image strength.

Such other radical polymerizable compounds include those selected from acrylic esters, methacrylic esters, and styrenes.

Specific examples thereof include acrylic esters such as alkyl acrylates, methacrylic esters such as aryl acrylates and alkyl methacrylates, aryl methacrylates, styrenes such as styrene and alkylstyrenes, alkoxystyrenes, and halogen styrenes.

Preferred acrylic esters include those in which the number of carbon atoms in the alkyl group is 1 to 20. Examples thereof include methyl acrylate, ethyl acrylate, propyl acrylate, butyl acrylate, amyl acrylate, ethyl hexyl acrylate, octyl acrylate, t-octyl acrylate, chloroethyl acrylate, 2,2-dimethyl hydroxy propyl acrylate, 5-hydroxypentyl acrylate, trimethylolpropane monoacrylate, pentaerythritol monoacrylate, glycidyl acrylate, benzyl acrylate, methoxybenzyl acrylate, furfuryl acrylate, and tetrahydrofurfuryl acrylate.

Aryl acrylates include, for example, phenyl acrylate.

Preferred methacrylic esters include alkyl groups having 1 to 20 carbon atoms. Examples thereof include methyl methacrylate, ethyl methacrylate, propyl methacrylate, isopropyl methacrylate, amyl methacrylate, hexyl methacrylate, cyclohexyl methacrylate, benzyl methacrylate, chlorobenzyl methacrylate, octyl methacrylate, 4-hydroxybutyl methacrylate, 5-hydroxypentyl methacrylate, 2,2-dimethyl-3-hydroxypropyl methacrylate, trimethylolpropane monomethacrylate, pentaerythritol monomethacrylate, glycidyl methacrylate, furfuryl methacrylate, and tetrahydrofurfuryl methacrylate.

Aryl methacrylates include, for example, phenyl methacrylate, cresyl methacrylate, and naphthyl methacrylate.

Styrenes include, for example, methylstyrene, dimethylstyrene, trimethylstyrene, ethylstyrene, diethylstyrene, isopropylstyrene, butylstyrene, hexylstyrene, cyclohexylstyrene, desylstyrene, benzylstyrene, chloromethyl styrene, trifluoromethyl styrene, ethoxymethyl styrene, and acetoxymethylstyrene.

Alkoxystyrenes include, for example, methoxystyrene, 4-methoxy-3-methylstyrene, and dimethoxystyrene.

Halogen styrenes include, for example, chlorostyrene, dichlorostyrene, trichlorostyrene, tetrachlorostyrene, pentachlorostyrene, bromostyrene, dibromostyrene, iodine styrene, fluorostyrene, trifluorostyrene, 2-bromo-4-trifluoromethylstyrene, and 4-fluoro-3-trifluoromethyl styrene.

The radical polymerizable compounds may be used either solely or in a combination of two or more.

The solvent used in the synthesis of the polymer compound in the present invention is not particularly limited and may be suitably selected according to the purpose. Examples thereof include ethylene dichloride, cyclohexanone, methyl ethyl ketone, acetone, methanol, ethanol, propanol, butanol, ethylene glycol monomethyl ether, ethylene glycol monoethyl ether, 2-methoxyethyl acetate, 1-methoxy-2-propanol, 1-methoxy-2-propyl acetate, N,N-dimethylformamide, N,N-dimethylacetamide, dimethylsulfoxide, toluene, ethyl acetate, methyl lactate, and ethyl lactate. They may be used either solely or as a mixture of two or more.

The molecular weight of the polymer compound according to the present invention is 10,000 or more but less than 100,000, more preferably 10,000 to 50,000, in terms of mass average molecular weight. When the mass average molecular weight is less than 10,000, the strength of the cured film is sometimes unsatisfactory. On the other hand, when the mass average molecular weight is more than 100,000, the developability is likely to lower.

The polymer compound according to the present invention may contain an unreacted monomer. In this case, the content of the unreacted monomer in the polymer compound is preferably 15% by mass or less.

The polymer compounds according to the present invention may be used either solely or as a mixture of two or more, or alternatively may be used as a mixture of other polymer compound.

The other polymer compound is not particularly limited and may be suitably selected according to the purpose. Examples thereof include acid group-containing epoxy acrylate compounds described, for example, in Japanese Patent Application Laid-Open (JP-A) No. 51-131706, Japanese Patent Application Laid-Open (JP-A) No. 52-94388, Japanese Patent Application Laid-Open (JP-A) No. 64-62375, Japanese Patent Application Laid-Open (JP-A) No. 02-97513, Japanese Patent Application Laid-Open (JP-A) No. 03-289656, Japanese Patent Application Laid-Open (JP-A) No. 61-243869, and Japanese Patent Application Laid-Open (JP-A) No. 2002-296776.

The epoxy acrylate compound is a compound that has an epoxy compound-derived skeleton and contains an ethylenically unsaturated double bond and a carboxyl group in its molecule. The epoxy acrylate compound may be produced, for example, by a method including reacting a polyfunctional epoxy compound with a carboxyl group-containing monomer and further adding a polybasic acid anhydride.

Examples of additional other polymer compounds include vinyl copolymers having an (meth)acryloyl group on its side chain and an acid group other than the polymer compound according to the present invention.

In this case, the content of the other polymer compound in the polymer compound according to the present invention is preferably 50% by mass or less, more preferably 30% by mass or less.

The solid content of the binder in the solids of the photosensitive composition is preferably 5% by mass to 80% by mass, and more preferably 10% by mass to 70% by mass. When the solid content of the binder is less than 5% by mass, the film strength of the photosensitive layer may be easily weakened, and the tucking property of the surface of the photosensitive layer may be adversely affected. When the solid content is more than 80% by mass, the exposure sensitivity of the photosensitive layer may degrade.

### <Polymerizable Compound>

The polymerizable compound is not particularly limited and may be suitably selected in accordance with the intended use. A compound having at least one addition-polymerizable group in a molecule and a boiling point of 100° C. or more under normal pressure is preferable. Preferred examples thereof include at least one selected from monomers having a (meth)acrylic group.

The monomer having a (meth)acrylic group is not particularly limited and may be suitably selected in accordance with the intended use. Examples thereof include: monofunctional acrylates and monofunctional methacrylates such as polyethylene glycol mono(meth)acrylate, polypropylene glycol mono(meth)acrylate, and phenoxyethyl(meth)acrylate; compounds prepared by adding an ethylene oxide or a propylene oxide to a polyfunctional alcohol, e.g. trimethylol propane, glycerin, and bisphenol, for reaction and making the reaction product into (meth)acrylate, such as polyethylene glycol di(meth)acrylate, polypropylene glycol di(meth)acrylate, trimethylolethane triacrylate, trimethylolpropane triacrylate, trimethylol propane diacrylate, neopentyl glycol di(meth)acrylate, pentaerythritol tetra(meth)acrylate, pentaerythritol tri(meth)acrylate, dipentaerythritol hexa(meth)acrylate, dipentaerythritol penta(meth)acrylate, hexanediol di(meth)acrylate, trimethylol propane tri(acryloyl oxypropyl)ether, tri(acryloyl oxyethyl) isocyanurate, and tri(acryloyl oxyethyl) cyanurate, glycerol tri(meth)acrylate; urethane acrylates described in Japanese Patent Application Publication (JP-B) Nos. 48-41708 and 50-6034, and Japanese Patent Application Laid-Open (JP-A) No. 51-37193; polyester acrylates described in Japanese Patent Application Laid-Open (JP-A) No. 48-64183, Japanese Patent Application Publication (JP-B) Nos. 49-43191, and 52-30490; and polyfunctional acrylates and methacrylates such as epoxy acrylates, which are reaction products between epoxy resins and (meth)acrylic acids. Among these, trimethylol propane tri(meth)acrylate, pentaerythritol tetra(meth)acrylate, dipentaerythritol hexa(meth)acrylate, and dipentaerythritol penta(meth)acrylate are particularly preferable.

The amount of the polymerizable compound incorporated in the photosensitive composition is preferably 1% by mass to 50% by mass, more preferably 5% by mass to 40% by mass, particularly preferably 10% by mass to 30% by mass, based on the total solid content. When the content of the polymerizable compound is below the lower limit of the above-defined polymerizable compound content range, the photosensitivity is likely to lower. On the other hand, when the content of the polymerizable compound is above the upper limit of the above-defined polymerizable compound content range, the dispersion stability of the pigment is likely to lower.

### <Photopolymerization Initiator or Photopolymerization Initiation Compound>

The photopolymerization initiator is not particularly limited and may be suitably selected from conventional ones as long as it has the property to initiate polymerization; the photopolymerization initiator is preferably the one that exhibits photosensitivity to ultraviolet rays to visual lights. The photopolymerization initiator may be an active substance that generates a radical due to an effect with a photo-exited photosensitizer, or a substance that initiates cation polymerization depending on the monomer species.

The photopolymerization initiator preferably contains at least one component that has a molecular extinction coefficient of about 50 in a range of about 300 nm to 800 nm, more preferably about 330 nm to 500 nm.

Examples of the photopolymerization initiator include halogenated hydrocarbon derivatives (such as having a triazine skeleton or an oxadiazole skeleton, an oxadiazole skeleton), phosphorous oxide, hexaaryl-biimidazols, oxime derivatives, organic peroxides, thio compounds, ketone compounds, aromatic onium salts, and ketoxime ether.

Examples of the halogenated hydrocarbon compounds having a triazine skeleton include the compounds described in Bulletin of the Chemical Society of Japan, by Wakabayasi, et al. 42, 2924 (1969); GB Pat. No. 1388492; JP-A No. 53-133428; DE Pat. No. 3337024; Journal of Organic Chemistry, by F. C. Schaefer et. al. 29, 1527 (1964); JP-A Nos. 62-58241, 05-281728, and 05-34920; and U.S. Pat. No. 4,212,976.

Examples of the compounds described in Bulletin of the Chemical Society of Japan, by Wakabayasi, et al. 42, 2924 (1969) set forth above include 2-phenyl-4,6-bis(trichloromethyl)-1,3,5-triazine, 2-(4-chlorophenyl)-4,6-bis(trichloromethyl)-1,3,5-triazine, 2-(4-tolyl)-4,6-bis(trichloromethyl)-1,3,5-triazine, 2-(4-methoxyphenyl)-4,6-bis(trichloromethyl)-1,3,5-triazine, 2-(2,4-dichlorophenyl)-4,6-bis(trichloromethyl)-1,3,5-triazine, 2,4,6-tris(trichloromethyl)-1,3,5-triazine, 2-methyl-4,6-bis(trichloromethyl)-1,3,5-triazine, 2-n-nonyl-4,6-bis(trichloromethyl)-1,3,5-triazine, and 2-(α,α,β-trichloroethyl)-4,6-bis(trichloromethyl)-1,3,5-triazine.

Examples of the compounds described in GB Pat. No. 1388492 set forth above include 2-styryl-4,6-bis(trichloromethyl)-1,3,5-triazine, 2-(4-methylstyryl)-4,6-bis(trichloromethyl)-1,3,5-triazine, 2-(4-methoxystyryl)-4,6-bis(trichloromethyl)-1,3,5-triazine, and 2-(4-methoxystyryl)-4-amino-6-trichloromethyl-1,3,5-triazine.

Examples of the compounds described in JP-A No. 53-133428 set forth above include 2-(4-methoxynaphtho-1-yl)-4,6-bis(trichloromethyl)-1,3,5-triazine, 2-(4-ethoxy-naphtho-1-yl)-4,6-bis(trichloromethyl)-1,3,5-triazine, 2-[4-(2-ethoxyethyl)-naphtho-1-yl]-4,6-bis(trichloromethyl)-1,3,5-triazine, 2-(4,7-dimethoxy-naptho-1-yl)-4,6-bis(trichloromethyl)-1,3,5-triazine, and 2-(acenaphtho-5-yl)-4,6-bis(trichloromethyl)-1,3,5-triazine.

Examples of the compounds described in DE Pat. No. 3337024 set forth above include 2-(4-styrylphenyl)-4,6-bis(trichloromethyl)-1,3,5-triazine, 2-(4-(4-methoxystyryl)phenyl)-4,6-bis(trichloromethyl)-1,3,5-triazine, 2-(1-naphthylvinylenephenyl)-4,6-bis(trichloromethyl)-1,3,5-triazine, 2-chlorostyrylphenyl-4,6-bis(trichloromethyl)-1,3,5-triazine, 2-(4-thiophene-2-vinylenephenyl)-4,6-bis(trichloromethyl)-1,3,5-triazine, 2-(4-thiophene-3-vinylenephenyl)-4,6-bis(trichloromethyl)-1,3,5-triazine, 2-(4-furan-2-vinylenephenyl)-4,6-bis(trichloromethyl)-1,3,5-triazine, and 2-(4-benzofuran-2-vinylenephenyl)-4,6-bis(trichloromethyl)-1,3,5-triazine.

Examples of the compounds described in Journal of Organic Chemistry, by F. C. Schaefer et. al. 29, 1527 (1964) set forth above include 2-methyl-4,6-bis(tribromomethyl)-1,3,5-triazine, 2,4,6-tris(tribromomethyl)-1,3,5-triazine, 2,4,6-tris(dibromomethyl)-1,3,5-triazine, 2-amino-4-methyl-6-tri(bromomethyl)-1,3,5-triazine and 2-methoxy-4-methyl-6-trichloromethyl-1,3,5-triazine.

Examples of the compounds described in JP-A No. 62-58241 set forth above include 2-(4-phenylethylphenyl)-4,6-bis(trichloromethyl)-1,3,5-triazine, 2-(4-naphthyl-1-ethynylphenyl)-4,6-bis(trichloromethyl)-1,3,5-triazine, 2-(4-(4-triethynyl)phenyl)-4,6-bis(trichloromethyl)-1,3,5-triazine, 2-(4-(4-methoxyphenyl)ethynylphenyl)-4,6-bis(trichloromethyl)-1,3,5-triazine, 2-(4-(4-isopropylphenylethynyl)phenyl)-4,6-bis(trichloromethyl)-1,3,5-triazine, and 2-(4-(4-ethylphenylethynyl)phenyl)-4,6-bis(trichloromethyl)-1,3,5-triazine.

Examples of the compounds described in JP-A No. 05-281728 set forth above include 2-(4-trifluoromethylphenyl)-4,6-bis(trichloromethyl)-1,3,5-triazine, 2-(2,6-difluorophenyl)-4,6-bis(trichloromethyl)-1,3,5-triazine, 2-(2,6-dichlorophenyl)-4,6-bis(trichloromethyl)-1,3,5-triazine, and 2-(2,6-dibromophenyl)-4,6-bis(trichloromethyl)-1,3,5-triazine.

Examples of the compounds described in JP-A No. 05-34920 set forth above include 2,4-bis(trichloromethyl)-6-[4-(N,N-diethoxycarbonylmethylamino)-3-bromophenyl]-1,3,5-triazine, trihalomethyl-s-triazine compounds described in U.S. Pat. No. 4,239,850, and also 2,4,6-tris(trichloromethyl)-s-triazine, and 2-(4-chlorophenyl)-4,6-bis(tribromomethyl)-s-triazine.

Examples of the compounds described in U.S. Pat. No. 4,212,976 set forth above include the compounds having an oxadiazole skeleton such as 2-trichloromethyl-5-phenyl-1,3,4-oxadiazole, 2-trichloromethyl-5-(4-chlorophenyl)-1,3,4-oxadiazole, 2-trichloromethyl-5-(1-naphthyl)-1,3,4-oxadiazole, 2-trichloromethyl-5-(2-naphthyl)-1,3,4-oxadiazole, 2-tribromomethyl-5-phenyl-1,3,4-oxadiazole, 2-tribromomethyl-5-(2-naphthyl)-1,3,4-oxadiazole, 2-trichloromethyl-5-styryl-1,3,4-oxadiazole, 2-trichloromethyl-5-(4-chlorostyryl)-1,3,4-oxadiazole, 2-trichloromethyl-5-(4-methoxystyryl)-1,3,4-oxadiazole, 2-trichloromethyl-5-(1-naphthyl)-1,3,4-oxadiazole, 2-trichloromethyl-5-(4-n-butoxystyryl)-1,3,4-oxadiazole, and 2-tribromomethyl-5-styryl-1,3,4-oxadiazole.

Examples of the oxime derivatives which are preferably used in the present invention include 3-benzoyloxyiminobutan-2-one, 3-acetoxyiminobutan-2-one, 3-propyonyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutane-2-one, and 2-ethoxycarbonyloxyimino-1-phenylpropan-1-one.

As for photopolymerization initiators other than set forth above, the following substances are further exemplified: acridine derivatives such as 9-phenyl acridine and 1,7-bis(9,9′-acridinyl)heptane, and N-phenylglycine; polyhalogenated compounds such as carbon tetrabromide, phenyltribromosulfone, and phenyltrichloromethylketone; coumarins such as 3-(2-benzofuroyl)-7-diethylaminocoumarin, 3-(2-benzofuroyl)-7-(1-pyrrolidinyl)coumarin, 3-benzoyl-7-diethylaminocoumarin, 3-(2-methoxybenzoyl)-7-diethylaminocoumarin, 3-(4-dimethylaminobenzoyl)-7-diethylaminocoumarin, 3,3′-carbonylbis(5,7-di-n-propoxycoumarin), 3,3′-carbonylbis(7-diethylaminocoumarin), 3-benzoyl-7-methoxycoumarin, 3-(2-furoyl)-7-diethylaminocoumarin, 3-(4-diethylaminocinnamoyl)-7-diethylaminocoumarin, 7-methoxy-3-(3-pyridylcarbonyl)coumarin, 3-benzoyl-5,7-dipropoxycoumarin, and 7-benzotriazol-2-ylcoumarin, and also the coumarin compounds described in JP-A Nos. 05-19475, 07-271028, 2002-363206, 2002-363207, 2002-363208, and 2002-363209; amines such as ethyl 4-dimethylaminobenzoate, n-butyl 4-dimethylaminobenzoate, phenethyl 4-dimethylaminobenzoate, 2-phthalimide-4-dimethylaminobenzoate, 2-methacryloyloxyethyl-4-dimethylaminobenzoate, pentamethylene-bis(4-dimethylaminobenzoate), phenethyl-3-dimethylaminobenzoate, pentamethylene esters, 4-dimethylamino benzaldehyde, 2-chloro-4-dimethylamino benzaldehyde, 4-dimethylaminobenzyl alcohol, ethyl(4-dimethylaminobenzoyl)acetate, 4-piperidine acetophenone, 4-dimethyamino benzoin, N,N-dimethyl-4-toluidine, N,N-diethyl-3-phenetidine, tribenzylamine, dibenzylphenylamine, N-methyl-N-phenylbenzylamine, 4-bromo-N,N-diethylaniline, and tridodecyl amine; amino fluorans such as ODB and ODBII; crystal violet lactone, leucocrystal violet; acylphosphine oxides such as bis(2,4,6-trimethylbenzoyl)phenylphosphine oxide, bis(2,6-dimethylbenzoyl)-2,4,4-trimethyl-pentylphenylphosphine oxide, and Lucirin TPO. Examples of the metallocenes include bis(η⁵-2,4-cyclopentadiene-1-yl)-bis(2,6-difluoro-3-(1H-pyrrole-1-yl)-phenyl)titanium, η⁵-cyclopentadienyl-η⁶-cumenyl-iron(1+)-hexafluorophosphate(1−), and the compounds described in JP-A No. 53-133428, JP-B Nos. 57-1819 and 57-6096, and U.S. Pat. No. 3,615,455.

Examples of the ketone compounds set forth above include benzophenone, 2-methylbenzophenone, 3-methylbenzophenone, 4-methylbenzophenone, 4-methoxybenzophenone, 2-chlorobenzophenone, 4-chlorobenzophenone, 4-bromobenzophenone, 2-carboxybenzophenone, 2-ethoxycarbonylbenzophenone, benzophenone-tetracarboxylic acid and its tetramethyl ester; 4,4′-bis(dialkylamino)benzophenones such as 4,4′-bis(dimethylamino)benzophenone, 4,4′-bis(dicyclohexylamino)benzophenone, 4,4′-bis(diethylamino)benzophenone, 4,4′-bis(dihydroxyethylamino)benzophenone, 4-methoxy-4′-dimethylaminobenzophenone, 4,4′-dimethoxybenzophenone, and 4-dimethylaminobenzophenone; 4-dimethylaminoacetophenone, benzyl, anthraquinone, 2-tert-butylanthraquinone, 2-methylanthraquinone, phenanthraquinone, xanthone, thioxanthone, 2-chlorothioxanthone, 2,4-diethylthioxanthone, fluorene, 2-benzyl-dimethylamino-1-(4-morpholinophenyl)-1-butanone, 2-methyl-1-[4-(methylthio)phenyl]-2-morpholino-1-propanone, 2-hydroxy-2-methyl-[4-(1-methylvinyl)phenyl]propanol oligomer, benzoin; benzoin ethers such as benzoin methylether, benzoin ethylether, benzoin propylether, benzoin isopropylether, benzoin phenylether, and benzyl dimethyl ketal; acridone, chloroacridone, N-methylacridone, N-butylacridone, and N-butyl-chloroacridone.

### <<Photosensitizer>>

In order to adjust the exposure sensitivity and photosensitive wavelength when exposing the photosensitive layer, which will be described hereinafter, it is possible to add a photosensitizer in addition to the photopolymerization initiator.

The photosensitizer may be suitably selected depending on the types of laser beam such as visible light, ultraviolet ray laser beam, and visible light laser beam, as a light irradiation unit, which will be described hereinafter.

The photosensitizer may be exited by active irradiation and may generate a radical, an available acidic group and the like through interaction with other substances such as radical generators and acid generators by transferring energy or electrons.

The photosensitizer is not particularly limited and may be suitably selected from conventional ones; and examples thereof include conventional polynucleic aromatics such as pyrene, perylene, and triphenylene; xanthenes such as fluorescein, eosine, erythrosine, Rhodamine B, rose bengal; cyanines such as indocarbocyanine, thiacarbocyanine, and oxacarbocyanine); merocyanines such as merocyanine, and carbomerocyanine; thiazines such as thionine, methylene blue, toluidine blue; acridines such as acridine orange, chloroflavin, and acryflavin; anthraquinones such as anthraquinon; squaryliums such as squarylium; acridones such as acridone, chloroacridone, N-methylacridone, N-butylacridone, N-butyl-chloroacridone; coumarins such as 3-(2-benzofuroyl)-7-diethylaminocoumarin, 3-(2-benzofuroyl)-7-(1-pyrrolidinyl) coumarin, 3-benzoyl-7-diethylaminocoumarin, 3-(2-methoxybenzoyl)-7-diethylaminocoumarin, 3-(4-dimethylaminobenzoyl)-7-diethylaminocoumarin, 3,3′-carbonylbis(5,7-di-n-propoxycoumarin), 3,3′-carbonylbis (7-diethylaminocoumarin), 3-benzoyl-7-methoxycoumarin, 3-(2-furoyl)-7-diethylaminocoumarin, 3-(4-diethylaminocinnamoyl)-7-diethylaminocoumarin, 7-methoxy-3-(3-pyridylcarbonyl)coumarin, 3-benzoyl-5,7-dipropoxycoumarin, and coumarin compounds described in Japanese Patent Application Laid-Open (JP-A) Nos. 05-19475, 07-271028, 2002-363206, 2002-363207, 2002-363208, and 2002-363209.

As for the combination of the photopolymerization initiator and the photosensitizer, the initiating mechanism that involves electron transfer may be exemplified such as combinations of (1) an electron donating initiator and a photosensitizer dye, (2) an electron accepting initiator and a photosensitizer dye, and (3) an electron donating initiator, a photosensitizer dye, and an electron accepting initiator (ternary initiating mechanism) as described in JP-A No. 2001-305734.

The amount of the photosensitizer is preferably 0.05% by mass to 30% by mass relative to the total components of the photosensitive composition, more preferably 0.1% by mass to 20% by mass, and still more preferably 0.2% by mass to 10% by mass. When the amount is less than 0.05% by mass, the sensitivity to the active energy ray may decrease, longer period may be required for exposing process, and the productivity may tend to lower, and when the amount is more than 30% by mass, the photosensitizer may precipitate from the photosensitive layer during preservation period.

Each of these photopolymerization initiators may be used alone or in combination.

The photopolymerization initiator is not particularly limited and may be suitably selected in accordance with the intended use as long as it is photosensitive to a laser beam having a wavelength of 405 nm in the exposure process, which will be described below. Examples of the photopolymerization initiator include complex photoinitiators prepared by compounding the phosphine oxide, the α-amino alkyl ketones, the halogenated hydrocarbon compound having a triazine skeleton, and an amine compound as a photosensitizer, which will be described below; compounds prepared in combination with photosensitizers such as a hexaarylbiimidazole compound; or titanocene.

The amount of the photopolymerization initiator or the photopolymerization initiation compound incorporated in the photosensitive composition is preferably 0.01% by mass to 20% by mass, more preferably 1% by mass to 15% by mass, particularly preferably 1% by mass to 10% by mass, based on the total solid content. When the content of the photopolymerization initiator or the photopolymerization initiation compound is below the lower limit of the above-defined photopolymerization initiator or photopolymerization initiation compound content range, the photosensitivity is likely to lower. On the other hand, when the content of the photopolymerization initiator or the photopolymerization initiation compound is above the upper limit of the above-defined photopolymerization initiator or photopolymerization initiation compound content range, the adhesion is likely to lower.

### <Thermocrosslinker>

The thermocrosslinker is not particularly limited and may be suitably selected in accordance with the intended use. In order to enhance the film strength of the hardened photosensitive layer which is formed by using the photosensitive composition, for example, it is possible to use an epoxy compound having at least two oxirane groups within one molecule or an oxetane compound having at least two oxetanyl groups within one molecule within the range where no adverse impact is anticipated on the developing property of the photosensitive layer.

Examples of the epoxy resin compound having at least two oxirane groups within one molecule include bixylenol epoxy resins or biphenol epoxy resins (product name: “YX4000”, manufactured by Japan Epoxy Resin K.K.) or mixtures thereof; heterocyclic epoxy resins having an isocyanurate skeleton or the like (product name: “TEPIC”, manufactured by NISSAN CHEMICAL INDUSTRIES, LTD., “ARALDITE PT810”, manufactured by Chiba Specialty Chemicals K.K., and the like); bisphenol A epoxy resins, novolac epoxy resins, bisphenol F epoxy resins, hydrogenerated bisphenol A epoxy resins, bisphenol S epoxy resins, phenol novolac epoxy resins, cresol novolac epoxy resins, haloganated epoxy resins (such as low brominated epoxy resins, high haloganated epoxy resins, brominated phenol novolac epoxy resins), aryl group containing bisphenol A epoxy resins, trisphenol methan epoxy resins, diphenyldimethanol epoxy resins, phenol biphenylene epoxy resins, dicyclopentadiene epoxy resins (“HP-7200” and “HP-7200H” manufactured by Dainippon Ink and Chemicals, Inc., etc.); glycidylamine epoxy resins (diaminodiphenylmethane epoxy resins, glycidylaniline, triglycidylaminophenol), glycidylester epoxy resins (phthalic acid diglycidyl ester, adipi acid diglycidyl ester, hexahydrophthalic acid glycidyl ester, dimer acid glycidyl ester etc.); hydantoin epoxy resins, alicyclic epoxy resins (such as 3,4-epoxy cyclohexenylmethyl-3′,4′-epoxy cyclohexenyl carboxylate, bis(3,4-epoxycyclohexylmethyl)adipate, dicyclopentadiene diepoxide, GT-300, GT-400, ZEHPE3150, manufactured by Daniel Chemical Industries, Ltd.), imide cycloaliphatic epoxy resins, trihydroxyphenylmethane epoxy resins, bisphenol A novolac epoxy resins, tetraphenylolethane epoxy resins, glycidyl phthalate resins, tetraglycidylxylenoylethan resins, naphthalene group-containing epoxy resins (naphthol aralkyl epoxy resins, naphthol novolac epoxy resins, tetrafunctional naphthalene epoxy resins, those commercially available include ESN-190, ESN-360 by Nippon Steel Chemical, HP-4032, EXA-4750, EXA-4700 manufactured by Dainippon Ink and Chemicals, Inc., etc.); reactants obtained from a reaction between epichlorohydrin and a polyphenol compound which is obtained by addition reaction between a phenol compound and a diolefin compound such as divinylbenzene or dicyclopentadiene; a ring-opening polymerization product of 4-vinylcyclohexene-1-oxide epoxidized with peracetic acid or the like; epoxy resins having linear phosphorus containing structure; epoxy resins having cyclic phosphorus containing structure; α-methylstilbene liquid crystal epoxy resins, dibenzoyloxybenzene liquid crystal epoxy resins; azophenyl liquid crystal epoxy resins; azomethine phenyl liquid crystal epoxy resins; binaphthyl liquid crystal epoxy resins; azine epoxy resins; glycidylmethacrylate copolymer epoxy resins (“CP-50S” and “CP-50M” manufactured by NOF Corporation, etc.), and copolymerized epoxy resins between cyclohexyl maleimide and glycidyl methacrylate, bis(glycidyloxyphenyl)fluorine epoxy resins, and bis(glycidyloxyphenyl)adamantine epoxy resins. However, the thermocrosslinker is not limited to those stated above. These epoxy resins may be used alone or in combination.

Further, in addition to the epoxy compound containing at least two oxirane groups per molecule, an epoxy compound containing two epoxy groups per molecule, having an alkyl group at the β-position may be used. Compounds containing an epoxy group of which the β-position has been substituted by an alkyl group (more specifically a β-alkyl-substituted glycidyl group or the like) are particularly preferred.

The epoxy compound containing at least an epoxy group of which the β-position has an alkyl group may be such that all of the two or more epoxy groups contained in one molecule is a β-alkyl-substituted glycidyl group, or alternatively at least one epoxy group is a β-alkyl-substituted glycidyl group.

For the epoxy compound containing an epoxy group of which the β-position has an alkyl group, the content of the β-alkyl-substituted glycidyl group in the whole epoxy group in the whole epoxy compound contained in the photosensitive composition is preferably 70% or more from the viewpoint of storage stability at room temperature.

The β-alkyl-substituted glycidyl group is not particularly limited and may be suitably selected according to the purpose. Examples of such β-alkyl-substituted glycidyl groups include β-methyl glycidyl, β-ethyl glycidyl, propyl glycidyl, and β-butyl glycidyl groups. Among them, the β-methyl glycidyl group is preferred from the viewpoints of improving the storage stability of the photosensitive resin composition and facilitating the synthesis.

For example, epoxy compounds derived from a polyhydric phenol compound and a β-alkylepihalohydrin are preferred as the epoxy compound containing an epoxy group of which the β-position has an alkyl group.

The β-alkylepihalohydrin is not particularly limited and may be suitably selected according to the purpose. Examples thereof include β-methylepihalohydrins such as β-methylepichlorohydrin, β-methylepibromohydrin, and β-methylepifluorohydrin; β-ethylepihalohydrins such as β-ethylepichlorohydrin, β-ethylepibromohydrin, and β-ethylepifluorohydrin; β-propylepihalohydrins such as β-propylepichlorohydrin, β-propylepibromohydrin, and β-propylepifluorohydrin; and β-butylepihalohydrins such as β-butylepichlorohydrin, β-butylepibromohydrin, and β-butylepifluorohydrin. Among them, β-methylepihalohydrin is preferred from the viewpoint of reactivity with the polyhydric phenol and fluidity.

Any compound containing two or more aromatic hydroxyl groups per molecule may be used as the polyhydric phenol compound without particular limitation and may be suitably selected according to the purpose. Examples thereof include bisphenol compounds such as bisphenol A, bisphenol F, and bisphenol S, biphenol compounds such as biphenol and tetramethyl biphenol, naphthol compounds such as dihydroxynaphthalene and binaphthol, phenol novolac resins such as phenol-formaldehyde polycondensates, monoalkyl (1 to 10 carbon atoms)-substituted phenol-formaldehyde polycondensates such as cresol-formaldehyde polycondensates, dialkyl (1 to 10 carbon atoms)-substituted phenol-formaldehyde polycondensates such as xylenol-formaldehyde polycondensates, bisphenol compound-formaldehyde polycondensates such as bisphenol A-formaldehyde polycondensates, copolycondensates of phenol with a monoalkyl (1 to 10 carbon atoms)-substituted phenol and formaldehyde, and polyaddition products of a phenol compound with divinylbenzene. Among them, for example, bisphenol compounds are preferred when an improvement in fluidity and storage stability is contemplated.

Examples of epoxy compounds containing an epoxy group of which the β-position has an alkyl group include di-β-alkyl glycidyl ethers of bisphenol compounds such as di-β-alkyl glycidyl ethers of bisphenol A, di-β-alkyl glycidyl ethers of bisphenol F, and di-β-alkyl glycidyl ethers of bisphenol S; di-β-alkyl glycidyl ethers of biphenol compounds such as di-β-alkyl glycidyl ethers of biphenol and di-β-alkyl glycidyl ethers of tetramethyl biphenol; β-alkyl glycidyl ethers of naphthol compounds such as di-β-alkyl glycidyl ethers of dihydroxynaphthalene and di-β-alkyl glycidyl ethers of binaphthol; poly-β-alkyl glycidyl ethers of phenol-formaldehyde polycondensates; poly-β-alkyl glycidyl ethers of monoalkyl (1 to 10 carbon atoms)-substituted phenol-formaldehyde polycondensates such as poly-β-alkyl glycidyl ethers of cresol-formaldehyde polycondensates; poly-β-alkyl glycidyl ethers of dialkyl (1 to 10 carbon atoms)-substituted phenol-formaldehyde polycondensates such as poly-β-alkyl glycidyl ethers of xylenol-formaldehyde polycondensates; poly-β-alkyl glycidyl ethers of bisphenol compound-formaldehyde polycondensates such as poly-β-alkyl glycidyl ethers of bisphenol A-formaldehyde polycondensates; and poly-β-alkyl glycidyl ethers of polyaddition products between a phenol compound and divinylbenzene.

Among them, β-alkyl glycidyl ethers derived from bisphenol compounds represented by general formula (IV) and from polymers produced from these bisphenol compounds and epichrohydrin or the like, and poly-β-alkyl glycidyl ethers of phenol compound-formaldehyde polycondensates represented by general formula (V) are preferred.

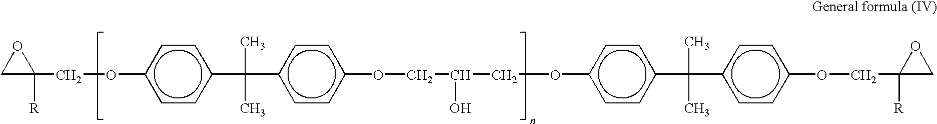

In general formula (IV), R represents a hydrogen atom or an alkyl group having 1 to 6 carbon atoms; and n is an integer of 0 to 20.

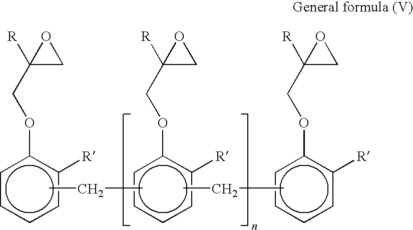

In general formula (V), R and R′, which may be the same or different, represent any one of a hydrogen atom and an alkyl group having 1 to 6 carbon atoms; and n is an integer of 0 to 20.

The epoxy compounds containing an epoxy group of which the β-position has an alkyl group may be used either solely or in a combination of two or more. Alternatively, an epoxy compound containing at least two oxirane groups per molecule and an epoxy compound containing an epoxy group of which the β-position has an alkyl group may be used in combination.

Examples of the oxetane compounds include bis[(3-methyl-3-oxetanylmethoxy)methyl]ether, bis[(3-ethyl-3-oxetanylmethoxy)methyl]ether, 1,4-bis[(3-methyl-3-oxetanylmethoxy)methyl]benzene, 1,4-bis[(3-ethyl-3-oxetanylmethoxy)methyl]benzene, (3-methyl-3-oxetanyl)methylacrylate, (3-ethyl-3-oxetanyl)methyl acrylate, (3-methyl-3-oxetanyl)methyl methacrylate, (3-ethyl-3-oxetanyl)methyl methacrylate or oligomers thereof; or polyfunctional oxetanes such as copolymers thereof; and ether compounds prepared between a compound having an oxetane group and a resin having a hydroxyl group such as novolac resin, poly(p-hydroxystyrene), cardo bisphenols, calix-arenes, calix-resorcin arenas, and silsesquioxane; and copolymers between unsaturated monomer having an oxetane ring and alkyl(meth)acrylate.

For the above-noted thermocrosslinker, it is possible to use polyisocyanate compounds described in Japanese Patent Application Laid-Open (JP-A) No. 05-9407, and the polyisocyanate compounds may be derived from an aliphatic compound or an alicyclic compound, or an aromatic group-substituted aliphatic compound each of which contains at least two isocyanate groups.

Specific examples of such polyisocyanate compounds include bifunctional isocyanates such as mixtures of 1,3-phenylene diisocyanate and 1,4-phenylene diisocyanate, 2,4-toluene diisocyanate, 2,6-toluene diisocyanate, 1,3-xylylene diisocyanate, 1,4-xylylene diisocyanate, bis(4-isocyanate-phenyl)methane, bis(4-isocyanatecyclohexyl)methane, isophorone diisocyanate, hexamethylene diisocyanate, trimethylhexamethylene diisocyanate; polyfunctional alcohols compounded between the bifunctional isocyanate, and trimethylolpropane, pentaerythritol, and glycerine; alkylene oxide adducts of the above-noted polyfunctional alcohol, and adducts with the above-noted bifunctional isocyanate; and cyclic trimers or buret from hexamethylene diisocyanate, hexamethylene-1,6-diisocyanate, and derivatives thereof; and norbornan diisocyanate.

For enhancing shelf stability of the photosensitive composition of the present invention, a compound that can be prepared by reacting a blocking agent to the polyisocyanate or isocyanate group of the derivatives thereof may be used.

Examples of the isocyanate group-containing blocking agent include alcohols such as isopropanol, and tert-butanol; lactams such as ∈-caprolactam; phenols such as phenol, cresol, p-tert-butylphenol, p-sec-butylphenol, p-sec-aminophenol, p-octylphenol, and p-nonylphenol; heterocyclic hydroxyl compounds such as 3-hydroxypyridine, and 8-hydroxyquinoline; active methylene compounds such as dialkyl malonate, methyl ethyl ketoxime, acetylacetone, alkyl acetoacetate oxime, acetooxime, and cyclohexanon oxime. Besides, the compounds having at least one polymerizable double bond or having at least one block isocyanate group in one molecule, which are described in Japanese Patent Application Laid-Open (JP-A) No. 06-295060, may be used.

Further, for the thermocrosslinker, melamine derivatives may be used. Examples of the melamine derivatives include methylolmelamine, and alkylated methylol melamine (a compound in which a methylol group is etherified with methyl, ethyl, or butyl). These may be used alone or in combination. Of these, alkylated methylol melamine is preferable, and hexa-methylated methylol melamine is particularly preferable in that excellent storage stability of the photosensitive layer can be assured, and it is useful in enhancing the surface hardness of the photosensitive layer or the film strength of the hardened film itself.

As other thermocrosslinkers, aldehyde condensation products and resin precursors may also be employed. Specific example thereof include N,N′-dimethylolurea, N,N′-dimethylolmalonamide, N,N′-dimethylolsuccinimide, 1,3-N,N′-dimethylolterephthalamide, 2,4,6-trimethylolphenol, 2,6-dimethylol-4-methylanisole, and 1,3-dimethylol-4,6-diisopropylbenzene.

Further, in place of these methylol compounds, such compounds may be employed as etylol compounds, butylol compounds, and esters of acetic acid or propionic acid that corresponds to the methylol compounds respectively.

The amount of the thermal crosslinking agent used in the photosensitive composition is preferably 1% by mass to 30% by mass, more preferably 2% by mass to 25% by mass, particularly preferably 5% by mass to 15% by mass, based on the total solid content. When the content of the thermal crosslinking agent is below the lower limit of the above-defined thermal crosslinking agent range, the adhesion of the cured film to the substrate is likely to lower. On the other hand, when the content of the thermal crosslinking agent is above the upper limit of the above-defined thermal crosslinking agent range, the storage stability is likely to lower.

### <Colorant>

The photosensitive composition according to the present invention includes an organic pigment as a colorant (a pigment) of which the halogen content is 900 ppm or less based on the total solid content. The organic pigment shows a green color because the organic pigment contains, as colorants (pigments), a pigment that contains 5% by mass to 50% by mass of a halogen atom per molecule and shows a yellow color, and a pigment that does not contain a halogen atom per molecule and shows a blue color, at a mixing ratio of 1:1 to 1:4.

Among the colorants (pigments), phthalocyanine pigments may be mentioned as the pigment that does not contain a halogen atom per molecule and shows a blue color upon exposure to visible light (hereinafter sometimes referred to as “blue pigment”). Specific examples of phthallocyanine pigments include copper phthalocyanine blue (C.I. Pigment Blue 15:3).

Pigments containing a halogen atom in the molecule thereof is preferred as the pigment that has an average particle diameter of 100 nm to 1,000 nm and shows a yellow color upon exposure to visible light (hereinafter sometimes referred to as “yellow pigment”). Examples thereof include monoazo compounds, i.e., C.I. Pigment Yellow 2, C.I. Pigment Yellow 3, C.I. Pigment Yellow 6, C.I. Pigment Yellow 49, C.I. Pigment Yellow 73, C.I. Pigment Yellow 75, C.I. Pigment Yellow 97, C.I. Pigment Yellow 98, C.I. Pigment Yellow 111, and C.I. Pigment Yellow 116. Additional examples thereof include disazo compounds, for example, diarycide compounds including nonlake disazo compounds such as C.I. Pigment Yellow 12, C.I. Pigment Yellow 13, C.I. Pigment Yellow 14, C.I. Pigment Yellow 17, C.I. Pigment Yellow 55, C.I. Pigment Yellow 63, C.I. Pigment Yellow 81, C.I. Pigment Yellow 83, C.I. Pigment Yellow 87, C.I. Pigment Yellow 106, C.I. Pigment Yellow 113, C.I. Pigment Yellow 114, C.I. Pigment Yellow 121, C.I. Pigment Yellow 124, C.I. Pigment Yellow 126, C.I. Pigment Yellow 127, C.I. Pigment Yellow 136, C.I. Pigment Yellow 152, C.I. Pigment Yellow 170, C.I. Pigment Yellow 171, C.I. Pigment Yellow 172, C.I. Pigment Yellow 174, C.I. Pigment Yellow 176, and C.I. Pigment Yellow 188, lake type disazo compounds such as C.I. Pigment Yellow 168. Further examples thereof include bisacetoacetarylide compounds, i.e., C.I. Pigment Yellow 16 and benzimidazolone compounds, i.e., C.I. Pigment Yellow 154. Still further examples thereof include isoindoline and isoindolinone compounds, i.e., C.I. Pigment Yellow 109, C.I. Pigment Yellow 110, and C.I. Pigment Yellow 173. Other examples thereof include quinophthalone compounds, i.e., C.I. Pigment Yellow 138. Among them, C.I. Pigment Yellow 173, C.I. Pigment Yellow 138, and C.I. Pigment Yellow 110 are particularly preferred because of their excellent heat resistance.

The colorant (pigment) contained in the photosensitive composition according to the present invention can be dispersed by mixing powdery pigment particles with a binder for dispersion and optionally a dispersion aid in an organic solvent solution and dispersing the mixture by a conventional method. That is, the dispersion treatment can be performed by kneading using a dispergator/kneader such as a paint shaker, an ultrasonic dispergator, a three-roll mill, a ball mill, a sand mill, a bead mill, a homogenizer, or a kneader.

In this case, carboxylic acid group-containing resins are usable as the resin for dispersion. Further, in the present invention, alkali-soluble crosslinking resins may be used.

The resin for dispersion used is preferably 0.1% by mass to 200% by mass, more preferably 1% by mass to 100% by mass, particularly preferably 2% by mass to 50% by mass, of the organic pigment. When the content of the resin is below the lower limit of the above-defined resin content range, the dispersion stability of the pigment is likely to lower.

In the dispersion procedure, preferably, the organic solvent is used in an amount of at least 100% by mass based on the total amount of the pigment and the resin. When the amount of the solvent is less than 100% by mass, the viscosity in the dispersion procedure is so high that the dispersion procedure particularly with a ball mill, a sand mill, a bead mill or the like is likely to be difficult.

A solvent, which can dissolve the resin for dispersion and can highly wet the pigment used, is preferred as the organic solvent, and examples of preferred solvents include aromatic hydrocarbons, acetic esters, ethers, alcohols, glycol monoethers, glycol monoether acetates, and ketones.

In the dispersion treatment, the whole amount of the resin for dispersion may be used together with the pigment. Alternatively, a part of the resin may be added after the dispersion treatment. Likewise, in the dispersion treatment, the whole amount of the organic solvent may be used together with the pigment, or alternatively a part of the organic solvent may be added after the dispersion treatment.

Dispersion aids include anionic dispersants such as a polycarboxylic acid-type polymer surfactants, or polysulfonic acid-type polymer surfactants, nonionic dispersants such as polyoxyethylene-polyoxypropylene block polymers, and derivatives of organic coloring matters produced by introducing a substituent such as a carboxyl group, a sulfonic acid salt group, a carboxylic acid amide group, or a hydroxyl group into an organic coloring matter such as an anthraquinone, perylene, phthalocyanine, or quinacridone coloring matter.

The use of these dispersion aids can improve the dispersion or dispersion stability of the pigment and thus is preferred. The pigment dispersion aid and the derivative of the organic coloring matter are preferably used in an amount of 50% by mass or less based on the pigment. When the amount of the pigment dispersing aid and the derivative of the organic coloring matter is more than 50% by mass, the chromaticity is likely to misalign.

In the colorant, the mixing ratio between the yellow pigment and the blue pigment is preferably 1:10 to 10:1, more preferably 1:5 to 5:1, most preferably 2:5 to 5:2.

When the yellow pigment and the blue pigment are mixed together at the above mixing ratio, the photosensitive composition or a cured film of the photosensitive composition substantially shows a green color.

Even when the color of the photosensitive composition per se of the present invention is not a green color, contemplated effects can be attained when the cured product of the photosensitive composition according to the present invention is green on a copper clad laminate having a bronze color.

The amount of the colorant incorporated in the photosensitive composition according to the present invention is not particularly limited. When an organic solvent is contained in the photosensitive composition, the amount of the colorant incorporated in the photosensitive composition is preferably 0.01% by mass to 10% by mass, more preferably 0.05% by mass to 8% by mass, most preferably 0.1% by mass to 5% by mass, based on the whole component of the solder resist composition according to the present invention excluding the organic solvent.

When the amount of the pigment in the photosensitive composition is below the lower limit of the above-defined pigment content range, the color density of the photosensitive layer is likely to lower. On the other hand, when the amount of the pigment in the photosensitive composition is above the upper limit of the above-defined pigment amount range, the photosensitivity is likely to lower. That is, when the amount of the pigment incorporated is in the above-defined pigment amount range, a permanent protective film having good visibility in visual inspection can be formed while suppressing a lowering in the curing properties of the resin caused by a reduction in ultraviolet transmission.

In order to provide a photosensitive composition (a photosensitive layer) that can realize high sensitivity to a blue-violet laser beam, the average particle diameter of the yellow pigment contained in the colorant is important. The average particle diameter is preferably 100 nm to 1,000 nm, more preferably 150 nm to 750 nm, most preferably 200 nm to 500 nm.

When the average particle diameter of the yellow pigment is less than 100 nm, the transmission in the photosensitive wavelength region of the photosensitive layer is lowered and, consequently, the sensitivity is low. On the other hand, when the average particle diameter is more than 1,000 nm, the scattering of light is increased resulting in lowered resolution.

The average particle diameter of the blue pigment contained in the colorant is not particularly limited. However, the average particle diameter is preferably 10 nm to 1,000 nm, more preferably 50 nm to 1,000 nm, most preferably 100 nm to 500 nm.

Coarse particles having a size of 1,000 nm or more, preferably 500 nm or more damage the coating face when a coating liquid for the photosensitive layer is coated. Accordingly, preferably, the coarse particles are removed, for example, by a centrifugation method, a sintered filter, or a membrane filtration method.

When the average particle diameter is less than 10 nm, the degree of coloring (optical density) is lowered. Accordingly, in this case, the amount of the pigment particles should be increased to provide a necessary degree of coloring, resulting in increased cost. On the other hand, when the average particle diameter is more than 1,000 nm, satisfactory resolution cannot be realized due to the influence of light scattering.

When the photosensitive composition according to the present invention is prepared, in addition to the colorant, the above-described alkali-soluble photosensitive resin, photopolymerizable compound, thermal crosslinking agent, and photopolymerization initiator or photopolymerization initiation compound, and a heat curing accelerator, an inorganic filler, and other components which will be described later are mixed. These additives may be mixed before or after the dispersion treatment of the colorant.

A method may be adopted in which only a part of the resin for dispersion is used in the dispersion procedure without use of the whole amount of the resin for dispersion and the remaining amount of the resin for dispersion is mixed later, particularly in the preparation of the coating liquid for the photosensitive layer. The amount of each of the components is regulated from the time when the photosensitive composition is prepared so that the formulation of the photosensitive composition is finally as described above.

### <Heat Curing Accelerator>

The heat curing accelerator functions to accelerate heat curing of the epoxy resin compound or the polyfunctional oxetane compound and is suitable for addition to the photosensitive resin. The amount (in terms of solid content ratio) of the thermal crosslinking accelerator in the photosensitive composition is preferably 0.01% by mass to 10% by mass, more preferably 0.1% by mass to 5% by mass, most preferably 0.5% by mass to 3% by mass. When the thermal crosslinking accelerator is below the lower limit of the above-defined thermal crosslinking accelerator amount range, the adhesion of the cured film to the substrate is likely to lower. On the other hand, when the thermal crosslinking accelerator is above the upper limit of the above-defined thermal crosslinking accelerator amount range, the storage stability is likely to lower.

The heat curing accelerator is not particularly limited and may be suitably selected in accordance with the intended use. Examples of heat curing accelerator include amine compounds such as dicyandimide, benzyldimethylamine, 4-(dimethylamino)-N,N-dimethylbenzylamine, 4-methoxy-N,N-dimethylbenzylamine, and 4-methyl-N,N-dimethylbenzylamine; quaternary ammonium salt compounds such as triethylbenzyl ammonium chloride; block isocyanate compounds such as dimethylamine; bicyclic amidine compounds of imidazole derivatives such as imidazole, 2-methylimidazole, 2-ethylimidazole, 2-ethyl-4-methylimidazole, 2-phenylimidazole, 4-phenylimidazole, 1-cyanoethyl-2-phenylimidazole, and 1-(2-cyanoethyl)-2-ethyl-4-methylimidazole, and salts thereof; phosphorus compounds such as triphenylphosphine; guanamine compounds such as melamine, guanamine, acetoguanamine, and benzoguanamine; S-triazine derivatives such as 2,4-diamino-6-methacryloyloxyethyl-S-triazine, 2-vinyl-2,4-diamino-S-triazine, 2-vinyl-4,6-diamino-S-triazine-isocyanuric acid adducts, 2,4-diamino-6-methacryloyloxyethyl-S-triazine-isocyanuric acid adducts, trifluoroborane-amine complex, organic hydrazide; aromatic acid anhydrides such as phthalic anhydride, trimellitic anhydride, ethylene glycol bis(anhydro-trimellitate), glycerol tris(anhydro-trimellitate), benzophenone-tetracarboxylic acid anhydride; aliphatic acid anhydrides such as maleic anhydride, and tetrahydrophthalic anhydride; polyphenols such as polyvinylphenol, polyvinylphenol bromide, phenol novolak, and alkylphenol novolak. These may be used alone or in combination. The compound may be property selected without particular limitations as long as it allows for curing catalyst of the epoxy resin compound and the polyfunctional oxetane compound or it can accelerate a reaction between a carboxyl group and the epoxy resin compound or the polyfunctional oxetane compound, and compounds capable of accelerating thermal curing other than those stated above may be used.

The solid content of the compound capable of accelerating thermal curing between the epoxy resin or the polyfunctional oxetane compound and a carboxylic acid in the solids of the photosensitive composition solution is typically 0.01% by mass to 20% by mass.

### <Inorganic Filler>

The inorganic filler serves to improve the surface hardness of the permanent pattern, or restrain the coefficient of linear expansion of the permanent pattern to low-level, or restrain the dielectric constant and electrical loss tangent of the hardened film itself to low-level.

The inorganic filler is not particularly limited and may be suitably selected from conventional inorganic pigments, and examples thereof include kaolin, barium sulfate, barium titanate, silicon oxide powder, silicon oxide fine powder, silica produced by gas phase process, indefinitely shaped silica, crystalline silica, molten silica, spherically shaped silica, talc, clay, magnesium carbonate, calcium carbonate, aluminum oxide, aluminum hydroxide, and mica.

The average particle diameter of the inorganic filler is preferably 3 μm or less, and more preferably 0.1 μm to 2 μm. When the average particle diameter is larger than 3 μm, the resolution of the photosensitive layer may degrade due to light scattering.

The amount of the inorganic filler used in the photosensitive composition is preferably 5% by mass to 60% by mass, more preferably 10% by mass to 50% by mass, still more preferably 15% by mass to 40% by mass, based on the total solid content. When the amount of the inorganic filler is below the lower limit of the above-defined inorganic filler amount range, the hardness of the cured film is likely to lower. On the other hand, when the amount of the inorganic filler is above the upper limit of the above-defined inorganic filler amount range, the photosensitivity is likely to lower.

Moreover, organic fine particles may be added as necessary. The organic fine particles are not particularly limited and may be suitably selected in accordance with the intended use, and examples thereof include melamine resins, benzoguanamine resins, and crosslinkable polyethylene resins. Spherically shaped fine particles and the like made from silica or crosslinkable resin having an average particle diameter of about 0.1 μm to 2 μm, and an oil absorption of about 100 m²/g to 200 m²/g can be used.

The inorganic filler contains particles having an average particle diameter of 0.1 μm to 2 μm. Accordingly, even when the thickness of the permanent pattern is reduced to 5 μm to 20 μm due to a thickness reduction of the printed wiring board, the inorganic filler particles do not crosslink both sides, i.e., obverse and reverse surfaces, of the permanent pattern. Accordingly, a permanent pattern, which does not cause ion migration even in a high acceleration speed test (HAST) and has excellent heat resistance and moisture resistance, can be formed.

### <Other Components>

If necessary, various additives, for example, thermal polymerization inhibitors for dark reaction suppression purposes (for example, hydroquinone, hydroquinone monomethyl ether, pyrogallol, or t-butyl catechol), titanate coupling agents for an improvement in adhesion to the substrate (for example, silane coupling agents having a vinyl group, an epoxy group, an amino group, or a mercapto group, isopropyl tri(methacryloyl)titanate, or diisopropyl isostearoyl-4-aminobenzoyl titanate), surfactants for an improvement in smoothness of the film (for example, fluoro, silicon, or hydrocarbon surfactants) and other various additives such as ultraviolet absorbers and antioxidants may be added to the photosensitive composition (coating liquid for a photosensitive layer).

The organic solvent is preferably used so that the proportion of the whole solid matter including the organic pigment, the alkali-soluble photosensitive resin, the polymerizable compound, the photopolymerization initiator (or the photopolymerization initiation compound), the thermal crosslinking agent, the heat curing accelerator, and the inorganic filler in the photosensitive composition (coating liquid for photosensitive layer) is 5% by mass to 40% by mass. When the total solid content is more than 40% by mass, the viscosity is high and, consequently, the coatability is likely to lower. On the other hand, when the total solid content is less than 5% by mass, the viscosity is lowered and, consequently, the coatability is likely to lower.

### [Protective Film]

The protective film serves to prevent contamination and damage of the photosensitive layer and protect the photosensitive layer.

The site at which the protective film is formed in the photosensitive film is not particularly limited and may be suitably selected in accordance with the intended use. Typically, the protective film is formed on the photosensitive layer.

Examples of the protective film include those used for the support, silicone paper, paper with polyethylene or polypropylene laminated thereon, polyolefin sheet or polytetrafluoroethylene sheet. Of these, polyethylene films and polypropylene films are preferable.

The thickness of the protective film is not particularly limited and may be suitably selected in accordance with the intended use, and for example, the thickness is preferably 5 μm to 100 μm, and more preferably 8 μm to 30 μm.

When the protective film is used, it is preferable that an adhesive strength A between the photosensitive layer and the support, and an adhesive strength B between the photosensitive layer and the protective film satisfy the relation, adhesive strength A>adhesive strength B.

The combinations of the support and the protective film, i.e. (support/protective film), are exemplified by (polyethylene terephthalate/polypropylene), (polyethylene terephthalate/polyethylene), (polyvinyl chloride/cellophane), (polyimide/polypropylene), and (polyethylene terephthalate/polyethylene terephthalate). Further, the surface treatment of the support and/or the protective film may result in the relation of the force set forth above. The surface treatment of the support may be utilized for enhancing the adhesive force with the photosensitive layer; examples of the surface treatment include deposition of under-coat layer, corona discharge treatment, flame treatment, ultraviolet-ray treatment, radio frequency exposure treatment, glow discharge treatment, active plasma treatment, and laser beam treatment.

The static friction coefficient between the support and the protective film is preferably 0.3 to 1.4, and more preferably 0.5 to 1.2.

When the static friction coefficient is less than 0.3, winding displacement may generate in roll configuration due to excessively high slipperiness, and when the static friction coefficient is more than 1.4, winding of the material in a roll configuration may be difficult.

The protective film may be subjected to a surface treatment in order to control the adhesive property between the protective film and the photosensitive layer. The surface treatment can be performed, for example, by forming an under-coat layer of polymer such as polyorganosiloxane, fluorinated polyolefin, polyfluoroethylene, and polyvinyl alcohol on the surface of the protective film. The under-coat layer may be formed by applying the coating solution for the polymer over the surface of the protective film, then drying the coated surface at 30° C. to 150° C., in particular 50° C. to 120° C., for 1 minute to 30 minutes.

### [Other Layers]

The photosensitive film of the present invention may have a cushion layer, an oxygen-barrier layer (PC layer), a peeling layer, an adhesive layer, a light absorption layer, and a surface protective layer and the like, in addition to the photosensitive layer, the support and the protective film.

The configuration, thickness and the like of the other layers in the photosensitive film are not particularly limited and may be suitably selected in accordance with the intended use.

The cushion layer has no tucking ability at room temperature, however, the layer is melted to flow when formed under vacuum and heating conditions.

The PC layer typically contains polyvinyl alcohol as main components, and the thickness of the formed PC layer is about 1.5 μm.

The photosensitive film is formed in an elongated sheet and wound to a cylindrical core tube in a roll shape for storage. The length of the photosensitive film is not particularly limited and may be suitably selected from 10 m to 20,000 m, for example. The photosensitive film may be subjected to slit processing in a user-friendly manner such that the elongated photosensitive film of 100 m to 1,000 m is rolled in a roll shape. In this case, it is preferable that the photosensitive film is wound to a cylindrical core tube such that the support constitutes the outermost of the roll. Further, the rolled photosensitive film may be slit in sheet-like shape. During storage period, preferably a separator which is moisture proof and contains a drying agent is arranged at the edge faces from the perspective of protection of the edge faces and preventing edge fusion; and a material of lower moisture vapor permeability is preferably used for packaging.

The photosensitive film of the present invention includes a photosensitive layer of a laminated photosensitive composition that represents excellent shelf stability, superior chemical resistance after development, higher surface hardness, and sufficient thermal resistance. Accordingly, the photosensitive films according to the present invention may be widely applied to, for example, production of printed wiring boards, display members such as column members, rib members, spacers, and partition members; permanent patterns such as holograms, micro machines, and proofs. In particular, the photosensitive film can be preferably used for forming permanent patterns of a printed wiring board.

In particular, since the photosensitive film of the present invention has a uniform film thickness, even though the permanent pattern (a protective film, a interlayer insulating film or a solder resist) is formed into a thin layer when forming the permanent pattern, a permanent pattern, which does not cause ion migration even in a high acceleration speed test (HAST) and has excellent heat resistance and moisture resistance, can be formed. As a result, the pattern forming material can be finely and precisely formed on a surface of the substrate.

### (Method for Forming Permanent Pattern)

According to a method for forming a permanent pattern of the present invention, a photosensitive film of the present invention is laminated on a surface of the substrate by any one of heating and pressurizing, and then the photosensitive film is exposed and developed so as to form a permanent pattern.

Hereinafter, through the explanation of a method for forming a permanent pattern of the present invention, a permanent pattern produced by the method will be specifically explained.

### —Substrate—

Material of the substrate is not particularly limited and may be suitably selected from among materials known in the art ranging from those having high surface smoothness to those each having convexoconcave thereon. However, a plate-like base material (substrate) is preferable, and specific examples thereof include known substrates for forming printed wiring boards (such as copper clad laminate), glass plates (such as soda glass plate), synthetic resin films, papers, and metal plates. Of these, printed wiring boards are preferable, and printed wiring boards on which wiring has been formed are particularly preferable in that it can highly closely mount a semiconductor and components on a multilayered interconnection substrate, a build-up interconnection substrate, or the like.

The laminate includes the photosensitive layer provided on a substrate. A permanent pattern can be formed by exposing the photosensitive layer by an exposure step which will be described later, curing the exposed areas, and subjecting the treated photosensitive layer to a development step.

### [Lamination Step]

The laminate can be formed by any method without particular limitation, and the method for laminate formation may be suitably selected according to the purpose. Preferably, the laminate is formed by separating the protective film from the photosensitive film and superimposing and stacking the photosensitive layer onto the substrate while applying any one of heat or pressure to the photosensitive film.

The heating temperature is not particularly limited and may be suitably adjusted in accordance with the intended use, for example, the heating temperature is preferably 70° C. to 130° C., and more preferably 80° C. to 110° C.

The pressure at the pressurization is not particularly limited and may be suitably adjusted in accordance with the intended use, for example, the pressure is preferably 0.01 MPa to 1.0 MPa, and more preferably 0.05 MPa to 1.0 MPa.

An apparatus used to perform any one of the heating and pressurization is not particularly limited and may be suitably selected in accordance with the intended use. Preferred examples thereof include heat presses and heat roll laminators (such as VP-II, manufactured by Taisei Laminator Co., Ltd.), vacuum laminators (VP130, manufactured by Nichigo-Morton Co., Ltd.).

### [Exposure Step]

Regarding the method for exposing a pattern forming material (for example, a photosensitive laminate) according to the present invention, an exposure step utilizing a maskless pattern exposure system (digital exposure) in which a two-dimensional image is formed by relative scanning exposure while modulating light based on image data will be mainly explained.

Digital exposure is an exposing method in which relative scanning is performed while light modulation based on image data using two-dimensionally arranged spatial light modulation devices to form a two-dimensional image.

More specifically, the digital exposure is an exposure method including exposing pattern-wise a photosensitive layer without use of a “mask” unlike a conventional mask exposure method (referred to also as analog exposure) including disposing an object called a “mask,” which is formed of a material not permeable to exposure light or having low permeability exposure light and has an image formed therein (an exposure pattern; hereinafter referred to also as pattern), in an optical path of the exposure light and exposing a photosensitive layer in a pattern corresponding to the image.

In the digital exposure, an ultra-high pressure mercury lamp or a laser beam is used as a light source.

The ultra-high pressure mercury lamp is a discharge lamp including mercury sealed into a quartz glass tube or the like. In the ultra-high pressure mercury lamp, the vapor pressure of mercury is set to a high value to enhance the luminescence efficiency (in some ultra-high pressure mercury lamp, the vapor pressure of mercury during lighting is about 5 MPa. W. Elenbaas: Light Sources, Philips Technical Library 148-150). Among bright line spectra, a single exposure wavelength of 405 nm±40 nm is used and h line (405 nm) is mainly used.

The laser is an oscillator and an amplifier, which utilize an induced emission phenomenon that occurs in a material having a population inversion to provide a single monochromatic light having higher interference and directionality by amplification and oscillation of light waves. Excitation materials include liquid crystals, glass, liquids, coloring matters, and gases. Conventional lasers such as solid state lasers (YAG lasers), liquid lasers, gas lasers (argon lasers, He—Ne lasers, carbon dioxide lasers, or excimer lasers), and semiconductor lasers from these media may be used in the above wavelength region.

The semiconductor laser is a laser using a light emitting diode that causes induced emission of coherent light by pn junction when electrons and holes flow out to a junction area, for example, by carrier injention, excitation with electron beams, ionization by collision, or photoexcitation. The wavelength of the emitted coherent light is determined by the semiconductor compound. The wavelength of the laser is a single exposure wavelength of 405 nm±40 nm.

In the present invention, the single exposure wavelength refers to a main wavelength in the case of exposure with laser and in the case of exposure with an ultra-high pressure mercury lamp, refers to an exposure wavelength obtained by removing bright lines other than 405 nm, that is, a wavelength of 365 nm and wavelengths larger than 405 nm, through an ND filter or the like to provide only one wavelength as the main wavelength.

The exposure method is not particularly limited and may be suitably selected according to the purpose. Among others, digital exposure using laser beams is preferred.

The digital exposure may be carried out by any unit without particular limitation, and the unit may be suitably selected according to the purpose. The unit is described, for example, in Japanese Patent Application Laid-Open (JP-A) No. 2005-311305 and Japanese Patent Application Laid-Open (JP-A) No. 2007-10785, and examples thereof include light irradiation unit for light irradiation and light modulation units for light modulation that modulates light applied from the light irradiation unit according to information of a pattern to be formed.

The digital exposure is not particularly limited and may be suitably selected according to the purpose. For example, preferably, the digital exposure is performed by generating control signals based on information about a pattern to be formed and using light modulated according to the control signals. For example, the following method is preferably used. Specifically, for the exposure of the photosensitive layer, an exposure head is provided. The exposure head includes a light irradiation unit and a light modulation unit that includes two-dimensionally arranged n pieces (wherein n is a natural number of 2 or more) of pixel parts, which receive light from the light irradiation unit and allows the light to exit therefrom, and can control the pixel parts according to pattern information. The exposure heads are disposed so that the direction of pixel part columns makes a predetermined set inclination angle θ with the scanning direction of the exposure head. In the exposure head, pixel parts used in N-fold exposure, wherein N is a natural number of 2 or more, are specified among the above usable pixel parts by a service pixel part specifying unit. For the exposure head, the pixel part control unit controls the pixel parts so that only the pixel parts specified by the service pixel part specifying unit participate in the exposure, and the exposure head is moved relatively to the photosensitive layer in a scanning direction to each other to expose the photosensitive layer.

In the present invention, the term “N-fold exposure” refers to exposure set so that, in substantially all areas in the exposed areas on an exposure surface on the photosensitive layer, straight lines parallel to the scanning direction of the exposure head intersect N light spot columns (pixel columns) applied onto the exposure surface. Here the term “light spot columns (pixel columns)” refer to the sequence of light spots (pixels) as pixel units, which have a smaller angle to the scanning direction of the exposure head, among the light spots (pixels) as pixel units generated by the pixel parts. The arrangement of the pixel parts is not always limited to a rectangular lattice form, and the pixel parts may be disposed, for example, in a parallelogram form.

The description of the “substantially all areas” in the exposed areas is derived from the fact that, due to inclination of the pixel part column in both-side parts of each pixel part, the number of pixel part columns in the pixel parts used that intersect a straight line parallel to the scanning direction of the exposure head is reduced and, thus, in this case, even when a plurality of exposure heads connected to each other is used, due to the occurrence of an error, for example, in mounting angle and arrangement in the exposure head, in some cases, the number of pixel part columns in the pixel parts used that intersect the straight line parallel to the scanning direction is slightly increased or decreased, and that, in a very small part equal to or smaller than the resolution in connections between pixel part columns in each pixel part used, due to the occurrence of an error, for example, in mounting angle and arrangement in the exposure head, the pitch of the pixel part along a direction orthogonal to the scanning direction is not exactly equal to the pitch of the pixel parts in other parts, and, consequently, the number of pixel part columns of the pixel parts used that intersect the straight line parallel to the scanning direction is increased or decreased within ±1. In the following description, N-fold exposures, wherein N is a natural number of 2 or more, are collectively referred to as “multiple exposure.” Further, in the following description, in an embodiment wherein the exposure apparatus or exposure method according to the present invention are used as an imaging apparatus and an imaging method, “N-fold imaging” and “multiple imaging” are used as the term corresponding to the “N-fold exposure” and the term corresponding to the “multiple exposure,” respectively.

N in the N-fold exposure may be any natural number of 2 or more without particular limitation, and the value of N may be suitably selected according to the purpose. A natural number of 3 or more is preferred, and a natural number of 3 to 7 is more preferred.

The wavelength of the laser beam in the present invention is not particularly limited and may be suitably selected according to the purpose. However, the wavelength of the laser beam is preferably 330 nm to 650 nm, more preferably 365 nm to 445 nm, particularly preferably 395 nm to 415 nm, from the viewpoint of shortening the exposure time of the photosensitive composition.

The beam diameter of the laser is not particularly limited. However, among others, the beam diameter of the laser is preferably 5 μm to 30 μm, more preferably 7 μm to 20 μm, in terms of 1/e² in a Gaussian beam from the viewpoint of the resolution of deep color partition walls.

The amount of energy of the laser beam is not particularly limited. However, among others, the amount of energy of the laser beam is preferably 1 mJ/cm² to 100 mJ/cm², more preferably 5 mJ/cm² to 50 mJ/cm², from the viewpoints of exposure time and resolution.

In the present invention, the laser beam should be subjected to spatial light modulation according to the image data. To this end, the use of a digital microdevice as a spatial light modulation element described in [0173] to [0174] of JP-A No. 2005-311305 is preferred.

For example, a laser direct imaging apparatus “INPREX IP-3000 (manufactured by FUJIFILM Corporation)” can be used as the exposure apparatus. The exposure apparatus according to the present invention, however, is not limited to this exposure apparatus.

### [Other Steps]

Other steps can be performed without particular limitation and may be suitably selected from conventional patterning forming steps, and examples thereof include a development step and a curing treatment step.

### [Developing Step]

In the developing step, the photosensitive layer is exposed in the exposing step, exposed areas of the photosensitive layer are hardened, and unhardened regions are removed, thereby developing the photosensitive layer surface to form a permanent pattern.

The method of removing unhardened regions is not particularly limited and may be suitably selected in accordance with the intended use. Examples thereof include a method in which unhardened regions are removed using a developer.

The developer is not particularly limited and may be suitably selected in accordance with the intended use. Preferred examples of the developers include hydroxides of alkaline metals and alkaline earth metals or aqueous solutions of carbonates, hydrogen carbonates, ammonia water, and tetraammonium salts. Of these, a sodium carbonate aqueous solution is particularly preferable.

The developer may be combined with surfactants, defoamers; organic bases such as benzylamine, ethylene diamine, ethanol amine, tetramethylene ammonium hydroxide, diethylene triamine, triethylene pentamine, morpholine, and triethanol amine; organic solvents to promote developing such as alcohols, ketones, esters, ethers, amides, and lactones. The developer may be an aqueous developer obtained by combining water or aqueous alkali solutions and organic solvent, or organic solvent alone.

### [Hardening Treatment Step]

The method for forming the permanent pattern of the present invention preferably further includes a hardening treatment step.

In the hardening treatment step, the photosensitive layer in the permanent pattern which is formed in the developing step is subjected to a hardening treatment.

The hardening treatment is not particularly limited and may be suitably selected in accordance with the intended use. Examples thereof include an entire surface exposing treatment, and an entire surface heating treatment.

For the method of subjecting the photosensitive layer to the entire surface exposing treatment, a method is exemplified in which after the developing step, the entire surface of the photosensitive laminate with the permanent pattern formed thereon is exposed. Exposing the entire surface of the photosensitive laminate accelerates hardening of the resin in the photosensitive composition which forms the photosensitive layer to thereby harden the surface of the permanent pattern.

An apparatus to perform the exposure of the entire surface is not particularly limited and may be suitably selected in accordance with the intended use. Preferred examples of the apparatus include UV exposers such as ultrahigh pressure mercury lamp.

For the method of subjecting the photosensitive layer to the entire surface heating treatment, a method is exemplified in which after the developing step, the entire surface of the photosensitive laminate with the permanent pattern formed thereon is heated. Heating the entire surface of the photosensitive laminate can enhance the film strength of the permanent pattern surface.

The heating temperature of the entire surface heating is preferably 120° C. to 250° C., and more preferably 120° C. to 200° C. When the heating temperature is less than 120° C., the effect of enhancing the film strength that would be obtainable from a heat treatment may not be obtained. When the heating temperature is more than 250° C., the quality of the film may be weakened and brittle due to decomposition of the resin in the photosensitive composition.

The heating time in the entire surface heating treatment is preferably 10 minutes to 120 minutes, and more preferably 15 minutes to 60 minutes.

An apparatus to perform the entire surface heating is not particularly limited and may be suitably selected from among conventional apparatuses. For example, dry oven, hot plate, IR heater are exemplified.

When the substrate is a printed wiring board such as a multilayered interconnection substrate, a permanent pattern of the present invention can be formed on the printed wiring board, and further, the surface of the printed wiring board can be soldered as follows.

In other words, a hardened layer which is the permanent pattern is formed in the developing step, and a metal layer is exposed on the surface of the printed wiring board. The regions of the metal layer exposed on the surface of the printed wiring board are plated with gold and is then soldered. On the soldered regions, semiconductor, and components are mounted. At this point in time, the permanent pattern made of the hardened layer exerts a function as a protective film or an insulating film (interlayer insulating film) to block external impact shock and conduction between neighboring electrodes.

In the method for forming a permanent pattern of the present invention, preferably, at least any one of a protective film and an interlayer insulating film is formed. When the permanent pattern formed according to the permanent pattern forming process of the present invention is of the protective layer or the interlayer insulating film, the interconnection can be protected from external impact shock and bending. Particularly when the permanent patter is of the interlayer insulating film, it is effective in high-density mounting of semiconductors and components onto multilayered interconnection substrates, build-up interconnection substrates, and the like.

The method for forming a permanent pattern according to the present invention can realize pattern formation at a high speed and thus can be widely used in the formation of various patterns. In particular, the method is suitable for use in wiring pattern formation.

Further, the permanent pattern formed by the method for forming a permanent pattern according to the present invention has excellent surface hardness, insulating properties, heat resistance, moisture resistance and other properties and is suitable for use as protective films, interlayer insulating films, and solder resist patterns.

### EXAMPLES

The following examples further illustrate the present invention. However, it should be noted that the present invention is not limited by the examples. All percentages and parts are by mass unless indicated otherwise.

### Synthesis Example 1

In 1,000-mL three-necked flask, 159 g of 1-methoxy-2-propanol was placed, and was heated to 85° C. under a nitrogen gas stream. A solution of 63.4 g of benzyl methacrylate, 72.3 g of methacrylic acid, and 4.15 g of V-601 (manufactured by Wako Pure Chemical Industries, Ltd.) in 159 g of 1-methoxy-2-propanol was added dropwise to the reaction solution over a period of 2 hours. After the completion of the dropwise addition, the reaction solution was heated for additional 5 hours to allow a reaction to proceed. The heating was then stopped, and a benzyl methacrylate/methacrylic acid (molar ratio=30/70%) copolymer was obtained.

A portion (120.0 g) of the copolymer solution was transferred to a 300-mL three-necked flask. 16.6 g of glycidyl methacrylate and 0.16 g of p-methoxyphenol were added thereto, and the mixture was stirred for dissolution. After the dissolution, 2.4 g of tetraethylammonium chloride was added to the solution. The mixture was heated to 100° C., and an addition reaction was allowed to proceed. The disappearance of glycidyl methacrylate was confirmed by gas chromatography, and the heating was stopped. To this mixture, 1-methoxy-2-propanol was added to prepare a solution of Polymer compound 1 having a solid content of 50% shown in Table 1.

The mass average molecular weight (Mw) of the polymer compound was measured by gel-permeation chromatography (GPC) using polystyrene as a standard substance and was found to be 15,000.

The acid value (carboxyl group content) per solid matter was 2.2 meq/g as measured by titration with sodium hydroxide.

Further, the content (C═C value) of ethylenically unsaturated bond per solid matter was determined by iodine value titration and was found to be 2.1 meq/g.

### Synthesis Example 2

To a four-necked flask equipped with a reflux condenser, a thermometer, a glass tube for nitrogen replacement, and a stirrer, 70 parts of Blenmer GS (manufactured by Nippon Oils & Fats Co., Ltd., glycidyl methacrylate having a lowered chlorine content, halogen content: 1 ppm or less), 30 parts of methyl methacrylate, 100 parts of carbitol acetate, and 3 parts of azobisisobutyronitrile were added. The contents of the flask were heated with stirring under a nitrogen gas stream at 80° C. for 5 hours to allow a polymerization reaction to proceed and thus to give a 50% copolymer solution.

To the 50% copolymer solution, 0.05 part of hydroquinone, 37 parts of acrylic acid, and 0.2 part of dimethylbenzylamine were added, and an addition reaction was allowed to proceed at 100° C. for 24 hours.

Subsequently, 45 parts of tetrahydrophthalic anhydride and 79 parts of carbitol acetate were added thereto, and a reaction was allowed to proceed at 100° C. for 3 hours to give a 50% solution of an ultraviolet curable resin (A2).

### Dispersion Example 1

The following pigment dispersion composition and 30 parts of glass beads having a diameter of 2 mm were placed in a 200-mL polyethylene container, followed by dispersion with a paint shaker (manufactured by TOYO SEIKI Co., Ltd.) for one hr to give Dispersion 1 of a yellow pigment as shown in Table 1. The particles of Dispersion 1 were measured with a laser scattering-type particle size distribution measuring apparatus. As a result, the average particle diameter was 340 nm. The results are shown in Table 1.

### [Pigment Dispersion Composition]

| | |
|---|---|
| Polymer compound 1 | 9.1 parts |
| SANDORIN YELLOW 6GL (manufactured by Ciba Specialty | 10 parts |
| Chemicals Inc., C.I. Pigment Yellow 173), structural formula | |
| (1) below) | |
| SOLSPERSE S-20000 (manufactured by ICI) | 0.28 parts |
| Propylene glycol monomethyl ether acetate | 50.4 parts |

Structural formula (1)

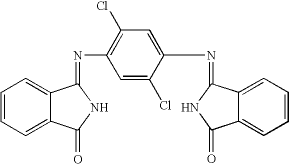

### Dispersion Example 2

Dispersion 2 was prepared in the same manner as in Dispersion Example 1, except that the dispersion time was 2 hours. The results are shown in Table 1. The average particle diameter was 160 nm.

### Dispersion Example 3

Dispersion 3 was prepared in the same manner as in Dispersion Example 1, except that the dispersion time was 0.5 hours. The results are shown in Table 1. The average particle diameter was 1,250 nm.

### Dispersion Example 4

A dispersion having the same composition as the dispersion in Dispersion Example 1 was previously mixed. Thereafter, dispersing was carried out using zirconia beads having a diameter of 1.0 mm with MOTORMILL M-200 (manufactured by Eiger Japan K.K.) at a peripheral velocity of 9 m/s for 24 hours to prepare Dispersion 4 of a yellow pigment as shown in Table 1. The results are shown in Table 1. The size of 20 arbitrary particles was measured by observation of the particles under a transmission electron microscope (TEM) and photographs of the particles. As a result, it was found that the average particle diameter was 60 nm.

### Dispersion Example 5

The following pigment dispersion composition and 30 parts of glass beads having a diameter of 2 mm were placed in a 200-mL polyethylene container, followed by dispersion with a paint shaker (manufactured by TOYO SEIKI Co., Ltd.) for one hour to give Dispersion 5 of a yellow pigment as shown in Table 1. The particles of Dispersion 5 were measured with a laser scattering-type particle size distribution measuring apparatus. As a result, the average particle diameter was 260 nm. The results are shown in Table 1.

### [Pigment Dispersion Composition]

| | |
|---|---|
| Polymer compound 1 | 9.1 parts |
| SEIKAFAST YELLOW 2770 (manufactured by Dainichiseika Color & Chemicals | 10 parts |
| Manufacturing Co., Ltd., C.I. Pigment Yellow 83), structural formula (2) below) | |
| SOLSPERSE S-20000 (manufactured by ICI) | 0.28 parts |
| Propylene glycol monomethyl ether acetate | 50.4 parts |

Structural formula (2)

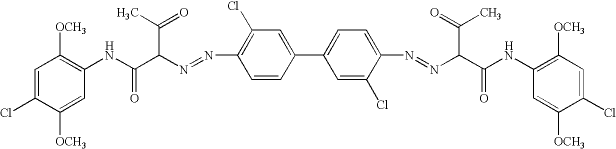

### Dispersion Example 6

The following pigment dispersion composition and 30 parts of glass beads having a diameter of 2 mm were placed in a 200-mL polyethylene container, followed by dispersion with a paint shaker (manufactured by TOYO SEIKI Co., Ltd.) for two hours to give Dispersion 6 of a yellow pigment as shown in Table 1. The particles of Dispersion 6 were measured with a laser scattering-type particle size distribution measuring apparatus. As a result, the average particle diameter was 520 nm. The results are shown in Table 1.

### [Pigment Dispersion Composition]

| | |
|---|---|
| Polymer compound 1 | 9.1 parts |
| YELLOW 2RLT (manufactured by Ciba Specialty Chemicals | 10 parts |
| Industries Co., Ltd., C.I. Pigment Yellow 109), structural | |
| formula (3) below) | |
| SOLSPERSE S-20000 (manufactured by ICI) | 0.28 parts |
| Propylene glycol monomethyl ether acetate | 50.4 parts |

Structural formula (3)

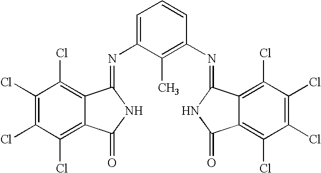

### Dispersion Example 7

The following pigment dispersion composition and 30 parts of glass beads having a diameter of 2 mm were placed in a 200-mL polyethylene container, followed by dispersion with a paint shaker (manufactured by TOYO SEIKI Co., Ltd.) for two hours to give Dispersion 7 of a yellow pigment as shown in Table 1. The particles of Dispersion 7 were measured with a laser scattering-type particle size distribution measuring apparatus. As a result, the average particle diameter was 350 nm. The results are shown in Table 1.

### [Pigment Dispersion Composition]

| | |
|---|---|
| Polymer compound 1 | 9.1 parts |
| CROMOPHTAL YELLOW 3RT (manufactured by Ciba | 10 parts |
| Specialty Chemicals Inc., C.I. Pigment Yellow 110), | |
| structural formula (4) below) | |
| SOLSPERSE S-20000 (manufactured by ICI) | 0.28 parts |
| Propylene glycol monomethyl ether acetate | 50.4 parts |

Structural formula (4)

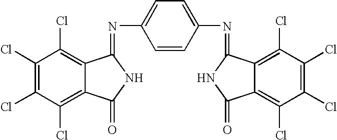

### Dispersion Example 8

The following pigment dispersion composition and 30 parts of glass beads having a diameter of 2 mm were placed in a 200-mL polyethylene container, followed by dispersion with a paint shaker (manufactured by TOYO SEIKI Co., Ltd.) for two hours to give Dispersion 8 of a yellow pigment as shown in Table 1. The particles of Dispersion 8 were measured with a laser scattering-type particle size distribution measuring apparatus. As a result, the average particle diameter was 400 nm. The results are shown in Table 1.

### [Pigment Dispersion Composition]

| | |
|---|---|
| Polymer compound 1 | 9.1 parts |
| PALIOTOL YELLOW D0960 (manufactured by Baden | 10 parts |
| Aniline and Soda Manufacturing, C.I. Pigment Yellow 138), | |
| structural formula (5) below) | |
| SOLSPERSE S-20000 (manufactured by ICI) | 0.28 parts |
| Propylene glycol monomethyl ether acetate | 50.4 parts |

Structural formula (5)

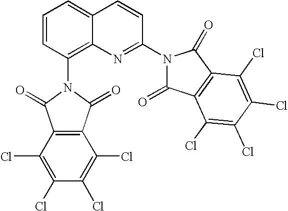

### Dispersion Example 9

The following pigment dispersion composition and 30 parts of glass beads having a diameter of 2 mm were placed in a 200-mL polyethylene container, followed by dispersion with a paint shaker (manufactured by TOYO SEIKI Co., Ltd.) for two hours to give Dispersion 9 of a yellow pigment as shown in Table 2. The particles of Dispersion 9 were measured with a laser scattering-type particle size distribution measuring apparatus. As a result, the average particle diameter was 420 nm. The results are shown in Table 2.

### [Pigment Dispersion Composition]

| | |
|---|---|
| Polymer compound 1 | 9.1 parts |
| FAST YELLOW FGL (manufactured by Dainichiseika Color | 10 parts |
| & Chemicals Manufacturing Co., Ltd., C.I. Pigment Yellow | |
| 97), structural formula (6) below) | |
| SOLSPERSE S-20000 (manufactured by ICI) | 0.28 parts |
| Propylene glycol monomethyl ether acetate | 50.4 parts |

Structural formula (6)

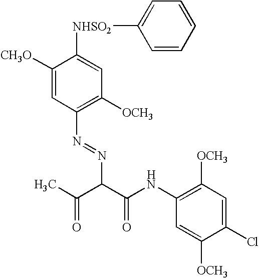

### Dispersion Example 10

The following pigment dispersion composition and 30 parts of glass beads having a diameter of 2 mm were placed in a 200-mL polyethylene container, followed by dispersion with a paint shaker (manufactured by TOYO SEIKI Co., Ltd.) for two hours to give Dispersion 10 of a yellow pigment as shown in Table 2. The particles of Dispersion 10 were measured with a laser scattering-type particle size distribution measuring apparatus. As a result, the average particle diameter was 380 nm. The results are shown in Table 2.

### [Pigment Dispersion Composition]

| | |
|---|---|
| Polymer compound 1 | 9.1 parts |
| DISAZO YELLOW AAPT (manufactured by Dainichiseika Color & Chemicals | 10 parts |
| Manufacturing Co., Ltd., C.I. Pigment Yellow 55), structural formula (7) below) | |
| SOLSPERSE S-20000 (manufactured by ICI) | 0.28 parts |
| Propylene glycol monomethyl ether acetate | 50.4 parts |

Structural formula (7)

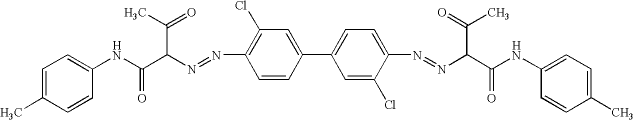

### Dispersion Example 11

The following pigment dispersion composition and 30 parts of glass beads having a diameter of 2 mm were placed in a 200-mL polyethylene container, followed by dispersion with a paint shaker (manufactured by TOYO SEIKI Co., Ltd.) for two hours to give Dispersion 11 of a yellow pigment as shown in Table 2. The particles of Dispersion 11 were measured with a laser scattering-type particle size distribution measuring apparatus. As a result, the average particle diameter was 230 nm. The results are shown in Table 2.

### [Pigment Dispersion Composition]

| | |
|---|---|
| Polymer compound 1 | 9.1 parts |
| PALIOTOL YELLOW D1155 (manufactured by CLARIANT, | 10 parts |
| C.I. Pigment Yellow 185), structural formula (8) below) | |
| SOLSPERSE S-20000 (manufactured by ICI) | 0.28 parts |
| Propylene glycol monomethyl ether acetate | 50.4 parts |

Structural formula (8)

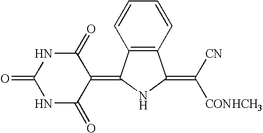

### Dispersion Example 12

The following pigment dispersion composition and 30 parts of glass beads having a diameter of 2 mm were placed in a 200-mL polyethylene container, followed by dispersion with a paint shaker (manufactured by TOYO SEIKI Co., Ltd.) for two hours to give Dispersion 12 of a yellow pigment as shown in Table 2. The particles of Dispersion 12 were measured with a laser scattering-type particle size distribution measuring apparatus. As a result, the average particle diameter was 430 nm. The results are shown in Table 2.

### [Pigment Dispersion Composition]

| | |
|---|---|
| Polymer compound 1 | 9.1 parts |
| CHROMOPHTHAL YELLOW 2RF (manufactured by Ciba | 10 parts |
| Specialty Chemicals Inc., C.I. Pigment Yellow 139), | |
| structural formula (9) below) | |
| SOLSPERSE S-20000 (manufactured by ICI) | 0.28 parts |
| Propylene glycol monomethyl ether acetate | 50.4 parts |

Structural formula (9)

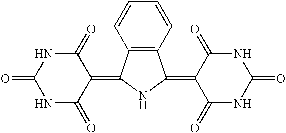

### Dispersion Example 13

The following pigment dispersion composition and 30 parts of glass beads having a diameter of 2 mm were placed in a 200-mL polyethylene container, followed by dispersion with a paint shaker (manufactured by TOYO SEIKI Co., Ltd.) for two hours to give Dispersion 13 of a blue pigment as shown in Table 2. The particles of Dispersion 13 were measured with a laser scattering-type particle size distribution measuring apparatus. As a result, the average particle diameter was 280 nm. The results are shown in Table 2.

### [Pigment Dispersion Composition]

| | |
|---|---|
| Polymer compound 1 | 9.1 parts |
| HELIOGEN BLUE D707PB (manufactured by Baden Aniline | 10 parts |
| and Soda Manufacturing, C.I. Pigment Blue 15:3), structural | |
| formula (10) below) | |
| SOLSPERSE S-20000 (manufactured by ICI) | 0.28 parts |
| Propylene glycol monomethyl ether acetate | 50.4 parts |

Structural formula (10)

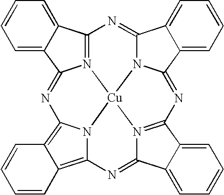

### Dispersion Example 14

The following pigment dispersion composition and 30 parts of glass beads having a diameter of 2 mm were placed in a 200-mL polyethylene container, followed by dispersion with a paint shaker (manufactured by TOYO SEIKI Co., Ltd.) for one hour to give Dispersion 14 of a blue pigment as shown in Table 2. The particles of Dispersion 13 were measured with a laser scattering-type particle size distribution measuring apparatus. As a result, the average particle diameter was 330 nm. The results are shown in Table 2.

### [Pigment Dispersion Composition]

| | |
|---|---|
| Polymer compound 1 | 9.1 parts |
| CYANINE BLUE 5025 (manufactured by Dainichiseika Color | 10 parts |
| & Chemicals Manufacturing Co., Ltd., C.I. Pigment Blue | |
| 15:1), structural formula (11) below) | |
| SOLSPERSE S-20000 (manufactured by ICI) | 0.28 parts |
| Propylene glycol monomethyl ether acetate | 50.4 parts |

Structural formula (11)

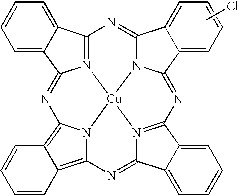

### Dispersion Example 15

The following pigment dispersion composition and 30 parts of glass beads having a diameter of 2 mm were placed in a 200-mL polyethylene container, followed by dispersion with a paint shaker (manufactured by TOYO SEIKI Co., Ltd.) for two hours to give Dispersion 15 of a green pigment as shown in Table 2. The particles of Dispersion 15 were measured with a laser scattering-type particle size distribution measuring apparatus. As a result, the average particle diameter was 380 nm. The results are shown in Table 2.

### [Pigment Dispersion Composition]

| | |
|---|---|
| Polymer compound 1 | 9.1 parts |
| CYANINE GREEN 2G-550-D (manufactured by | 10 parts |
| Dainichiseika Color & Chemicals Manufacturing Co., Ltd., | |
| C.I. Pigment Green 7) structural formula (12) below) | |
| SOLSPERSE S-20000 (manufactured by ICI) | 0.28 parts |
| Propylene glycol monomethyl ether acetate | 50.4 parts |

Structural formula (12)

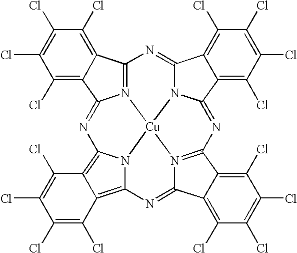

### (Pigment-Free Solution C1)

Pigment-free solution C1 as shown in Table 2 was produced by the dissolution of the following pigment dispersion composition.

### [Solution Composition]

| | |
|---|---|
| Polymer compound 1 | 9.1 parts |
| SOLSPERSE S-20000 (manufactured by ICI) | 0.28 parts |
| Propylene glycol monomethyl ether acetate. | 50.4 parts |

TABLE 1

| | Dispersion 1 | Dispersion 2 | Dispersion 3 | Dispersion 4 | Dispersion 5 | Dispersion 6 | Dispersion 7 | Dispersion 8 |
|---|---|---|---|---|---|---|---|---|
| C.I. Pigment | 10.0 | 10.0 | 10.0 | 10.0 | | | | |
| Yellow 173 | | | | | | | | |
| C.I. Pigment | | | | | 10.0 | | | |
| Yellow 83 | | | | | | | | |
| C.I. Pigment | | | | | | 10.0 | | |
| Yellow 109 | | | | | | | | |
| C.I. Pigment | | | | | | | 10.0 | |
| Yellow 110 | | | | | | | | |
| C.I. Pigment | | | | | | | | 10.0 |
| Yellow 138 | | | | | | | | |
| C.I. Pigment | | | | | | | | |
| Yellow 97 | | | | | | | | |
| C.I. Pigment | | | | | | | | |
| Yellow 55 | | | | | | | | |
| C.I. Pigment | | | | | | | | |
| Yellow 185 | | | | | | | | |
| C.I. Pigment | | | | | | | | |
| Yellow 139 | | | | | | | | |
| C.I. Pigment | | | | | | | | |
| Blue 15:3 | | | | | | | | |
| C.I. Pigment | | | | | | | | |
| Blue 15:1 | | | | | | | | |
| C.I. Pigment | | | | | | | | |
| Green 7 | | | | | | | | |
| Polymer | 9.10 | 9.10 | 9.10 | 9.10 | 9.10 | 9.10 | 9.10 | 9.10 |
| compound 1 | | | | | | | | |
| SOLSPERSE | 0.28 | 0.28 | 0.28 | 0.28 | 0.28 | 0.28 | 0.28 | 0.28 |
| 20000 | | | | | | | | |
| Propylene | 50.4 | 50.4 | 50.4 | 50.4 | 50.4 | 50.4 | 50.4 | 50.4 |
| glycol mono- | | | | | | | | |
| methyl ether | | | | | | | | |
| acetate | | | | | | | | |
| Halogen | 15.8 | 15.8 | 15.8 | 15.8 | 15.8 | 15.8 | 15.8 | 40.0 |
| content of | | | | | | | | |
| pigment | | | | | | | | |
| molecule (%) | | | | | | | | |
| Average | 340 | 160 | 1250 | 60 | 260 | 520 | 350 | 400 |
| particle | | | | | | | | |
| diameter of | | | | | | | | |
| pigment | | | | | | | | |
| (nm) | | | | | | | | |

TABLE 2

| | | Dispersion | Dispersion | Dispersion | Dispersion | Dispersion | Dispersion | |
|---|---|---|---|---|---|---|---|---|
| | Dispersion 9 | 10 | 11 | 12 | 13 | 14 | 15 | C1 |
| C.I. Pigment | | | | | | | | |
| Yellow 173 | | | | | | | | |
| C.I. Pigment | | | | | | | | |
| Yellow 83 | | | | | | | | |
| C.I. Pigment | | | | | | | | |
| Yellow 109 | | | | | | | | |
| C.I. Pigment | | | | | | | | |
| Yellow 110 | | | | | | | | |
| C.I. Pigment | | | | | | | | |
| Yellow 138 | | | | | | | | |
| C.I. Pigment | 10 | | | | | | | |
| Yellow 97 | | | | | | | | |
| C.I. Pigment | | 10 | | | | | | |
| Yellow 55 | | | | | | | | |
| C.I. Pigment | | | 10 | | | | | |
| Yellow 185 | | | | | | | | |
| C.I. Pigment | | | | 10 | | | | |
| Yellow 139 | | | | | | | | |
| C.I. Pigment | | | | | 10 | | | |
| Blue 15:3 | | | | | | | | |
| C.I. Pigment | | | | | | 10 | | |
| Blue 15:1 | | | | | | | | |
| C.I. Pigment | | | | | | | 10 | |
| Green 7 | | | | | | | | |
| Polymer | 9.10 | 9.10 | 9.10 | 9.10 | 9.10 | 9.10 | 9.10 | 9.10 |
| compound 1 | | | | | | | | |
| SOLSPERSE | 0.28 | 0.28 | 0.28 | 0.28 | 0.28 | 0.28 | 0.28 | 0.28 |
| 20000 | | | | | | | | |
| Propylene | 50.4 | 50.4 | 50.4 | 50.4 | 50.4 | 50.4 | 50.4 | 50.4 |
| glycol | | | | | | | | |
| monomethyl | | | | | | | | |
| ether | | | | | | | | |
| acetate | | | | | | | | |
| Halogen | 5.85 | 10.8 | 0.5 | 0.2 | 0 | 5.8 | 50.6 | — |
| content of | | | | | | | | |
| pigment | | | | | | | | |
| molecule | | | | | | | | |
| (%) | | | | | | | | |
| Average | 420 | 380 | 230 | 430 | 280 | 330 | 380 | — |
| particle | | | | | | | | |
| diameter of | | | | | | | | |
| pigment | | | | | | | | |
| (nm) | | | | | | | | |

### Example 1

A photosensitive composition solution having the following composition containing Dispersion 1 (yellow pigment dispersion) prepared in Dispersion Example 1 and Dispersion 13 (blue pigment dispersion) prepared in Dispersion Example 13 at a mixing ratio of 1:2 (mass ratio) was prepared and was coated onto a 16 μm-thick polyethylene terephthalate support (16FB50 manufactured by TORAY INDUSTRIES, INC.) to form a photosensitive layer having a thickness of 35 μm on the dry basis.

A polypropylene film (manufactured by Oji Paper Co., Ltd.: ALPHAN E200, film thickness 20 μm) was then stacked as a protective film by lamination on the photosensitive layer. The assembly thus obtained was wound with a winder to prepare a photosensitive film.

### [Composition of Photosensitive Composition Solution]

| | |
|---|---|
| Polymer compound 1 | 63.3 parts |
| DPHA (manufactured by Nippon Kayaku Co., Ltd., | 22.2 parts |
| dipentaerythritol hexaacrylate (76%. diluted product) | |
| Bisphenol A β-methyl epoxy resin represented by general | 18.8 parts |
| formula (VI) (epoxy equivalent: 214 g/eq, viscosity: 62 Pa · s) | |
| N-Phenylglycine | 0.2 parts |
| Sensitizer represented by general formula (VII) | 0.20 parts |
| CG1325 (photopolymerization initiator) (manufactured by | 2.3 parts |
| Ciba Specialty Chemicals Inc., oxime derivative represented | |
| by general formula (VIII)) | |
| Dicyandiamide (heat curing accelerator) | 0.93 parts |
| Triazine/isocyanuric acid adduct (heat curing accelerator) | 0.53 parts |
| (2MAOK, manufactured by SHIKOKU CHEMICALS | |
| CORPORATION) | |
| Dispersion 1 (yellow pigment) | 0.37 parts |
| Dispersion 13 (blue pigment) | 0.75 parts |
| Barium sulfate dispersion*²⁾ (49.4%) | 81.4 parts |
| Hydroquinone monomethyl ether | 0.06 parts |
| Coating aid (fluorosurfactant F780F, 30% methyl ethyl ketone | 0.24 parts |
| solution) | |
| Methyl ethyl ketone | 45.4 parts |

*²⁾The barium sulfate dispersion was prepared by premixing 29.2 parts of barium sulfate (manufactured by SAKAI CHEMICAL INDUSTRY CO., LTD., B30), 20.9 parts of the Polymer compound 1 (50%) solution, and 36 parts of 1-methoxy-2-propylacetate together and then dispersing the mixture with MOTORMILL M-200 (manufactured by Eiger Japan K.K.) using zirconia beads having a diameter of 1.0 mm at a peripheral velocity of 9 m/s for 3.5 hours.
General formula (VI)

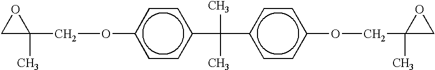

General formula (VII)

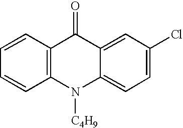

General formula (VIII)

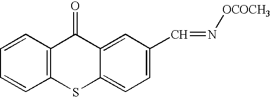

### —Preparation of Photosensitive Laminate—

A substrate was prepared by chemically polishing the surface of a wiring-formed copper clad laminate (through-hole-free, copper thickness 12 μm). The photosensitive film was stacked on the copper clad laminate with a vacuum laminator (manufactured by Nichigo-Morton Co., Ltd., VP130) so that the photosensitive layer in the photosensitive film came into contact with the copper clad laminate while separating the protective film in the photosensitive film. Thus, a photosensitive film comprising the copper clad laminate, the photosensitive layer, and the polyethylene terephthalate film (support) stacked in that order was prepared.

The contact bonding was carried out under conditions of vacuum drawing time 40 seconds, contact bonding temperature 70° C., contact bonding pressure 0.2 MPa, and pressing time 10 seconds.

### —Exposure Step—

The photosensitive layer in the laminate prepared above was exposed through the support to a pattern of a 405 nm laser beam with a laser direct imaging apparatus “INPREX IP-3000 (manufactured by FUJIFILM Corporation)” so that a pattern of hole parts with varied diameters ranging from 20 μm to 100 μm formed at diameter increments of 10 μm was formed, whereby the area of a part of the photosensitive layer was cured.

### <Pattern Forming Apparatus>

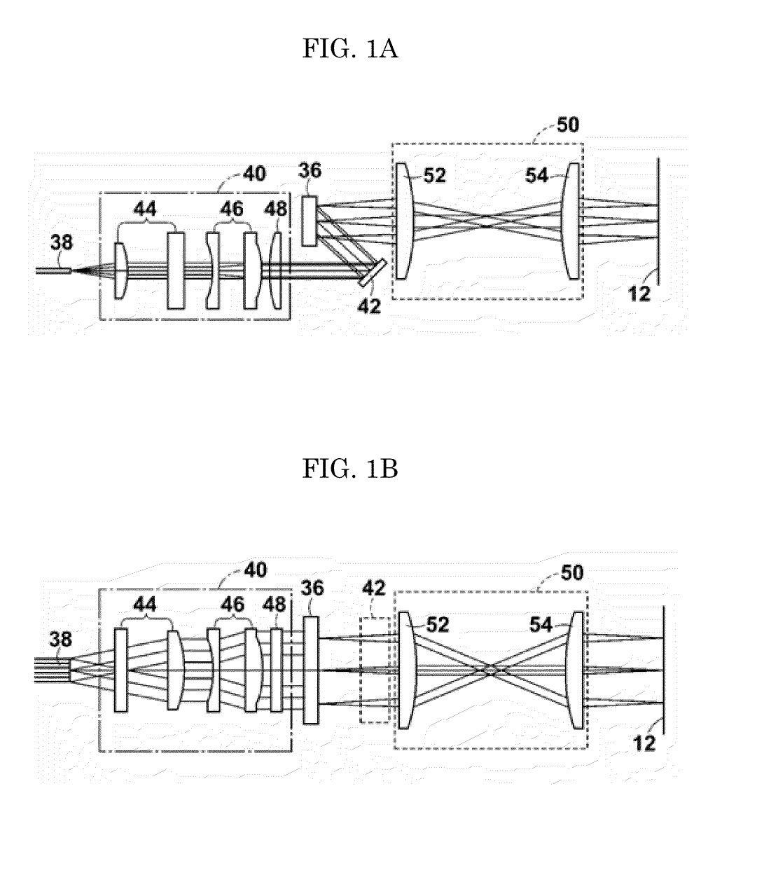

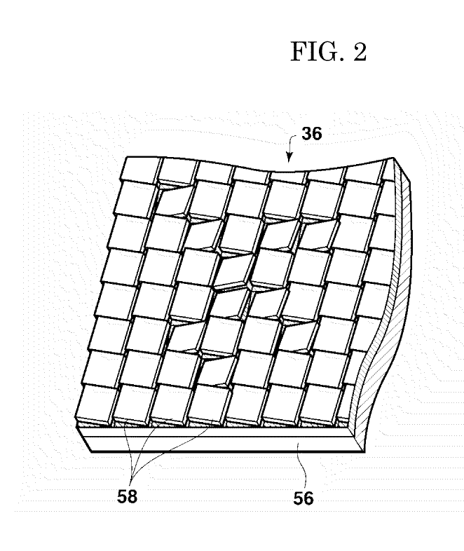

A pattern forming apparatus 10 with an exposure head 30 was used as a light irradiation unit. The exposure head 30 included a multiplexed laser beam source as a light irradiation unit described in JP-A No. 2005-311305 and DMD 36 as a light modulating unit in which a micromirror line containing 1,024 micromirrors 58 arranged in a main scanning direction schematically shown in FIG. 2, 768 sets of the micromirror lines being arranged in a subscanning direction. These micromirror lenses had been controlled so that, among these micromirror lenses, only 1,024 micromirrors×256 column were driven. The exposure head 30 further included an optical system that forms an image from light shown in FIG. 1 on the photosensitive transfer material.

The adopted set inclination angle of each exposure head 30, namely, each DMD 36, was slightly larger than angle θ_{ideal} that just provided double exposure when usable micromirrors 58 of 1,024 column×256 row were used.

The angle θ_{ideal} can be given by Formula 1:

sp sin θ_{ideal}≧Nδ (Formula 1)

In Formula 1, N represents the number of times of exposure in N-fold exposure; s represents the number of usable micromirrors 58 in the column direction; p represents the interval of usable micromirrors 58 in the column direction; and δ represents the pitch of scanning lines formed by micromirrors in such a state that the exposure head 30 has been inclined. As described above, DMD 36 in this embodiment included a number of micromirros 58 arranged vertically and horizontally at equal intervals in a rectangular lattice form. Accordingly, it could be expressed by:

p cos θ_{ideal}=δ (Formula 2)

and Formula 1 was expressed by:

s tan θ_{ideal}=N (Formula 3)

Since s=256 and N=2, the angle θ_{ideal} was about 0.45 degree. Therefore, 0.50 degree was adopted as an example of the set inclination angle θ.

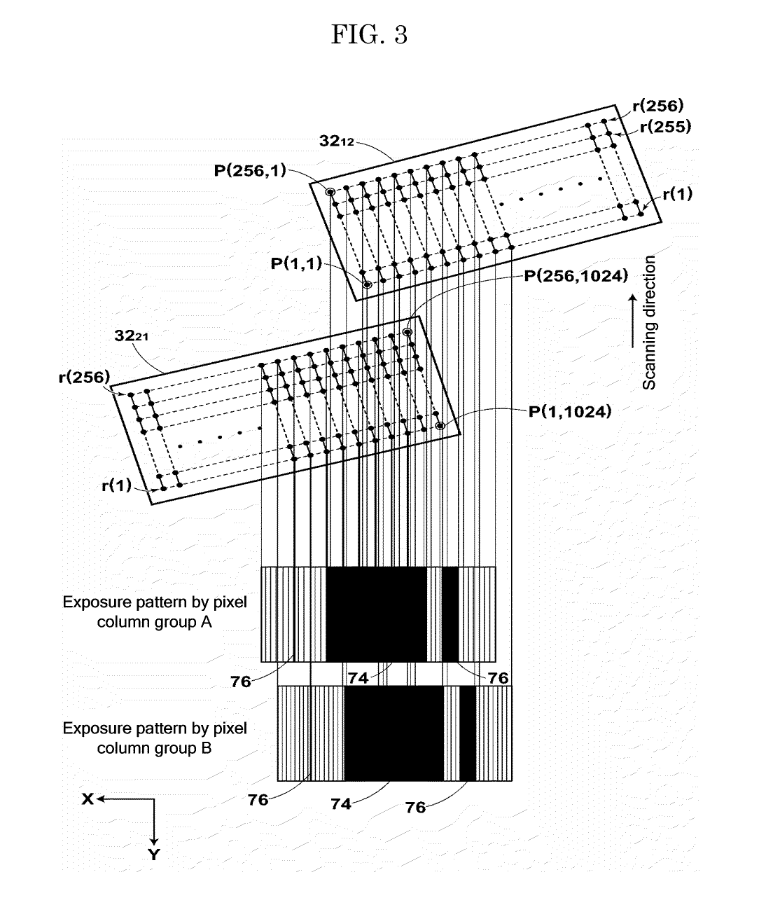

At the outset, in order to correct a variation in resolution and exposure unevenness in the double exposure, the state of an exposure pattern on the exposure surface was examined. The results are shown in FIG. 3. FIG. 3 shows a pattern of a group of light spots, from usable micromirrors 58 in DMD 36 provided in exposure heads 30₁₂ and 30₂₁, projected on an exposure surface of a photosensitive transfer material 12 in such a state that a stage 14 stands still. In the lower part of the drawing, the state of an exposure pattern formed on the exposure surface upon continuous exposure after movement of the stage 14 in such a state that the pattern of a group of light spots as shown in the upper part of the drawing appears, is shown for exposure areas 32₁₂ and 32₂₁. In FIG. 3, for convenience of explanation, the exposure pattern of every other columns of usable micromirror 58 is divided into an exposure pattern by a pixel column group A and an exposure pattern by a pixel column group B. In an actual exposure pattern on the exposure surface, these two exposure patterns are superimposed on top of each other.

As can be seen from FIG. 3, as a result of deviation of the relative position between the exposure heads 30₁₂ and 30₂₁ from an ideal stage, for both the exposure pattern by the pixel column group A and the exposure pattern by the pixel column group B, in exposure regions that overlap with each other on a coordinate axis orthogonal to the scanning direction of the exposure head in the exposure areas 32₁₂ and 32₂₁, a region of an overexposure state deviated from an ideal double exposed state occurs.

A set of a slit 28 and a photodetector was used as the light spot position detection unit. For the exposure head 30₁₂, the positions of light spots P (1, 1) and P (256, 1) within the exposure area 32₁₂ was detected, and, for the exposure head 30₂₁, the positions of light spots P (1, 1,024) and P (256, 1,024) within the exposed area 32₂₁ was detected. The inclination angle of a straight line obtained by connecting the light spot positions and an angle between the straight line and the scanning direction of the exposure head were measured.

For the exposure heads 30₁₂ and 30₂₁, using an actual inclination angle θ′, natural number T closest to a value t satisfying a relationship represented by Formula 4:

t tan θ′=N (Formula 4)

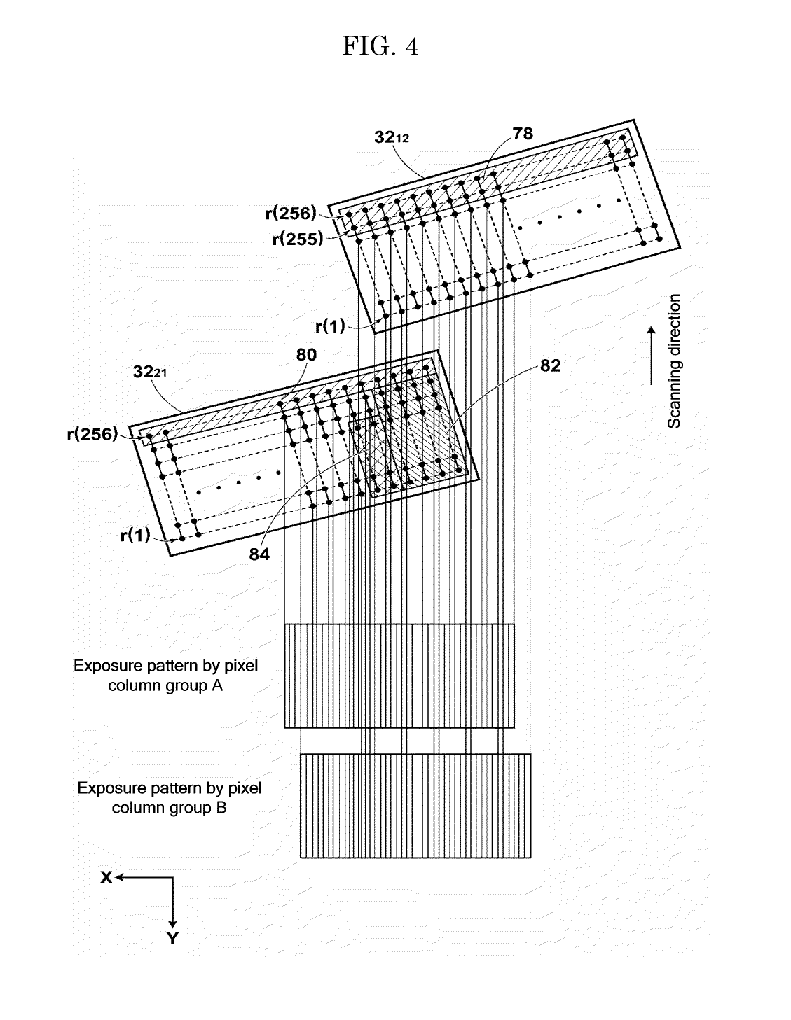

was derived. T=254 was derived for the exposure head 30₁₂, and T=255 was derived for the exposure head 30₂₁. As a result, micromirrors constituting areas 78 and 80 covered by slant lines in the FIG. 4 were specified as micromirrors not used in the main exposure.

Thereafter, regarding micromirrors corresponding to light spots other than light spots constituting the area 78 and the area 80 covered by slant lines in FIG. 4, in the same manner as described above, micromirrors corresponding to light spots constituting an area 82 covered by slant lines and an area 84 covered by hatching in FIG. 4 were specified and were added as the micromirrors not used in the main exposure.

The pixel part control unit sent a signal, by which setting to an normally off state angle is performed, for the micromirrors specified so as not to be used in the exposure, so that these micromirrors were controlled so as not to substantially participate in the exposure.

According to the above construction, in the exposure areas 32₁₂ and 32₂₁, for each area other than the connection area between heads which is an overlapped exposure area on the exposure surface formed by a plurality of the exposure heads, the total of the area of the overexposure deviated from ideal double exposure and the area of underexposure deviated from the ideal double exposure can be minimized.

### —Development Step—

The laminate was allowed to stand at room temperature for 10 minutes. Thereafter, the support was separated from the laminate, and a shower of a 1% aqueous sodium carbonate solution as an alkaline developing solution was sprayed for development against the whole area of the photosensitive layer on the copper clad laminate at 30° C. for a period of time which was twice the shortest development time to dissolve and remove the uncured areas. (Separately, the time until the photosensitive layer remaining uncured on the substrate was dissolved was measured and was defined as the shortest development time.)

The laminate was then washed with water and was dried to form a permanent pattern.

### —Curing Treatment Step—

The whole area of the laminate with a permanent pattern formed thereon was heated at 150° C. for 60 minutes to cure the surface of the permanent pattern and thus to enhance the film strength.

### <Evaluation>

For each of the photosensitive films and each of the permanent patterns, the degree of coloring, hue, absorbance of the photosensitive area, halogen content, exposure sensitivity, resolution, storage stability, and resist properties after curing were evaluated.

### <<Evaluation of Degree of Coloring and Hue>>

The degree of coloring of the photosensitive films was measured with a Macbeth photometer with a red color filter mounted thereon and was expressed in terms of the Macbeth optical density. An optical density of 0.5 or more is preferred. The hue was visually determined. The results are shown in Table 6.

### <<Evaluation of Absorbance in Photosensitive Area>>

Further, for the pohotosensitive films, an absorption spectrum was measured with a spectrophotometer, and the absorbance of the photosensitive area at 405 nm was measured. An absorbance of 1.0 or less is preferred. The results are shown in Table 6.

### <<Evaluation Of Dispersion Stability>>

The coating liquid for a photosensitive layer was stored at 40° C. for 7 days to observe whether or not the coagulation of the pigment occurred. When the coagulation of the pigment occurred, the dispersion stability was evaluated as B while, when the coagulation of pigment did not occur, the dispersion stability was evaluated as A. The results are shown in Table 6.

### <<Measurement and Evaluation for Halogen Content>>

The photosensitive layer (10 g) in the photosensitive films was burned in a combustion flask. The evolved gas was absorbed in pure water, and the content of halogen in the gas absorbed liquid was detected and quantitatively determined by ion chromatography. The results are shown in Table 6.

### <<Evaluation of Exposure Sensitivity>>

For the permanent pattern formed by pattern-wise exposure, development and rinsing as described above, the thickness of the cured area of the photosensitive layer remaining unremoved was measured. The relationship between the exposure dose of laser beams and the thickness of the cured layer was then plotted to provide a sensitivity curve. The amount of energy, which is necessary for providing a 30 μm-thick cured area having a gloss surface on the wiring, was regarded as a light energy amount necessary for curing the photosensitive layer. The results are shown in Table 6.

### <<Resolution>>

The surface of the printed wiring board with a permanent pattern formed thereon was observed under an optical microscope to determine the minimum diameter of holes free from the residual film in the whole part in the cured layer pattern. The minimum hole diameter was regarded as resolution. The smaller the numerical value, the better the resolution. The results are shown in Table 6.

### <<Edge Roughness>>

The laser beams are applied from above the polyethylene terephthalate film (support) in the laminate with the pattern forming apparatus to form a lateral line pattern in a direction orthogonal to the scanning direction of the exposure head, whereby double exposure is performed (pattern of line/space=1/1, line width; 30 μm).

The exposure dose in this case is the light energy amount necessary for curing the photosensitive layer determined in the evaluation of the exposure sensitivity. The laminate is then allowed to stand at room temperature for 10 minutes, and the polyethylene terephthalate film (support) is then separated from the laminate.

A 1% aqueous sodium carbonate solution of 30° C. was sprayed on the whole area of the photosensitive layer on the copper clad laminate at a spray pressure of 0.15 MPa for a period of time that is twice the shortest developing time determined in the evaluation of the developing time to dissolve and remove the area remaining uncured.

In the permanent pattern thus obtained, five arbitrary portions of lines with a width of 30 μm were observed under a laser microscope (VK-9500, manufactured by KEYENCE CORPORATION; magnification of object lens 50 times). Among edge positions within the visual field, the difference in level between the most significantly bulged portion (peak portion) and the most significantly slender portion (bottom portion) was determined as an absolute value, and the average of the values for the five portions was calculated. The average value was regarded as edge roughness. The smaller the edge roughness value, the better the properties. The results are shown in Table 6.

### <<Storage Stability>>

Next, in order to evaluate a change in developability with the elapse of time, a rolled sample provided by holding various protective sheets between superimposed sheet parts in a rolled sheet, packaging the rolled sheet in a light shielding moistureproof bag (BF3X, manufactured by TOKAI ALUMINUM FOIL CO., LTD.), and sealing both ends of the rolled sheet with a bush was stored under accelerated conditions (30° C., 90% RH) in a thermo-hygrostat for 3 days to determine a change in developability.

The initial shortest development time to was compared with the shortest development time t_{3d} after exposure to the accelerated conditions, and the ratio (t₀/t_{3d}) was determined. The storage stability was evaluated based on the ratio according to the following criteria.

A: One time or more, but less than twice
B: Twice or more, but less than three times (practically usable level)
C: Three times or more
The results are shown in Table 6.
—Resist Properties after Curing—

The protective film was separated from the photosensitive laminate, and the photosensitive laminate was then vacuum laminated on a copper clad laminate free from a circuit pattern. The assembly was cooled to room temperature, was then exposed at an exposure of 23 mJ/cm², was cured in a hot air circulation drying oven at 150° C. for 60 min, and was then cooled to room temperature to provide an evaluation sample for a pencil hardness test and an adhesion test. The properties of the cured film was evaluated in terms of the following items for the evaluation sample. The results are shown in Table 7.

### <<Pencil Hardness>>

According to a testing method specified in JIS K-5400, the highest hardness which did not damage the film upon the application of a load of 1 kg to the sample with a pencil hardness tester was determined. The results are shown in Table 7.

### <<Adhesion>>

According to a testing method specified in JIS D-0202, crosscuts were provided in the evaluation sample, and the state of separation of the film after a peeling test with a cellophane pressure-sensitive adhesive tape was then visually determined according to the following criteria. The results are shown in Table 7.

A: Not separated at all
B: Separated slightly
C: Separated completely

### <<Insulating Properties>>

The protective film was separated from the photosensitive film, and the photosensitive film was then stacked on a comb-shaped electrode B coupon of IPC-B-25 by vacuum lamination. The laminate was cooled to room temperature and was then exposed at an exposure of 23 mJ/cm², and curing was then performed in a hot air circulation-type drying oven at 150° C. for 60 minutes to prepare an evaluation sample. A bias voltage of DC 500 V was applied to the comb-shaped electrode to measure an insulating resistance value. The results are shown in Table 7.

### <<Acid Resistance Test>>

The same evaluation sample as used in the evaluation of <<Insulating properties>> was immersed in a 10% by volume aqueous sulfuric acid solution at 20° C. for 30 minutes, was then taken out of the 10% volume aqueous sulfuric acid solution, and the state of the coating film and the adhesion were comprehensively determined and evaluated. The results are shown in Table 7. The determination criteria were as follows.

A: Not changed at all
B: Changed slightly
C: Swelling or distention falling observed in coating film

### <<Alkali Resistance Test>>

The sample was tested and evaluated in the same manner as in the above <<Acid resistance test>>, except that the 10% by volume aqueous sulfuric acid solution was changed to a 10% by volume aqueous sodium hydroxide solution. The results are shown in Table 7.

### <<Electroless Gold Plating Resistance>>

Electroless gold plating was performed on the testing substrate according to a step which will be described later. For the testing substrate, the observation of a change in appearance and a peeling test with a cellophane pressure-sensitive adhesive tape were performed, and the state of separation of the resist film was evaluated according to the following criteria. The results are shown in Table 7.

A: Neither a change in appearance nor separation of the resist film occurred.
B: No change in appearance occurred, but the resist film was slightly separated.
C: Lifting of the resist film, hiding of plating under the film was observed, and the separation of the resist film in the peeling test was significant.

### —Electroless Gold Plating Step—

### —Degreasing—

The testing substrate was immersed in an acidic degreasing liquid (a 20% by volume aqueous solution of MeltexL-5B, manufactured by Nippon MacDermid Co., Inc., Ltd.) of 30° C. for 3 minutes.

### —Water Washing—

The testing substrate was immersed in running water for 3 minutes.

### —Soft Etching—

The testing substrate was immersed in a 14.3% aqueous ammonium persulfate solution at room temperature for 3 minutes.

### —Water Washing—

The testing substrate was immersed in running water for 3 minutes.

### —Immersion in Acid—

The testing substrate was immersed in a 10% by volume aqueous sulfuric acid solution at room temperature for one minute.

### —Water Washing—

The testing substrate was immersed in running water for 30 seconds to 1 minute.

### —Catalyst Application—

The testing substrate was immersed in a catalyst liquid (a 10% by volume aqueous solution of Metal Plate Activator 350, manufactured by Meltex Inc.) of 30° C. for 7 minutes.

### —Water Washing—

The testing substrate was immersed in running water for 3 minutes.

### —Electroless Nickel Plating—

The testing substrate was immersed in a nickel plating solution (a 20% by volume aqueous solution of Melplate Ni-865M, manufactured by Meltex Inc.) (85° C., pH=4.6) for 20 minutes.

### —Immersion in Acid—

The testing substrate was immersed in a 10% by volume aqueous sulfuric acid solution at room temperature for 1 minute.

### —Water Washing—

The testing substrate was immersed in running water for 30 seconds to 1 minute.

### —Electroless Gold Plating—

The testing substrate was immersed in a gold plating solution (an aqueous solution containing 15% by volume Aurolectroless UP manufactured by Meltex Inc. and 3% by volume potassium gold cyanide) (95° C., pH=6) for 10 minutes.

### —Water Washing—

The testing substrate was immersed in running water for 3 minutes.

—Washing with Warm Water—

The testing substrate was immersed in warm water of 60° C. and was thoroughly washed with water for 3 minutes. Water was drained off well, and the testing substrate was then dried.

An electroless gold plated testing substrate was produced through the above steps.

### <<PCT Resistance>>

The protective film was separated from each laminate and was then stacked on a printed wiring board by vacuum lamination. The assembly was cooled to room temperature and was then exposed at an exposure of 90 mJ/cm², and curing was performed in a hot air circulation-type drying oven at 150° C. for 60 minutes to prepare an evaluation sample.

The evaluation sample was cooled to room temperature and was then treated in a PCT tester (TABAI ESPEC HAST SYSTEM TPC-412MD) under conditions of 121° C. and 2 atm for 168 hours, and the state of the cured film was evaluated. The results are shown in Table 7. The determination criteria were as follows.

A: None of separation, color change, and elution were observed.
B: Any of separation, color change, and elution was observed.
C: Separation, color change, and elution were significant.

TABLE 3

| | Example | | | | | | |
|---|---|---|---|---|---|---|---|
| Component | 1 | 2 | 3 | 4 | 5 | 6 | 7 |
| Dispersion 1 | 0.37 | | | | 0.56 | 0.28 | 0.22 |
| Dispersion 2 | | 0.37 | | | | | |
| Dispersion 3 | | | 0.37 | | | | |
| Dispersion 4 | | | | 0.37 | | | |
| Dispersion 5 | | | | | | | |
| Dispersion 6 | | | | | | | |
| Dispersion 7 | | | | | | | |
| Dispersion 8 | | | | | | | |
| Dispersion 9 | | | | | | | |
| Dispersion 10 | | | | | | | |
| Dispersion 11 | | | | | | | |
| Dispersion 12 | | | | | | | |
| Dispersion 13 | 0.75 | 0.75 | 0.75 | 0.75 | 0.56 | 0.84 | 0.89 |
| Dispersion 14 | | | | | | | |
| Dispersion 15 | | | | | | | |
| Pigment-free | | | | | | | |
| solution C1 | | | | | | | |
| Polymer compound 1 | 63.3 | 63.3 | 63.3 | 63.3 | 63.3 | 63.3 | 63.3 |
| (solid content 50%) | | | | | | | |
| Resin A2 solution | | | | | | | |
| (solid content 50%) | | | | | | | |
| DPHA | 22.2 | 22.2 | 22.2 | 22.2 | 22.2 | 22.2 | 22.2 |
| CGI325 | 2.3 | 2.3 | 2.3 | 2.3 | 2.3 | 2.3 | 2.3 |
| 3-Chrolo-N-butyl | 0.74 | 0.74 | 0.74 | 0.74 | 0.74 | 0.74 | 0.74 |
| acridone | | | | | | | |
| IRGACURE 907 | | | | | | | |
| KAYACURE DETX-S | | | | | | | |
| Bisphenol A-type β- | 18.8 | 18.8 | 18.8 | 18.8 | 18.8 | 18.8 | 18.8 |
| methyl epoxy resin | | | | | | | |
| EHPE3150 | | | | | | | |
| Dicyandiamide | 0.93 | 0.93 | 0.93 | 0.93 | 0.93 | 0.93 | 0.93 |
| Melamine | | | | | | | |
| 2MAOK | 0.53 | 0.53 | 0.53 | 0.53 | 0.53 | 0.53 | 0.53 |
| F780F (methyl ethyl | 0.24 | 0.24 | 0.24 | 0.24 | 0.24 | 0.24 | 0.24 |
| ketone solution; solid | | | | | | | |
| content 30%) | | | | | | | |
| Barium sulfate | 81.4 | 81.4 | 81.4 | 81.4 | 81.4 | 81.4 | 81.4 |
| dispersion (solid | | | | | | | |
| content 42.4%) | | | | | | | |
| Silica | | | | | | | |
| Hydroquinone | 0.06 | 0.06 | 0.06 | 0.06 | 0.06 | 0.06 | 0.06 |
| monomethyl ether | | | | | | | |
| Methyl ethyl ketone | 45.4 | 45.4 | 45.4 | 45.4 | 45.4 | 45.4 | 45.4 |

TABLE 4

| | Example | | | | | | | | |
|---|---|---|---|---|---|---|---|---|---|
| Component | 8 | 9 | 10 | 11 | 12 | 13 | 14 | 15 | 16 |
| Dispersion 1 | | | | | | | 0.19 | 0.37 | 0.37 |
| Dispersion 2 | | | | | | | | | |
| Dispersion 3 | | | | | | | | | |
| Dispersion 4 | | | | | | | | | |
| Dispersion 5 | 0.37 | | | | | | | | |
| Dispersion 6 | | 0.37 | | | | | | | |
| Dispersion 7 | | | 0.37 | | | | | | |
| Dispersion 8 | | | | 0.37 | | | | | |
| Dispersion 9 | | | | | 0.37 | | | | |
| Dispersion 10 | | | | | | 0.37 | | | |
| Dispersion 11 | | | | | | | | | |
| Dispersion 12 | | | | | | | | | |
| Dispersion 13 | 0.75 | 0.75 | 0.75 | 0.75 | 0.75 | 0.75 | 0.37 | 0.75 | 0.75 |
| Dispersion 14 | | | | | | | | | |
| Dispersion 15 | | | | | | | | | |
| Pigment-free solution C1 | | | | | | | 0.56 | | |
| Polymer compound 1 | 63.3 | 63.3 | 63.3 | 63.3 | 63.3 | 63.3 | 63.3 | 50.6 | 63.3 |
| (solid content 50%) | | | | | | | | | |
| LIPOXY PR-300 (solid | | | | | | | | 9.3 | |
| content 68%) | | | | | | | | | |
| DPHA | 22.2 | 22.2 | 22.2 | 22.2 | 22.2 | 22.2 | 22.2 | 22.2 | 22.2 |
| CGI325 | 2.3 | 2.3 | 2.3 | 2.3 | 2.3 | 2.3 | 2.3 | 2.3 | 2.3 |
| 3-Chrolo-N-butyl | 0.74 | 0.74 | 0.74 | 0.74 | 0.74 | 0.74 | 0.74 | 0.74 | 0.74 |
| acridone | | | | | | | | | |
| IRGACURE 907 | | | | | | | | | |
| KAYACURE DETX-S | | | | | | | | | |
| Bisphenol A-type β- | 18.8 | 18.8 | 18.8 | 18.8 | 18.8 | 18.8 | 18.8 | 18.8 | 18.8 |
| methyl epoxy resin | | | | | | | | | |
| EHPE3150 | | | | | | | | | |
| Dicyandiamide | 0.93 | 0.93 | 0.93 | 0.93 | 0.93 | 0.93 | 0.93 | 0.93 | 0.93 |
| Melamine | | | | | | | | | |
| 2MAOK | 0.53 | 0.53 | 0.53 | 0.53 | 0.53 | 0.53 | 0.53 | 0.53 | 0.53 |
| F780F (methyl ethyl | 0.24 | 0.24 | 0.24 | 0.24 | 0.24 | 0.24 | 0.24 | 0.24 | 0.24 |
| ketone solution; solid | | | | | | | | | |
| content 30%) | | | | | | | | | |
| Barium sulfate | 81.4 | 81.4 | 81.4 | 81.4 | 81.4 | 81.4 | 81.4 | 81.4 | 81.4 |
| dispersion (solid content | | | | | | | | | |
| 42.4%) | | | | | | | | | |
| Silica | | | | | | | | | |
| Hydroquinone | 0.06 | 0.06 | 0.06 | 0.06 | 0.06 | 0.06 | 0.06 | 0.06 | 0.06 |
| monomethyl ether | | | | | | | | | |
| Methyl ethyl ketone | 45.4 | 45.4 | 45.4 | 45.4 | 45.4 | 45.4 | 45.4 | 45.4 | 45.4 |

TABLE 5

| | Comparative Example | | | | | | | |
|---|---|---|---|---|---|---|---|---|
| Component | 1 | 2 | 3 | 4 | 5 | 6 | 7 | 8 |
| Dispersion 1 | | | | | 0.75 | 0.19 | | |
| Dispersion 2 | | | | | | | | |
| Dispersion 3 | | | | | | | | |
| Dispersion 4 | | | | | | | | |
| Dispersion 5 | | | | | | | | |
| Dispersion 6 | | | | | | | | |
| Dispersion 7 | | | | | | | | |
| Dispersion 8 | | | | | | | | |
| Dispersion 9 | | | | | | | | |
| Dispersion 10 | | | | | | | | |
| Dispersion 11 | | | 0.37 | | | | | |
| Dispersion 12 | | 0.4 | | 0.37 | | | | |
| Dispersion 13 | | | 0.75 | 0.75 | 0.37 | 0.93 | 1.12 | |
| Dispersion 14 | | 0.4 | | | | | | |
| Dispersion 15 | 1.12 | | | | | | | |
| Pigment-free solution C1 | | | | | | | | 0.95 |
| Polymer compound 1 (solid | 63.3 | | 63.3 | 63.3 | 63.3 | 63.3 | 63.3 | 63.3 |
| content 50%) | | | | | | | | |
| Resin A2 solution (solid | | 50 | | | | | | |
| content 50%) | | | | | | | | |
| DPHA | 22.2 | 7 | 22.2 | 22.2 | 22.2 | 22.2 | 22.2 | 22.2 |
| CGI325 | 2.3 | | 2.3 | 2.3 | 2.3 | 2.3 | 2.3 | 2.3 |
| 3-Chrolo-N-butyl acridone | 0.74 | | 0.74 | 0.74 | 0.74 | 0.74 | 0.74 | 0.74 |
| IRGACURE 907 | | 4 | | | | | | |
| KAYACURE DETX-S | | 0.5 | | | | | | |
| Bisphenol A-type β-methyl | 18.8 | | 18.8 | 18.8 | 18.8 | 18.8 | 18.8 | 18.8 |
| epoxy resin | | | | | | | | |
| EHPE3150 | | 10 | | | | | | |
| Dicyandiamide | 0.93 | | 0.93 | 0.93 | 0.93 | 0.93 | 0.93 | 0.93 |
| Melamine | | 1 | | | | | | |
| 2MAOK | 0.53 | | 0.53 | 0.53 | 0.53 | 0.53 | 0.53 | 0.53 |
| F780F (methyl ethyl ketone | 0.24 | | 0.24 | 0.24 | 0.24 | 0.24 | 0.24 | 0.24 |
| solution; solid content 30%) | | | | | | | | |
| Barium sulfate dispersion | 81.4 | 40 | 81.4 | 81.4 | 81.4 | 81.4 | 81.4 | 81.4 |
| (solid content 42.4%) | | | | | | | | |
| Silica | | 10 | | | | | | |
| Hydroquinone monomethyl ether | 0.06 | | 0.06 | 0.06 | 0.06 | 0.06 | 0.06 | 0.06 |
| Methyl ethyl ketone | 45.4 | 28 | 45.4 | 45.4 | 45.4 | 45.4 | 45.4 | 45.4 |

### Example 2

As shown in Table 3, a photosensitive composition (a coating liquid for a photosensitive layer) containing Dispersion 2 (yellow pigment dispersion) in Dispersion Example 1 and Dispersion 13 (blue pigment dispersion) in Dispersion Example 13 at a mixing ratio of 1:2 (mass ratio) was prepared as Example 2 and was coated onto a support.

The stability of the coating liquid for a photosensitive layer was evaluated in the same manner as in Example 1. Further, for the photosensitive film and photosensitive laminate, the degree of coloring of the photosensitive layer, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 3

As shown in Table 3, a photosensitive composition (a coating liquid for a photosensitive layer) containing Dispersion 3 (yellow pigment dispersion) in Dispersion Example 3 and Dispersion 13 (yellow pigment dispersion) in Dispersion Example 13 at a mixing ratio of 1:2 (mass ratio) was prepared as Example 3 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 4

As shown in Table 3, a photosensitive composition (a coating liquid for a photosensitive layer) containing Dispersion 4 (yellow pigment dispersion) in Dispersion Example 4 and Dispersion 13 (blue pigment dispersion) in Dispersion Example 13 at a mixing ratio of 1:2 (mass ratio) was prepared as Example 4 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 5

As shown in Table 3, a photosensitive composition (a coating liquid for a photosensitive layer) containing Dispersion 1 (yellow pigment dispersion) in Dispersion Example 1 and Dispersion 13 (blue pigment dispersion) in Dispersion Example 13 at a mixing ratio of 1:1 (mass ratio) was prepared as Example 5 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 6

As shown in Table 3, a photosensitive composition (a coating liquid for a photosensitive layer) containing Dispersion 1 (yellow pigment dispersion) in Dispersion Example 1 and Dispersion 13 (blue pigment dispersion) in Dispersion Example 13 at a mixing ratio of 1:3 (mass ratio) was prepared as Example 6 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 7

As shown in Table 3, a photosensitive composition (a coating liquid for a photosensitive layer) containing Dispersion 1 (yellow pigment dispersion) in Dispersion Example 1 and Dispersion 13 (blue pigment dispersion) in Dispersion Example 13 at a mixing ratio of 1:4 (mass ratio) was prepared as Example 7 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 8

As shown in Table 4, a photosensitive composition (a coating liquid for a photosensitive layer) containing Dispersion 5 (yellow pigment dispersion) in Dispersion Example 1 and Dispersion 13 (blue pigment dispersion) in Dispersion Example 13 at a mixing ratio of 1:2 (mass ratio) was prepared as Example 8 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 9

As shown in Table 4, a photosensitive composition (a coating liquid for a photosensitive layer) containing Dispersion 6 (yellow pigment dispersion) in Dispersion Example 1 and Dispersion 13 (blue pigment dispersion) in Dispersion Example 13 at a mixing ratio of 1:2 (mass ratio) was prepared as Example 7 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 10

As shown in Table 4, a photosensitive composition (a coating liquid for a photosensitive layer) containing Dispersion 1 (yellow pigment dispersion) in Dispersion Example 7 and Dispersion 13 (blue pigment dispersion) in Dispersion Example 13 at a mixing ratio of 1:2 (mass ratio) was prepared as Example 10 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 11

As shown in Table 4, a photosensitive composition (a coating liquid for a photosensitive layer) containing Dispersion 8 (yellow pigment dispersion) in Dispersion Example 8 and Dispersion 13 (blue pigment dispersion) in Dispersion Example 13 at a mixing ratio of 1:2 (mass ratio) was prepared as Example 11 and was coated onto a support. The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 12

As shown in Table 4, a photosensitive composition (a coating liquid for a photosensitive layer) containing Dispersion 9 (yellow pigment dispersion) in Dispersion Example 9 and Dispersion 13 (blue pigment dispersion) in Dispersion Example 13 at a mixing ratio of 1:2 (mass ratio) was prepared as Example 12 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 13

As shown in Table 4, a photosensitive composition (a coating liquid for a photosensitive layer) containing Dispersion 10 (yellow pigment dispersion) in Dispersion Example 10 and Dispersion 13 (blue pigment dispersion) in Dispersion Example 13 at a mixing ratio of 1:2 (mass ratio) was prepared as Example 13 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 14

As shown in Table 4, a photosensitive composition (a coating liquid for a photosensitive layer) containing Dispersion 1 (yellow pigment dispersion) in Dispersion Example 1 and Dispersion 13 (blue pigment dispersion) in Dispersion Example 13 at a mixing ratio of 1:2 (mass ratio) and further Solution C1 free from a pigment, the amount of the mixture of Dispersion 1 and Dispersion 13 in the composition being half the amount in Example 1, was prepared as Example 14 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 15

As shown in Table 4, a photosensitive composition having the same formulation as the photosensitive composition (coating liquid for a photosensitive layer) of Example 1 was prepared as Example 15 except that 50.6 parts of the solution of Polymer compound 1 and 9.3 parts of LIPOXY PR-300 (manufactured by SHOWA HIGHPOLYMER CO., LTD.: a resin produced by subjecting a cresol novolak epoxy resin to a ring opening addition reaction with acrylic acid and then subjecting the product to an addition reaction with tetrahydrophthalic anhydride, acid value=81, solid content 68%, a propylene glycol monomethyl ether acetate solution) were used instead of 63.3 parts of the solution of Polymer compound 1. The photosensitive composition was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Example 16

In the same manner as in Example 1, a photosensitive film roll, a laminate, and a permanent pattern were formed followed by the evaluation of the degree of coloring, hue, absorbance at 405 nm, halogen content, shortest developing time, sensitivity, resolution, edge roughness, and a change in developing time with the elapse of time except that, in the pattern forming apparatus in Example 1, the set inclination angle θ was calculated based on formula 3 wherein N=1, natural number T closest to value t satisfying the relationship of t tan θ′=1 was derived based on formula 4 and N-fold exposure (N=1) was performed. The results are shown in Table 6. Likewise, the properties of the cured film were evaluated. The results are shown in Table 7.

### Comparative Example 1

As shown in Table 5, a photosensitive composition (a coating liquid for a photosensitive layer) containing Dispersion 15 (green pigment dispersion) in Dispersion Example 15 was prepared as Comparative Example 1 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Comparative Example 2

As shown in Table 5, a photosensitive composition (a coating liquid for a photosensitive layer) containing Dispersion 12 (yellow pigment dispersion) in Dispersion Example 12 and Dispersion 14 (blue pigment dispersion) in Dispersion Example 14 at a mixing ratio of 1:1 (mass ratio) was prepared as Comparative Example 2 and was coated onto a support.

In Table 5, EHPE 3150 is an epoxy resin manufactured by DAICEL CHEMICAL INDUSTRIES, LTD., IRGACURE 907 is a photopolymerization initiator manufactured by Ciba Specialty Chemicals Inc. and KAYACURE DETX-S is a photopolymerization initiator manufactured by NIPPON KAYAKU Co., LTD. Silica had an average particle diameter of 1 μm.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Comparative Example 3

As shown in Table 5, a photosensitive composition (a coating liquid for a photosensitive layer) containing Dispersion 11 (yellow pigment dispersion) in Dispersion Example 11 and Dispersion 13 (blue pigment dispersion) in Dispersion Example 13 at a mixing ratio of 1:2 (mass ratio) was prepared as Comparative Example 3 and was coated onto a support. After standing of the coating liquid at 40° C. for seven days, the presence of coagulates was confirmed by observation. Immediately after the preparation of the coating liquid, however, the coating liquid could be used for coating without any problem.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Comparative Example 4

As shown in Table 5, a photosensitive composition (a coating liquid for a photosensitive layer) containing Dispersion 12 (yellow pigment dispersion) in Dispersion Example 12 and Dispersion 13 (blue pigment dispersion) in Dispersion Example 13 at a mixing ratio of 1:2 (mass ratio) was prepared as Comparative Example 4 and was coated onto a support. After standing of the coating liquid at 40° C. for seven days, the presence of coagulates was confirmed by observation. Immediately after the preparation of the coating liquid, however, the coating liquid could be used for coating without any problem.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Comparative Example 5

As shown in Table 5, a photosensitive composition (a coating liquid for a photosensitive layer) containing Dispersion 1 (yellow pigment dispersion) in Dispersion Example 1 and Dispersion 13 (blue pigment dispersion) in Dispersion Example 13 at a mixing ratio of 2:1 (mass ratio) was prepared as Comparative Example 5 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Comparative Example 6

As shown in Table 5, a photosensitive composition (a coating liquid for a photosensitive layer) containing Dispersion 1 (yellow pigment dispersion) in Dispersion Example 1 and Dispersion 13 (blue pigment dispersion) in Dispersion Example 13 at a mixing ratio of 1:5 (mass ratio) was prepared as Comparative Example 6 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Comparative Example 7

As shown in Table 5, a photosensitive composition (a coating liquid for a photosensitive layer) containing only Dispersion 13 (blue pigment dispersion) in Dispersion Example 13 was prepared as Comparative Example 7 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

### Comparative Example 8

As shown in Table 5, a photosensitive composition (a coating liquid for a photosensitive layer) free from a color pigment was prepared as Comparative Example 8 and was coated onto a support.

The stability of the coating liquid for a photosensitive layer was evaluated in the same manner as in Example 1. Further, for the photosensitive film and photosensitive laminate, the degree of coloring, hue, absorbance at 405 nm, halogen atom content, shortest developing time, sensitivity, resolution, edge roughness, and a change in developing time with the elapse of time were evaluated in the same manner as in Example 1. The results are shown in Table 6. Likewise, the properties of the cured film were evaluated. The results are shown in Table 7.

TABLE 6

| | | Degree of | | | Absorbance | | | | | Storage stability |
|---|---|---|---|---|---|---|---|---|---|---|
| | | coloring | | | in photo- | Halogen | | | Edge | (change in |
| | Dispersion | Macbeth optical | | Legibility | sensitive | content | Sensitivity | Resolution | roughness | developability |
| Sample | stability | density | Hue | of pattern | area (405 nm) | (ppm) | (mJ/cm²) | (μm) | (μm) | with time) |
| Ex. 1 | A | 0.60 | Green | A | 0.70 | 359 | 23 | 40 | 1.5 | A |
| Ex. 2 | A | 0.61 | Green | A | 0.80 | 360 | 30 | 40 | 1.4 | A |
| Ex. 3 | A | 0.58 | Green | A | 0.60 | 358 | 25 | 60 | 1.3 | A |
| Ex. 4 | A | 0.51 | Green | A | 0.94 | 357 | 35 | 40 | 1.4 | A |
| Ex. 5 | A | 0.62 | Green | A | 0.75 | 465 | 25 | 55 | 1.3 | A |
| Ex. 6 | A | 0.64 | Green | A | 0.71 | 308 | 23 | 35 | 1.5 | A |
| Ex. 7 | A | 0.65 | Green | A | 0.65 | 276 | 23 | 40 | 1.5 | A |
| Ex. 8 | A | 0.52 | Green | A | 0.72 | 380 | 25 | 40 | 1.4 | A |
| Ex. 9 | A | 0.56 | Green | A | 0.83 | 725 | 30 | 40 | 1.3 | A |
| Ex. 10 | A | 0.62 | Green | A | 0.75 | 722 | 28 | 40 | 1.5 | A |
| Ex. 11 | A | 0.53 | Green | A | 0.84 | 682 | 35 | 40 | 1.6 | A |
| Ex. 12 | A | 0.58 | Green | A | 0.81 | 228 | 34 | 45 | 1.4 | A |
| Ex. 13 | A | 0.57 | Green | A | 0.75 | 293 | 25 | 45 | 1.5 | A |
| Ex. 14 | A | 0.45 | Green | B | 0.74 | 255 | 25 | 50 | 1.7 | A |
| Ex. 15 | A | 0.60 | Green | A | 0.70 | 370 | 27 | 50 | 1.7 | A |
| Ex. 16 | A | 0.60 | Green | A | 0.70 | 359 | 23 | 40 | 2.5 | A |
| Comp. Ex. 1 | A | 0.65 | Green | A | 0.84 | 2,175 | 32 | 60 | 1.8 | C |
| Comp. Ex. 2 | A | 0.64 | Green | A | 0.94 | 90 | 150 | 50 | 1.6 | C |
| Comp. Ex. 3 | B | 0.54 | Green | A | 0.70 | 150 | 32 | 50 | 1.2 | C |
| Comp. Ex. 4 | B | 0.56 | Green | A | 0.81 | 152 | 36 | 70 | 1.7 | C |
| Comp. Ex. 5 | A | 0.43 | Yellowish | B | 0.89 | 1,206 | 40 | 65 | 1.3 | A |
| | | | green | | | | | | | |
| Comp. Ex. 6 | A | 0.35 | Bluish | C | 0.53 | 417 | 30 | 60 | 1.8 | A |
| | | | green | | | | | | | |
| Comp. Ex. 7 | B | 0.31 | Blue | C | 0.70 | 150 | 23 | 65 | 1.2 | A |
| Comp. Ex. 8 | A | 0.15 | Colorless | C | 0.50 | 150 | 20 | 70 | 1.5 | A |

TABLE 7

| | | | Electrical | | | Electroless | |
|---|---|---|---|---|---|---|---|
| | Pencil | | insulating | Acid | Alkali | gold plating | PCT |
| | hardness | Adhesion | property (×10⁻¹³) | resistance | resistance | resistance | resistance |
| Ex. 1 | 5H | A | 9.5 | A | A | A | A |
| Ex. 2 | 5H | A | 9.6 | A | A | A | A |
| Ex. 3 | 5H | A | 9.3 | A | A | A | A |
| Ex. 4 | 5H | A | 8.9 | A | A | A | A |
| Ex. 5 | 5H | A | 9.0 | A | A | A | A |
| Ex. 6 | 5H | A | 9.1 | A | A | A | A |
| Ex. 7 | 5H | A | 9.5 | A | A | A | A |
| Ex. 8 | 5H | A | 9.2 | A | A | A | A |
| Ex. 9 | 5H | A | 9.3 | A | A | A | A |
| Ex. 10 | 5H | A | 9.5 | A | A | A | A |
| Ex. 11 | 5H | A | 9.1 | A | A | A | A |
| Ex. 12 | 5H | A | 9.3 | A | A | A | A |
| Ex. 13 | 5H | A | 9.4 | A | A | A | A |
| Ex. 14 | 5H | A | 9.0 | A | A | A | A |
| Ex. 15 | 5H | A | 9.5 | A | A | A | A |
| Ex. 16 | 5H | A | 9.3 | A | A | A | A |
| Comp. Ex. 1 | 5H | A | 9.2 | A | A | A | A |
| Comp. Ex. 2 | 5H | A | 2.6 | A | A | A | A |
| Comp. Ex. 3 | 5H | A | 9.5 | A | A | A | A |
| Comp. Ex. 4 | 5H | A | 9.1 | A | A | A | A |
| Comp. Ex. 5 | 5H | A | 9.2 | A | A | A | A |
| Comp. Ex. 6 | 5H | A | 9.7 | A | A | A | A |
| Comp. Ex. 7 | 5H | A | 9.3 | A | A | A | A |
| Comp. Ex. 8 | 2H | A | 9.6 | A | A | A | A |

As can be seen from the results of Tables 6 and 7, it has been confirmed that, for the photosensitive compositions of Examples 1 to 14 containing a pigment, which contains one halogen atom per molecule and shows a blue color, a pigment, which has an average particle diameter of 100 nm to 1,000 nm, contains 5% by mass to 40% by mass of a halogen atom, and shows a yellow color, and contains a colorant, which shows a green color, and the photosensitive films of Examples 1 to 14 can realize a smooth photosensitive layer, excellent storage stability, and, further, a high-definition permanent pattern could be provided when a blue-violet laser exposure system is used.

Further, it has been confirmed that the photosensitive compositions of Examples 1 to 16 having a halogen atom content of 250 ppm to 800 ppm had good dispersion stability, and the photosensitive films of Examples 1 to 16, which included a photosensitive layer having an exposure sensitivity of 20 mJ/cm² to 35 mJ/cm², could form a high-definition permanent pattern when a blue-violet laser exposure system was used.

Furthermore, as can be seen from the results of Example 16, it has been confirmed that Examples 1 to 15, which had adopted multiple exposure, had excellent properties, particularly excellent “sensitivity,” “resolution,” and “edge roughness.”

On the other hand, as can be seen from the results of Tables 6 and 7, Comparative Example 1 was unfavorable from the viewpoint of safety because the halogen content of the photosensitive layer is more than 900 ppm, and, for Comparative Example 2, despite a low halogen content (90 ppm) of the photosensitive composition, the sensitivity was very low, and the storage stability of the photosensitive layer was poor.

For Comparative Examples 3 and 4 that do not contain a halogen atom per molecule and contain a pigment, which shows a blue color, and a halogen atom-free pigment, which shows a yellow color, the dispersion stability and the storage stability of the photosensitive layer were poor.

Further, for Comparative Examples 5 to 8, the storage stability of the photosensitive layer was favorable. However, for Comparative Example 5 and Comparative Example 6 wherein the mixing ratio between the halogen-free blue pigment and the halogen-containing yellow pigment is outside the range of 1:1 to 4:1, the absorbance and the exposure sensitivity in the photosensitive areas were poor, and Comparative Example 7 and Comparative Example 8, wherein the hue was blue or colorless, provided unfavorable results because the coating of the photosensitive composition was less likely to be distinguished or could not be distinguished from the printed board and the like.

The photosensitive compositions and the photosensitive films of the present invention have good dispersion stability and storage stability and can provide a high-definition permanent pattern when a blue-violet laser exposure system is used. Accordingly, the photosensitive compositions and the photosensitive films are suitable for use as protective films and interlayer insulating films and can be widely used for the formation of permanent patterns, for example, in printed wiring boards (for example, multilayer wiring boards and build-up wiring boards), color filters and studs, rib materials, spacers, members for displays such as partition walls, holograms, micromachines, and proofs and are particularly suitable for use in the formation of permanent patterns in printed boards.

1. A photosensitive composition, comprising:
an alkali soluble photosensitive resin;
a polymerizable compound;
a photopolymerization initiator or a photoinitiator compound;
a thermal crosslinking resin; and
a colorant,
wherein the colorant comprises a pigment which contains 5% by mass to 50% by mass of a halogen atom per molecule and shows a yellow color, and a pigment which does not contain a halogen atom per molecule and shows a blue color in a mixing ratio (mass ratio) of 1:1 to 1:4,
the colorant shows a green color due to the mixing of the pigments, and
the halogen content in the total solid content of the photosensitive composition is 900 ppm or less.

2. The photosensitive composition according to claim 1, wherein the pigment which shows a blue color is a phthalocyanine pigment, and
the pigment which shows a yellow color is a pigment which contains a halogen atom in a molecule thereof and is selected from: monoazo compounds; diarylide non-lake compounds and lake compounds among disazo compounds; bisacetoacetarylide compounds; benzimidazolone compounds; metal complex compounds; quinophthalone compounds; isoindoline compounds; and aminoanthraquinone compounds and heterocylic anthraquinone pigments among condensed polycyclic compound.

3. The photosensitive composition according to claim 2, wherein the pigment which shows a yellow color is selected from C.I. Pigment Yellow 2, C.I. Pigment Yellow 3, C.I. Pigment Yellow 6, C.I. Pigment Yellow 49, C.I. Pigment Yellow 73, C.I. Pigment Yellow 75, C.I. Pigment Yellow 97, C.I. Pigment Yellow 98, C.I. Pigment Yellow 111, C.I. Pigment Yellow 116, C.I. Pigment Yellow 10, C.I. Pigment Yellow 60, C.I. Pigment Yellow 168, C.I. Pigment Yellow 12, C.I. Pigment Yellow 13, C.I. Pigment Yellow 14, C.I. Pigment Yellow 17, C.I. Pigment Yellow 55, C.I. Pigment Yellow 63, C.I. Pigment Yellow 81, C.I. Pigment Yellow 83, C.I. Pigment Yellow 87, C.I. Pigment Yellow 106, C.I. Pigment Yellow 113, C.I. Pigment Yellow 114, C.I. Pigment Yellow 121, C.I. Pigment Yellow 124, C.I. Pigment Yellow 126, C.I. Pigment Yellow 127, C.I. Pigment Yellow 136, C.I. Pigment Yellow 152, C.I. Pigment Yellow 170, C.I. Pigment Yellow 171, C.I. Pigment Yellow 172, C.I. Pigment Yellow 174, C.I. Pigment Yellow 176, C.I. Pigment Yellow 188, C.I. Pigment Yellow 109, C.I. Pigment Yellow 110, C.I. Pigment Yellow 173, C.I. Pigment Yellow 154, C.I. Pigment Yellow 93, C.I. Pigment Yellow 94, C.I. Pigment Yellow 95, C.I. Pigment Yellow 128, C.I. Pigment Yellow 166, and C.I. Pigment Yellow 138.

4. The photosensitive composition according to claim 1, wherein an amount of the halogen component in the photosensitive composition is 500 ppm or less.

5. The photosensitive composition according to claim 1, wherein the pigment which shows a yellow color has an average particle diameter of 100 nm to 500 nm.

6. A photosensitive film, comprising a photosensitive layer formed by applying a photosensitive composition onto a support and drying the applied photosensitive composition,
wherein the photosensitive composition comprises:
an alkali soluble photosensitive resin;
a polymerizable compound;
a photopolymerization initiator or a photoinitiator compound;
a thermal crosslinking resin; and
a colorant,
wherein the colorant comprises a pigment which contains 5% by mass to 50% by mass of a halogen atom per molecule and shows a yellow color, and a pigment which does not contain a halogen atom per molecule and shows a blue color in a mixing ratio (mass ratio) of 1:1 to 1:4,
the colorant shows a green color due to the mixing of the pigments, and
the halogen content in the total solid content of the photosensitive composition is 900 ppm or less.

7. A method for forming a permanent pattern, comprising:
exposing the photosensitive layer formed on a surface of a substrate using a photosensitive composition; and
developing the exposed photosensitive layer,
wherein the photosensitive composition comprises:
an alkali soluble photosensitive resin;
a polymerizable compound;
a photopolymerization initiator or a photoinitiator compound;
a thermal crosslinking resin; and
a colorant,
wherein the colorant comprises a pigment which contains 5% by mass to 50% by mass of a halogen atom per molecule and shows a yellow color, and a pigment which does not contain a halogen atom per molecule and shows a blue color in a mixing ratio (mass ratio) of 1:1 to 1:4,
the colorant shows a green color due to the mixing of the pigments, and
the halogen content in the total solid content of the photosensitive composition is 900 ppm or less.

8. The method for forming a permanent pattern according to claim 7, wherein the substrate is a printed wiring board with wiring formed thereon.

9. The method for forming a permanent pattern according to claim 7, wherein the exposure is performed using a laser beam having a wavelength of 350 nm to 415 nm.

10. The method for forming a permanent pattern according to claim 7, wherein, after the development, the photosensitive layer is subjected to curing treatment.

11. (canceled)
